(19) United States
(12) Patent Application Publication
(10) Pub. No.: US 2025/0391763 A1
(43) Pub. Date: Dec. 25, 2025

(54) INTEGRATED CIRCUIT DEVICE AND SYSTEM

(71) Applicant: TAIWAN SEMICONDUCTOR MANUFACTURING COMPANY, LTD., Hsinchu (TW)

(72) Inventors: Wei-Cheng TZENG, Hsinchu (TW); Chun-Yen LIN, Hsinchu (TW); Wei-Cheng LIN, Hsinchu (TW); Jiann-Tyng TZENG, Hsinchu (TW)

(21) Appl. No.: 18/937,578

(22) Filed: Nov. 5, 2024

Related U.S. Application Data
(60) Provisional application No. 63/663,419, filed on Jun. 24, 2024.

(51) Int. Cl. H01L 23/50; H01L 21/768; H01L 23/522; H01L 27/092; H01L 29/06; H01L 29/423; H01L 29/775; H01L 29/786

(52) U.S. Cl. CPC H01L 23/50; H01L 21/76877; H01L 23/5226; H10D 84/85; H10D 30/43; H10D 30/6735; H10D 30/6757; H10D 62/121

(57) ABSTRACT

An integrated circuit (IC) device includes an active region, a front side power rail, a back side power rail, and a first power tap structure extending between and electrically coupling the front side power rail to the back side power rail. The active region includes, along a first axis, a first active region portion and a second active region portion continuous to the first active region portion. The first active region portion has, along a second axis transverse to the first axis, a width smaller than that of the second active region portion. The front side power rail and the back side power rail are on opposite sides of the active region, along a thickness direction transverse to both the first axis and the second axis. Along the second axis, the first power tap structure overlaps the first active region portion, without overlapping the second active region portion.

### RELATED APPLICATION(S)

This application claims the benefit of U.S. Provisional Application No. 63/663,419, filed Jun. 24, 2024, which is herein incorporated by reference in its entirety.

### BACKGROUND

An integrated circuit (“IC”) device includes one or more semiconductor devices represented in an IC layout diagram (also referred to as “layout diagram,” “layout” or “IC layout”). A layout diagram is hierarchical and includes modules which carry out higher-level functions in accordance with the semiconductor device's design specifications. The modules are often built from a combination of cells, each of which represents one or more semiconductor structures configured to perform a specific function. Cells having pre-designed layout diagrams, sometimes known as standard cells, are stored in standard cell libraries (hereinafter “libraries” or “cell libraries” for simplicity) and accessible by various tools, such as electronic design automation (EDA) tools, to generate, optimize and verify designs for ICs.

To reduce the sizes of IC devices, sometimes a layer of semiconductor devices is formed, or bonded, over another layer of semiconductor devices. Examples include complementary field effect transistor (CFET) devices in which an upper or top semiconductor device overlies a lower or bottom semiconductor device in a stack configuration.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A is a schematic perspective view of a stack of semiconductor devices, in accordance with some embodiments.

FIG. 1B is a schematic perspective view, and FIGS. 1C, 1D, 1E and IF are schematic cross-sectional views of an IC device at various stages in a manufacturing process, in accordance with some embodiments.

FIG. 2A is a block diagram of an IC device, in accordance with some embodiments.

FIG. 2B is a schematic perspective view of a region of an IC device, in accordance with some embodiments.

FIG. 2C is a schematic view of a layout of a circuit region of an IC device, in accordance with some embodiments

FIGS. 3A, 3B, 3C, 3D are schematic cross-sectional views of various circuit regions of one or more IC devices, in accordance with some embodiments.

FIGS. 4A and 4B are schematic perspective views of various circuit regions of one or more IC devices, in accordance with some embodiments.

FIGS. 5A, 5B are schematic views of layouts of various power tap cells, in accordance with some embodiments.

FIGS. 6A, 6B are schematic cross-sectional views of various circuit regions of one or more IC devices, in accordance with some embodiments.

FIG. 7A includes a schematic circuit diagram of a circuit region and schematic views at various layers of a layout of the circuit region, in accordance with some embodiments.

FIGS. 7B, 7C are schematic views of various layouts of a circuit region, in accordance with some embodiments.

FIG. 8A includes a schematic circuit diagram of a circuit region and schematic views at various layers of a layout of the circuit region, in accordance with some embodiments.

FIGS. 8B, 8C, 8D are schematic views of various layouts of a circuit region, in accordance with some embodiments.

FIG. 9 includes schematic views of various metal and via interconnect schemes and applicable circuit regions in layouts of one or more IC devices, in accordance with some embodiments.

FIGS. 10A, 10B, 10C include schematic views of a layout of a circuit region at various design stages, in accordance with some embodiments.

FIG. 11 includes schematic views at various layers of a layout of a circuit region, in accordance with some embodiments.

FIGS. 12A and 12B each include a schematic diagram of a portion of an IC manufacturing process, and schematic views of an IC device at various stages in the manufacturing process, in accordance with some embodiments.

FIGS. 13A, 13B, 13C are flowcharts of various methods, in accordance with some embodiments.

FIG. 14 is a block diagram of an electronic design automation (EDA) system in accordance with some embodiments.

FIG. 15 is a block diagram of an IC device manufacturing system, and an IC manufacturing flow associated therewith, in accordance with some embodiments.

### DETAILED DESCRIPTION

The following disclosure provides different embodiments, or examples, for implementing features of the provided subject matter. Specific examples of components, materials, values, steps, arrangements, or the like, are described below to simplify the present disclosure. These are, of course, merely examples and are not limiting. Other components, materials, values, steps, arrangements, or the like, are contemplated. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed. Source/drain(s) may refer to a source or a drain, individually or collectively dependent upon the context.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In some embodiments, an IC device includes a power delivery structure configured to provide various power supply voltages, e.g., a positive power supply voltage VDD and a reference voltage such as the ground voltage VSS, to various circuits and/or circuit components of the IC device. In some configurations, the power delivery structure is arranged at both a front side and an opposite, back side of the IC device, and comprises one or more power tap structures configured to provide power from one of the front side and the back side to the other side. A chip area occupied by power tap structures or power tap cells is sometimes referred to as a power tap area.

In some embodiments, power tap structures in an IC device comprise both stand-alone power tap structures having larger sizes, and in-cell power tap structures having smaller sizes. In one or more embodiments, a stand-alone power tap structure corresponds to a power tap cell, and/or an in-cell power tap structure is a power tap structure incorporated in a standard cell, e.g., a functional cell. In at least one embodiment, an in-cell power tap structure comprises a via interconnect embedded in a dielectric structure that limits or defines a length of one or more gates in a circuit. In some embodiments, the via interconnect is arranged on a boundary of a first cell corresponding to the circuit, and is configured to be shared with a further circuit corresponding to a second cell placed in abutment with the first cell. In at least one embodiment, instead of being an in-cell power tap structure, a via interconnect is configurable for back side power delivery of a power supply voltage from a back side power rail to a top semiconductor device of a CFET device. In some embodiments, a top semiconductor device is configurable to receive the same power supply voltage either through back side power delivery from a back side power rail and a via interconnect, or through front side power delivery from a front side power rail without requiring a via interconnect.

In some embodiments, where an IC device comprises one or more in-cell power tap structures, it is possible to reduce a number of larger, stand-alone power tap structures. As a result, in one or more embodiments, the power tap area of the IC device is advantageously reduced. In at least one embodiment, an area that would otherwise be occupied by one or more stand-alone power tap structures is re-configured as an active region for one or more additional CFET devices, thereby obtaining area improvements.

In some embodiments, a via interconnect is configured by a cut-gate mask. In at least one embodiment, a cut-gate mask has a larger width in a first area where a via interconnect is to be formed, and a smaller width in a second area where a via interconnect is not to be formed. As a result, it is possible in one or more embodiments to provide CFET devices with an active region which has a larger width in the second area than in the first area. In some embodiments, by reconfiguring a top semiconductor device to receive a power supply voltage through front side power delivery instead of back side power delivery, it is possible to omit a via interconnect associated with the back side power delivery. As a result, it is possible in one or more embodiments to increase a width of the active region where the via interconnect is omitted, thereby obtaining performance improvements. One or more further advantages are achievable in various embodiments, as described herein.

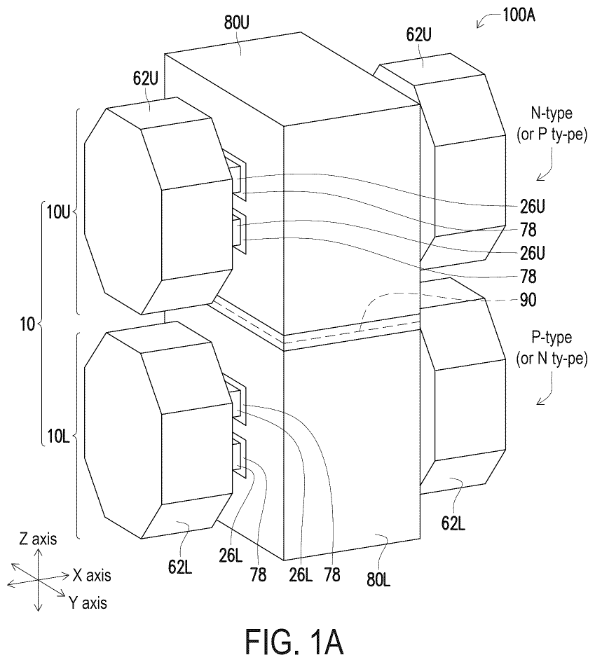

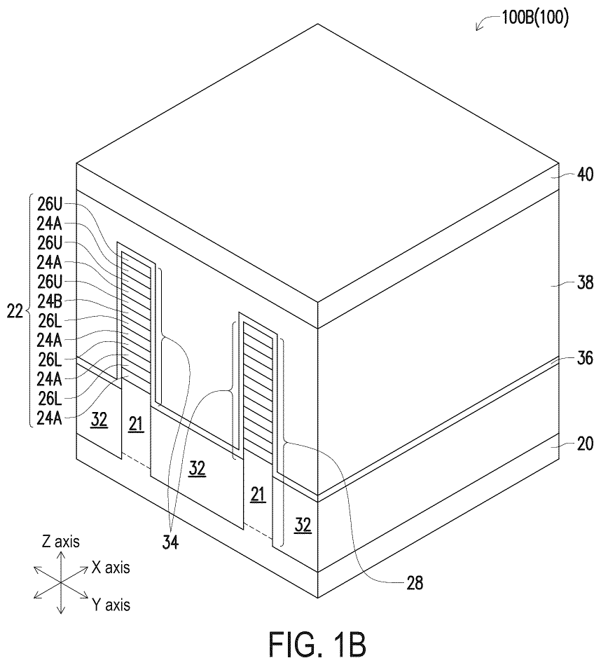

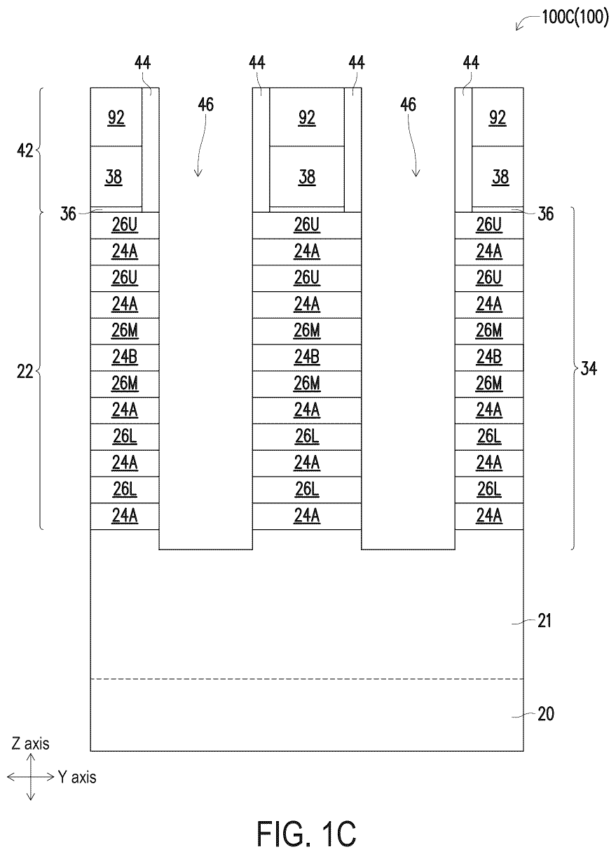

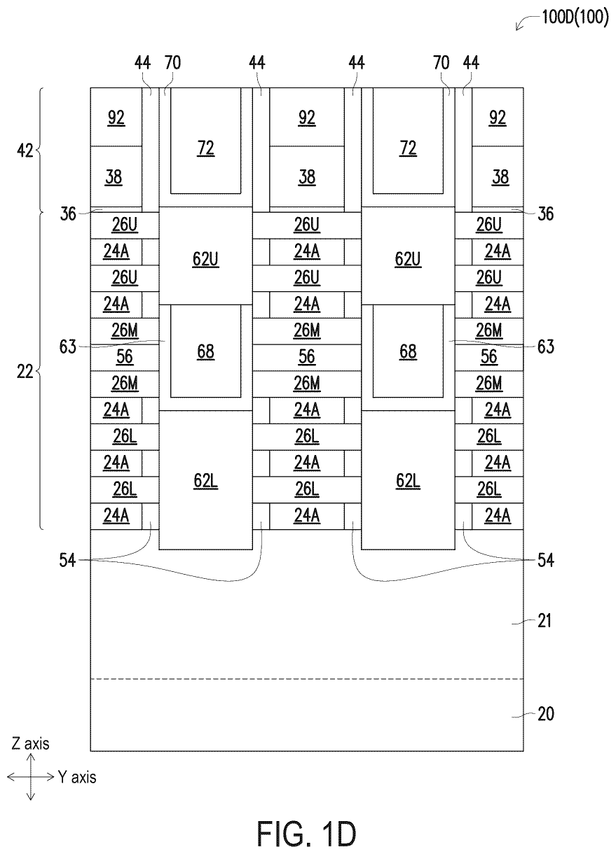

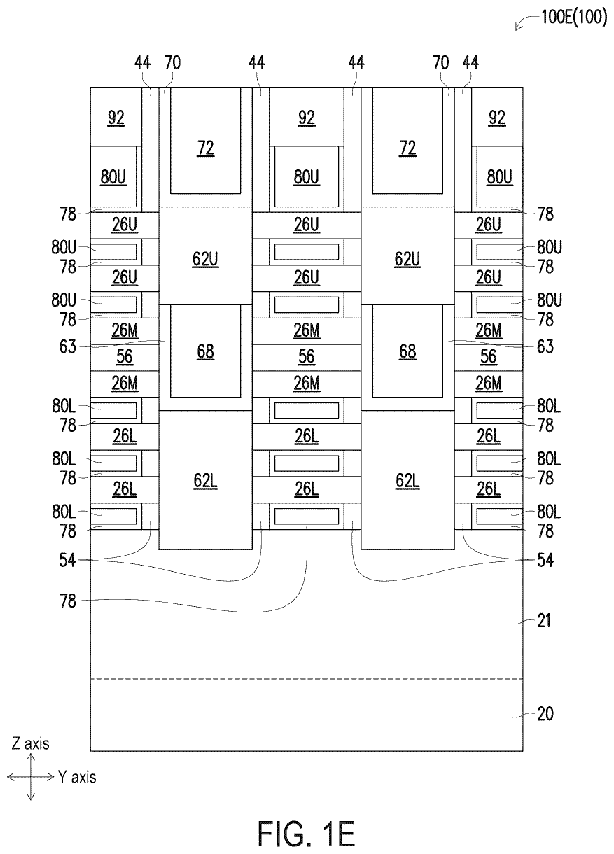

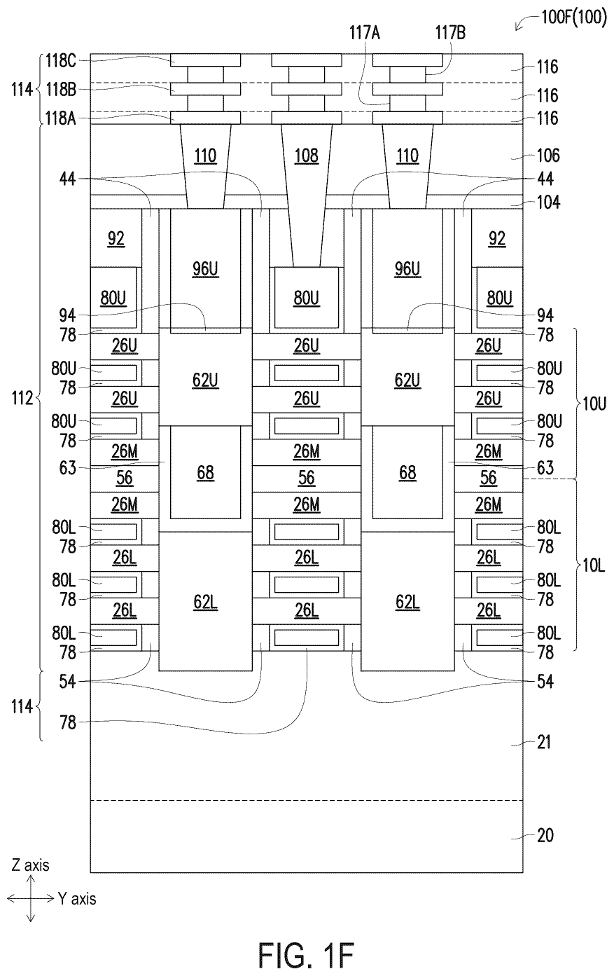

FIG. 1A is a schematic perspective view of a stack of semiconductor devices, or a device stack, 100A, in accordance with some embodiments.

The device stack 100A comprises a stacked structure 10 of a bottom semiconductor device 10L and a top semiconductor device 10U. The bottom semiconductor device 10L is over a substrate. For simplicity, the substrate is not illustrated in FIG. 1A. An example substrate is described with respect to FIGS. 1B-IF. The top semiconductor device 10U is physically stacked over the bottom semiconductor device 10L in a thickness direction of the substrate. The thickness direction is designated as a Z axis in FIG. 1A. In the example configuration in FIG. 1A, the top semiconductor device 10U and the bottom semiconductor device 10L are of different conductivity types. Other configurations where both top semiconductor device 10U and bottom semiconductor device 10L are of the same conductivity type are within the scopes of various embodiments. Conductivity type is sometimes referred to as semiconductor type. Examples of conductivity type include N-type and P-type. In an example, the top semiconductor device 10U is an N-type semiconductor device, the bottom semiconductor device 10L is a P-type semiconductor device, and the stacked structure 10 is referred to as an N-on-P structure. In another example, the top semiconductor device 10U is a P-type semiconductor device, the bottom semiconductor device 10L is an N-type semiconductor device, and the stacked structure 10 is referred to as a P-on-N structure. For simplicity, various example embodiments described herein include N-on-P structures. One or more features, functions and/or advantages of embodiments with N-on-P structures are applicable to and/or achievable in embodiments with P-on-N structures.

Examples of semiconductor devices include, but are not limited to, metal oxide semiconductor field effect transistors (MOSFET), complementary metal oxide semiconductors (CMOS) transistors, P-channel metal-oxide semiconductors (PMOS), N-channel metal-oxide semiconductors (NMOS), bipolar junction transistors (BJT), high voltage transistors, high frequency transistors, P-channel and/or N-channel field effect transistors (PFETs/NFETs), FinFETs, planar MOS transistors with raised source/drains, nanosheet FETs, nanowire FETs, or the like. In the example configuration in FIG. 1A, the top semiconductor device 10U and bottom semiconductor device 10L are nanosheet FETs. Other semiconductor device configurations are within the scopes of various embodiments. In some embodiments, the top semiconductor device 10U and bottom semiconductor device 10L have different semiconductor device configurations. For example, the bottom semiconductor device 10L is a planar MOS transistor whereas the top semiconductor device 10U is a nanosheet FET.

The top semiconductor device 10U comprises a gate 80U, and source/drains 62U on opposite sides of the gate 80U along an X axis. The gate 80U extends, or is elongated, along a Y axis. The X axis, Y axis, Z axis are mutually transverse to each other. In some embodiments, the X axis, Y axis, Z axis are mutually perpendicular to each other. The top semiconductor device 10U further comprises a channel region configured by nanosheets 26U which extend along the X axis and connect the source/drains 62U. In the example configuration in FIG. 1A, the top semiconductor device 10U comprises two nanosheets 26U. Other numbers of nanosheets per transistor are within the scopes of various embodiments. The top semiconductor device 10U comprises a gate dielectric layer 78 extending around each of the nanosheets 26U, and electrically isolating the gate 80U from the nanosheets 26U. The gate 80U extends around the gate dielectric layer 78 and nanosheets 26U in a configuration referred to as a gate-all-around (GAA) configuration. Other gate configurations are within the scopes of various embodiments.

The bottom semiconductor device 10L comprises a gate 80L, source/drains 62L, a channel region configured by nanosheets 26L, and a gate dielectric layer 78 extending around each of the nanosheets 26L. The gate 80L, source/drains 62L, and nanosheets 26L correspond to the gate 80U, source/drains 62U, and nanosheets 26U. The gate 80U, source/drains 62U, and nanosheets 26U correspondingly overlap the gate 80L, source/drains 62L, and nanosheets 26L along the Z axis. In the example configuration in FIG. 1A, the source/drains 62U, 62L are epitaxy structures of different conductivity types. For example, the source/drains 62L are P-type epitaxy structures, and the source/drains 62U are N-type epitaxy structures.

The stacked structure 10 further comprises an intermediate layer 90 between the gate 80U and gate 80L. In some embodiments, the intermediate layer 90 is a dielectric layer electrically isolating the gate 80U from the gate 80L, in a configuration referred to as an isolated gate configuration in which the gate 80U and gate 80L are controllable independently from each other. In at least one embodiment, the gate 80U and the gate 80L in an isolated gate configuration are still electrically coupled to each other by a conductor, e.g., a gate local interconnect (MGLI). In some embodiments, the intermediate layer 90 is a conductive layer electrically coupling the gate 80U to the gate 80L, in a configuration referred to as a connected gate configuration in which the electrically coupled gate 80U and gate 80L form a common gate for both top semiconductor device 10U and bottom semiconductor device 10L. In a connected gate configuration in accordance with some embodiments, the conductive intermediate layer 90 is formed integrally, and/or simultaneously, with the gate 80U and gate 80L in a single GAA structure.

As can be seen from FIG. 1A, in one or more embodiments, the stacking of the top semiconductor device 10U over the bottom semiconductor device 10L saves about 50% of the required chip area, compared to other approaches without stacking of semiconductor devices. In some embodiments, it is possible to manufacturing an IC device comprising multiple device stacks by CFET processes, with little or no changes to the manufacturing processes.

FIG. 1B is a schematic perspective view, and FIGS. 1C-IF are schematic cross-sectional views, in an X-Z plane, of an IC device 100 at various stages in a manufacturing process, in accordance with some embodiments. The IC device 100 comprises a plurality of device stacks corresponding to the device stack 100A. For simplicity, corresponding components in FIGS. 1A-IF are designated by the same reference numerals. In some embodiments, additional operations are provided before, during, and/or after the manufacturing process described with respect to FIGS. 1B-IF, and/or one or more of the described operations are replaced or eliminated, and or the order of the operations is interchangeable.

Referring to FIG. 1B, the manufacturing process starts from a substrate 20. In at least one embodiment, the substrate 20 is a semiconductor substrate. In some embodiments, the substrate 20 includes a single crystalline semiconductor layer on at least the surface of the substrate 20. Example materials of the substrate 20 include, but are not limited to, silicon (Si), germanium (Ge), silicon germanium (SiGe), gallium arsenide (GaAs), indium antimonide (InSb), gallium phosphide (GaP), gallium antimonide (GaSb), indium aluminum arsenide (InAlAs), indium gallium arsenide (InGaAs), gallium antimony phosphide (GaSbP), gallium arsenic antimonide (GaAsSb) and indium phosphide (InP). For example, the substrate 20 is a Si substrate. In some embodiments, the substrate 20 is a silicon-on-insulator (SOI) substrate, which includes an insulating layer disposed between two silicon layers. In at least one embodiment, the insulating layer is an oxide layer.

A multilayer structure 22 is formed over the substrate 20. In FIG. 1B, the multilayer structure 22 is illustrated in a state after formation of fins, as described herein. The multilayer structure 22 comprises alternatingly arranged first semiconductor layers 24A, 24B and second semiconductor layers 26U, 26L. The second semiconductor layers 26U, 26L correspond to the nanosheets described with respect to FIG. 1A, and are referred to herein by the same reference numerals of the nanosheets, for simplicity. The first semiconductor layers 24A, 24B and the second semiconductor layers 26U, 26L comprise semiconductor materials having different etch selectivity and/or oxidation rates. For example, the first semiconductor layers 24A, 24B comprise SiGe, and the second semiconductor layers 26U, 26L comprise Si. In some embodiments, the first and second semiconductor layers 24A, 24B, 26U, 26L are formed by a deposition process, such as epitaxy. For example, epitaxial growth of the layers of the multilayer structure 22 is performed by a molecular beam epitaxy (MBE) process, a metalorganic chemical vapor deposition (MOCVD) process, and/or other suitable epitaxial growth processes.

Subsequent to the formation of the multilayer structure 22, fins 28 are formed. Each fin 28 comprises a substrate portion 21 of the substrate 20, and a portion 34 of the multilayer structure 22. The portion 34 of the multilayer structure 22 is sometimes referred to as a stack of semiconductor layers 34. In some embodiments, the fins 28 are fabricated using suitable processes, such as double-patterning or multi-patterning processes. For example, in one or more embodiments, a sacrificial layer is formed over a substrate and patterned using a photolithography process. Spacers are formed alongside the patterned sacrificial layer using a self-aligned process. The sacrificial layer is then removed, and the remaining spacers are then used to pattern the fins 28 by etching the multilayer structure 22 and the substrate 20. Example etch processes include, but are not limited to, dry etch, wet etch, reactive ion etch (RIE), and/or other suitable processes. In FIG. 1B, two fins 28 are illustrated; however, the number of the fins is not limited to two. The fins 28 extend, or are elongated, along the X axis.

A shallow trench isolation (STI) 32 of an insulating material is formed over the substrate 20 and in trenches (not numbered) between the fins 28. For example, the insulating material is deposited over the substrate 20 and the fins 28. Example insulating materials of the STI 32 include, but are not limited to, silicon oxide, fluorine-doped silicate glass (FSG), silicon nitride, silicon oxynitride (SiON), SiOCN, SiCN, a low-k dielectric material, or the like. The deposition of the insulating material includes a suitable method, such as low-pressure chemical vapor deposition (LPCVD), plasma enhanced CVD (PECVD) or flowable CVD (FCVD). Then, a planarization operation, such as a chemical mechanical polishing (CMP) process and/or an etch-back process, is performed such that the tops of the fins 28 are exposed from the insulating material. A portion of the insulating material between adjacent fins 28 is removed. The remaining portion of the insulating material configures the STI 32. The partial removal of the insulating material includes dry etch, wet etch, or the like.

A sacrificial gate dielectric layer 36, a sacrificial gate electrode layer 38, and a mask structure 40 are deposited over the STI 32 and fins 28. The sacrificial gate dielectric layer 36 comprises one or more layers of dielectric material, such as SiO2, SiN, a high-k dielectric material, and/or other suitable dielectric material. In some embodiments, the sacrificial gate dielectric layer 36 is deposited by a CVD process, a sub-atmospheric CVD (SACVD) process, a FCVD process, an atomic layer deposition (ALD) process, a physical vapor deposition (PVD) process, or other suitable process. In at least one embodiment, the sacrificial gate electrode layer 38 comprises polycrystalline silicon (polysilicon). In some embodiments, the mask structure 40 comprises a multilayer structure. In some embodiments, the sacrificial gate electrode layer 38 and the mask structure 40 are formed by one or more processes such as layer deposition, for example, CVD (including both LPCVD and PECVD), PVD, ALD, thermal oxidation, e-beam evaporation, or other suitable deposition techniques. A structure 100B is obtained.

Referring to FIG. 1C, sacrificial gate stacks 42 are formed by one or more pattern and/or etch processes performed on the deposited sacrificial gate dielectric layer 36, sacrificial gate electrode layer 38, and mask structure 40 of the structure 100B. An example pattern process comprises a lithography process. An example etch process comprises dry etch (e.g., RIE), wet etch, other etch methods, and/or combinations thereof. Each sacrificial gate stack 42 comprises a portion of each of the sacrificial gate dielectric layer 36, sacrificial gate electrode layer 38, and mask structure 40. The sacrificial gate stacks 42 extend, or are elongated, along the Y axis. In FIG. 1C, three sacrificial gate stacks 42 are illustrated; however, the number of the sacrificial gate stacks 42 is not limited to two.

Spacers 44 are formed on sidewalls of the sacrificial gate stacks 42. For example, the spacers 44 are formed by first depositing a conformal layer that is subsequently etched back to form the spacers 44. The spacers 44 comprises a dielectric material, such as silicon oxide, silicon nitride, silicon carbide, silicon oxynitride, SiCN, silicon oxycarbide, SiOCN, and/or combinations thereof. In some embodiments, the spacers 44 comprise multiple layers.

Exposed portions of the stacks of semiconductor layers 34 of the fins 28 not covered by the sacrificial gate stacks 42 and the spacers 44 are selectively removed, e.g., by one or more suitable etch processes, such as dry etch, wet etch, or a combination thereof, to form trenches 46. In FIG. 1C, a lower most one of the second semiconductor layers 26U and an uppermost one of the second semiconductor layers 26L are designated as middle second semiconductor layers 26M which sandwich therebetween a middle first semiconductor layer 24B. The middle second semiconductor layers 26M and the middle first semiconductor layer 24B are not configured to form channel regions of the top semiconductor device 10U and bottom semiconductor device 10L. Edge portions of the first semiconductor layers 24A, 24B and second semiconductor layers 26U, 26L, 26M are exposed in the trenches 46. The trenches 46 also expose portions of the substrate portion 21. A structure 100C is obtained.

Referring to FIG. 1D, the exposed edge portions of the first semiconductor layers 24A are removed. In some embodiments, the removal comprises a selective wet etch process. The selective wet etch process further completely (or substantially completely) removes the first semiconductor layer 24B in the middle of the stack of semiconductor layers 34. For example, in embodiments where the first semiconductor layers 24A, 24B comprise SiGe, and the second semiconductor layers 26U, 26L, 26M comprise Si, a selective wet etch is configured to etch the first semiconductor layer 24B at a highest etch rate, the first semiconductor layers 24A at a second highest etch rate, and the second semiconductor layers 26U, 26L, 26M at a slowest etch rate. As a result, the exposed edge portions of the first semiconductor layers 24A and an entirety (or substantially an entirety) of the first semiconductor layer 24B are removed, whereas the second semiconductor layers 26U, 26L, 26M are substantially unchanged.

A dielectric material is deposited over and into the spaces created by the removal of the first semiconductor layer 24B and the partial removal of the edge portions of the first semiconductor layers 24A. The dielectric material filling in the spaces created by the partial removal of the edge portions of the first semiconductor layers 24A configures inner spacers 54. The dielectric material filling in the space created by the removal of the first semiconductor layer 24B configures an inner isolation structure 56. Examples of the dielectric material forming the inner spacers 54 and inner isolation structure 56 include, but are not limited to, a low-k dielectric material, such as SiO2, SiN, SiCN, SiOC, or SiOCN, or a high-k dielectric material, such as HfO2, ZrOx, ZrAlOx, HfAlOx, HfSiOx, AlOx, or other suitable dielectric material. In some embodiments, the inner spacers 54 and inner isolation structure 56 comprise different dielectric materials. In an example process, the inner spacers 54 and inner isolation structure 56 are formed by depositing a conformal layer of the dielectric material, using a conformal deposition process, such as ALD, followed by an anisotropic etching to remove portions of the conformal layer other than the inner spacers 54 and inner isolation structure 56.

Source/drain 62L are formed over, and in contact with, the exposed portions of the substrate portions 21, and exposed edge portions of the second semiconductor layers 26L. In the example configuration in FIG. 1D, the source/drains 62L comprise epitaxy structures and are sometimes referred to as source/drain epitaxy structures 62L. In some embodiments, the source/drain epitaxy structures 62L comprise one or more layers of Si, SiGe, Ge to configure a P-type bottom semiconductor device. Example epitaxial growth processes for growing the source/drain epitaxy structures 62L include, but are not limited to, CVD, ALD, MBE. In some embodiments, source/drain epitaxy structures 62L are grown to a height above the uppermost second semiconductor layer 26L, and then top portions of the source/drain epitaxy structures 62L are partially removed, e.g., by a dry etch or wet etch, so that upper surfaces of the remaining source/drain epitaxy structures 62L are at a level of the uppermost first semiconductor layer 24A immediately under the lower middle second semiconductor layer 26M, as illustrated in FIG. 1D.

A liner 63 is formed at least over the upper surfaces of the source/drain epitaxy structures 62L, and exposed side faces of the middle second semiconductor layers 26M, inner isolation structure 56. In some embodiments, the liner 63 comprises Si. In an example process, the liner 63 is a conformal layer formed by a conformal process, such as an ALD process.

A dielectric material 68 is formed over the liner 63 and over the source/drain cpitaxy structures 62L. In some embodiments, the dielectric material 68 comprises the same material as the STI 32 and/or is formed by the same method as the STI 32. The liner 63 and dielectric material 68 are removed outside the trenches 46, and partially removed inside the trenches 46, e.g., by a dry etch or wet etch. As a result, upper surfaces of the liner 63 and dielectric material 68 are at a level of the lowermost first semiconductor layer 24A immediately above the upper middle second semiconductor layer 26M, as illustrated in FIG. 1D. The liner 63 and dielectric material 68 configure an isolation structure between the source/drain 62L and source/drains 62U to be subsequently formed thereover.

Source/drain 62U are formed over, and in contact with, the upper surfaces of the liner 63 and dielectric material 68, and exposed edge portions of the second semiconductor layers 26U. In the example configuration in FIG. 1D, the source/drains 62U comprise epitaxy structures and are sometimes referred to as source/drain epitaxy structures 62U. The source/drain epitaxy structures 62U are of a conductivity type different from that of the source/drain epitaxy structures 62L. In some embodiments, the source/drain epitaxy structures 62U are manufactured by the same or similar manufacturing processes as/to the source/drain epitaxy structures 62L. In at least one embodiment, the source/drain epitaxy structures 62U have the same configuration, e.g., the same size, shape, height, as the source/drain epitaxy structures 62L. In an example, the source/drain epitaxy structures 62U comprise one or more layers of Si, SiP, SiC and SiCP to configure an N-type top semiconductor device. In some embodiments, source/drain epitaxy structures 62U are grown to a height above the sacrificial gate dielectric layer 36, and then top portions of the source/drain epitaxy structures 62U are partially removed, e.g., by a dry etch or wet etch, so that upper surfaces of the remaining source/drain epitaxy structures 62U are at a level of the sacrificial gate dielectric layer 36, as illustrated in FIG. 1D. This is an example, and a height of the source/drain epitaxy structures 62U is controllable depending on application and/or process requirements.

A contact etch stop layer (CESL) 70 is formed over the source/drain epitaxy structures 62U. Example materials of the CESL 70 include, but are not limited to, silicon nitride, silicon carbon nitride, silicon oxynitride, carbon nitride, silicon oxide, silicon carbon oxide, the like, or a combination thereof. The CESL 70 is formed by CVD, PECVD, ALD, or any suitable deposition technique.

An interlayer dielectric (ILD) layer 72 is formed over the CESL 70. Example materials of the ILD layer 72 include, but are not limited to, tetraethylorthosilicate (TEOS) oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials. The ILD layer 72 is deposited by a PECVD process or other suitable deposition technique. A structure 100D is obtained.

Referring to FIG. 1E, a planarization process, such as a CMP process, is performed to remove the mask structure 40 and expose the sacrificial gate electrode layer 38. The planarization process also removes portions of the ILD layer 72 and the CESL 70.

The exposed sacrificial gate electrode layer 38 and the sacrificial gate dielectric layer 36 are removed, e.g., by one or more suitable processes, such as dry etch, wet etch, or a combination thereof.

Next, the first semiconductor layers 24A are removed, e.g., by any suitable processes, such as dry etch, wet etch, or a combination thereof. The removal of the first semiconductor layers 24A exposes the inner spacers 54 and the second semiconductor layers 26U, 26L, and creates spaces between and around exposed portions of the second semiconductor layers 26U, 26L not covered by the inner spacers 54. The exposed portions of the second semiconductor layers 26U, 26L configure the nanosheets 26U, 26L described with respect to FIG. 1A. The middle second semiconductor layers 26M and inner isolation structure 56 are covered by the liner 63 and dielectric material 68, and are substantially unaffected by the removal of the first semiconductor layers 24A.

A gate dielectric layer 78 is formed over and around each of the nanosheets 26U, 26L. In some embodiments, the gate dielectric layer 78 comprises the same material as the sacrificial gate dielectric layer 36. In some embodiments, the gate dielectric layer 78 comprises a high-k dielectric material. In some embodiments, the gate dielectric layer 78 is formed by a conformal process, such as an ALD process.

A gate electrode material is formed over and around the gate dielectric layers 78, and the nanosheets 26U, 26L. The gate electrode material surrounding each of the nanosheets 26U configures the gate 80U. The gate electrode material surrounding each of the nanosheets 26L configures the gate 80L. In some embodiments, the gate electrode material comprises multiple gate electrode layers. Example gate electrode materials include, but are not limited to, polysilicon, aluminum, copper, titanium, tantalum, tungsten, cobalt, molybdenum, tantalum nitride, nickel silicide, cobalt silicide, TiN, WN, WCN, TiAl, TiTaN, TiAlN, TaN, TaCN, TaC, TaSiN, metal alloys, other suitable materials, and/or combinations thereof. In some embodiments, the gate electrode material comprises a P-type gate electrode layer, such as TIN, TaN, TiTaN, TiAIN, WCN, W, Ni, Co, or other suitable material, for configuring P-type bottom semiconductor devices. In at least one embodiment, the gate electrode material comprises an N-type gate electrode layer, such as TiAlC, TaAlC, TiSiAlC, TiC, TaSiAlC, or other suitable material, for configuring N-type top semiconductor devices. Example processes for depositing the gate electrode material include, but are not limited to, PVD, CVD, ALD, electro-plating, or other suitable methods.

In some embodiments, each of the gate 80U and gate 80L comprises a corresponding GAA structure, and the gate 80U and gate 80L are physically and electrically separated from each other by the middle second semiconductor layers 26M and inner isolation structure 56. In some embodiments, a combination of the middle second semiconductor layers 26M and inner isolation structure 56 corresponds to the intermediate layer 90 being a dielectric material in an isolated gate configuration. In at least one embodiment, the gate 80U and the gate 80L in an isolated gate configuration are still electrically coupled to each other by a conductor, e.g., an MGLI interconnect. In some embodiments, the gate 80U and gate 80L are integral parts of a GAA structure which extends around each of the nanosheets 26U, 26L, and configures a common gate for both top semiconductor device and bottom semiconductor device. The formation of the gate 80U and gate 80L completes the formation of the top semiconductor device 10U and bottom semiconductor device 10L. An ILD layer 92 similar to the ILD layer 72 is deposited over the gate 80U, and a planarization process, such as a CMP, is performed. A structure 100E is obtained.

Referring to FIG. 1F, openings are formed in the ILD layer 72 to expose the source/drain epitaxy structures 62U. A silicide layer 94 is formed over the exposed source/drain epitaxy structures 62U, and then source/drain contacts 96U are form in each opening and over the silicide layer 94. Source/drain contacts (or source/drain contact structures) are sometimes referred to as metal-to-device (MD) contacts. Source/drain contacts of top semiconductor devices are sometimes referred to as MD contacts or top contact structures. Source/drain contacts of bottom semiconductor devices are sometimes referred to as BMD contacts or bottom contact structures. For simplicity, an MD contact, or a contact structure, herein refers to either an MD contact at the upper layer or a BMD contact at the lower layer, unless specified otherwise. Example materials of the source/drain contacts 96U include, but are not limited to, Ru, Mo, Co, Ni, W, Ti, Ta, Cu, Al, TiN and TaN. The source/drain contacts 96U are formed by any suitable process, such as PVD, ECP, or CVD.

Dielectric layers 104, 106 are deposited over the MD contacts 96U and ILD layer 92. Various vias 108, 110 are formed by etching via openings in the dielectric layers 104, 106 and ILD layer 92, and then filling the via openings with a conductive material, such as a metal. A via over and in electrical contact with an MD contact is sometimes referred to as via-to-device (VD) via. A via over and in electrical contact with a gate is sometimes referred to as via-to-gate (VG) via. In the example configuration in FIG. 1F, the via 108 is a VG via which is over the gate 80U, and the vias 110 are VD vias correspondingly over the MD contacts 96U. VG and VD vias for bottom semiconductor devices are sometimes correspondingly referred to as BVG and BVD vias.

In some embodiments, the formation of structures up to and including the VG, VD vias completes a front-end-of-line (FEOL) fabrication. A resulting FEOL structure 112 comprising various semiconductor devices formed over a front side (or upper side) of the substrate 20 and the corresponding MD contacts, VG and VD vias is obtained. The FEOL fabrication is followed by a Back End of Line (BEOL) fabrication to provide routing for the semiconductor devices.

The BEOL fabrication comprises forming a redistribution structure 114 over the VD, VG vias 110, 108. The redistribution structure 114 comprises a plurality of metal layers 118A-118C and via layers 117A, 117B sequentially and alternatingly formed over the VD, VG vias 110, 108. The redistribution structure 114 further comprises various interlayer dielectric (ILD) layers 116 in which the metal layers and via layers are embedded. The metal layers and via layers of the redistribution structure 114 are configured to electrically couple various semiconductor devices, or circuits of the IC device 100 with each other, and/or with external circuitry. In the redistribution structure 114, the lowermost metal layer 118A immediately over and in electrical contact with the VD, VG vias 110, 108 is an M0 (metal-zero) layer, a next metal layer 118B immediately over the M0 layer is an M1 layer, a next metal layer 118C immediately over the M1 layer is an M2 layer, or the like. Conductive patterns in the M0 layer are referred to as M0 conductive patterns, conductive patterns in the M1 layer are referred to as M1 conductive patterns, or the like. A via layer Vn is arranged between and electrically couple the Mn layer and the Mn+1 layer, where n is an integer from zero and up. For example, the via layer 117A is a via-zero (V0) layer which is the lowermost via layer arranged between and electrically couple the M0 layer 118A and the M1 layer 118B. The next via layer 117B is a V1 layer which is the via layer arranged between and electrically couple the M1 layer 118B and the M2 layer 118C. Vias in the V0 layer are referred to as V0 vias, vias in the V1 layer are referred to as V1 vias, or the like. For simplicity, metal layers and via layers in the redistribution structure 114 are not fully illustrated in FIG. 1F. The redistribution structure 114 and interconnects therein are formed over the front side of the substrate 20, and are sometimes referred to as the front side redistribution structure and front side interconnects. A structure 100F is obtained, as illustrated in FIG. 1F.

In some embodiments, the fabrication of the IC device 100 further comprises forming various features and/or structures on the back side (e.g., the lower side in FIG. 1F) of the substrate 20. In an example manufacturing process, the structure 100F is flipped over and temporarily bonded to a carrier (not shown). Wafer thinning is performed from the back side (now facing upward) to remove a portion of the substrate 20. For example, as illustrated in FIG. 1F, a substrate portion 130 of the substrate 20 remains as a result of the wafer thinning on the back side. In some embodiments, the wafer thinning process includes a grinding operation, a polishing operation (such as, chemical mechanical polishing (CMP)), or the like. In at least one embodiment, the substrate 20 is completely removed, and a new substrate (not shown), e.g., an insulation substrate, is formed over the bottom semiconductor device 10L. Next, various BMD contacts, BVG vias and BVD vias are formed in manners similar to those correspondingly described with respect to the formation of MD contacts, VG vias and VD vias. A back side redistribution structure is formed, in a manner similar to the redistribution structure 114. The back side redistribution structure comprises various back side metal layers and various back side via layers arranged alternatingly in the thickness direction, i.e., along the Z axis. The back side redistribution structure further comprises various interlayer dielectric (ILD) layers in which the back side metal layers and back side via layers are embedded. The back side metal layer immediately adjacent the bottom semiconductor device 10L is a back side M0 (BM0) layer, a next back side metal layer is a back side M1 (BM1) layer, or the like. A back side via layer BVn is arranged between and electrically couples the BMn layer and the BMn+1 layer, where n is an integer from zero and up. For example, a via layer BV0 is the back side via layer arranged between and electrically couples the BM0 layer and the BM1 layer. Other back side via layers are BV1, BV2, or the like. Conductive patterns in the BM0 layer are referred to as BM0 conductive patterns, conductive patterns in the BM1 layer are referred to as BM1 conductive patterns, or the like. Vias in the BV0 layer are referred to as BV0 vias, vias in the BV1 layer are referred to as BV1 vias, or the like. Although the described manufacturing processes include formation of nanosheet devices in one or more embodiments, other types of devices, e.g., nanowire, FinFET, planar, or the like, are within the scopes of various embodiments. The described manufacturing processes and/or orders of operations are examples. Other manufacturing processes and/or orders of operations are within the scopes of various embodiments.

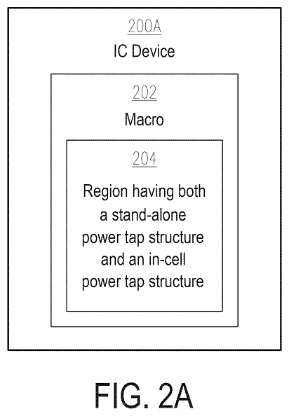

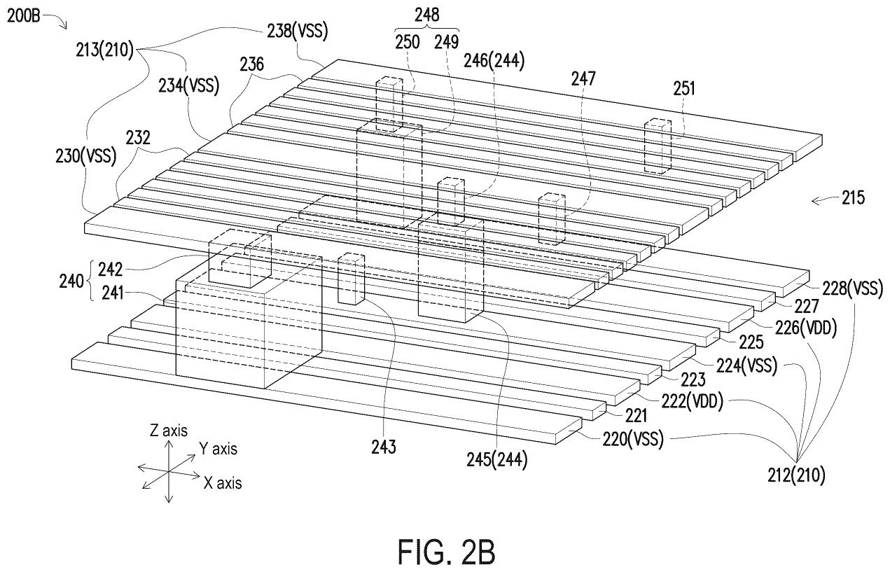

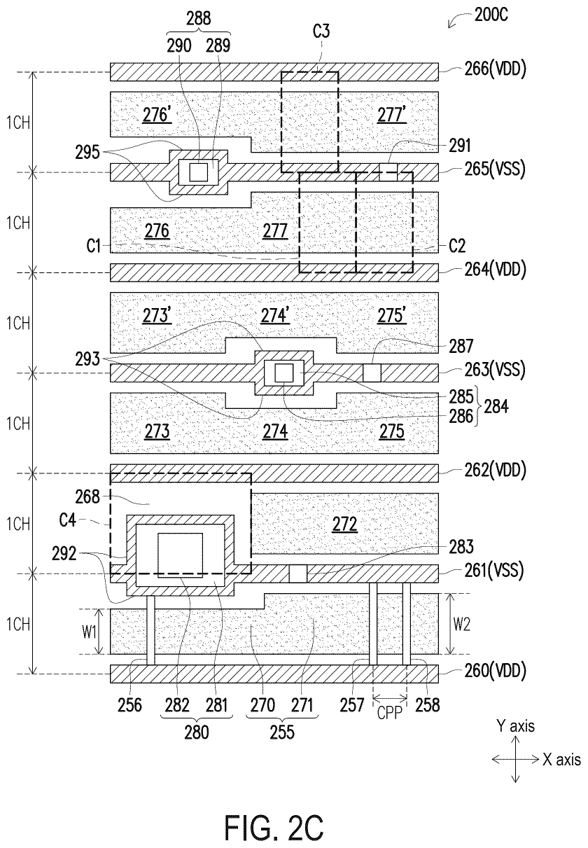

FIG. 2A is a block diagram of an IC device 200A, in accordance with some embodiments.

In FIG. 2A, the IC device 200A comprises, among other things, a macro 202. In some embodiments, the macro 202 comprises one or more of a memory, a power grid, a cell or cells, an inverter, a latch, a buffer and/or any other type of circuit arrangement that may be represented digitally in a cell library. In some embodiments, the macro 202 is understood in the context of an analogy to the architectural hierarchy of modular programming in which subroutines/procedures are called by a main program (or by other subroutines) to carry out a given computational function. In this context, the IC device 200A uses the macro 202 to perform one or more given functions. Accordingly, in this context and in terms of architectural hierarchy, the IC device 200A is analogous to the main program and the macro 202 is analogous to subroutines/procedures. In some embodiments, the macro 202 is a soft macro. In some embodiments, the macro 202 is a hard macro. In some embodiments, the macro 202 is a soft macro which is described digitally in register-transfer level (RTL) code. In some embodiments, synthesis, placement and routing have yet to have been performed on the macro 202 such that the soft macro can be synthesized, placed and routed for a variety of process nodes. In some embodiments, the macro 202 is a hard macro which is described digitally in a binary file format (e.g., Graphic Database System II (GDSII) stream format), where the binary file format represents planar geometric shapes, text labels, other information and the like of one or more layout-diagrams of the macro 202 in hierarchical form. In some embodiments, synthesis, placement and routing have been performed on the macro 202 such that the hard macro is specific to a particular process node.

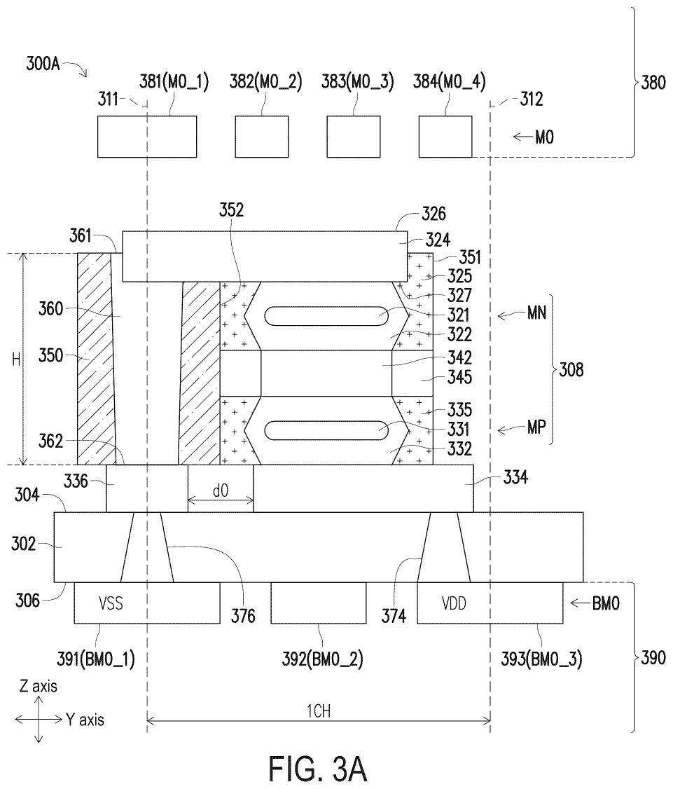

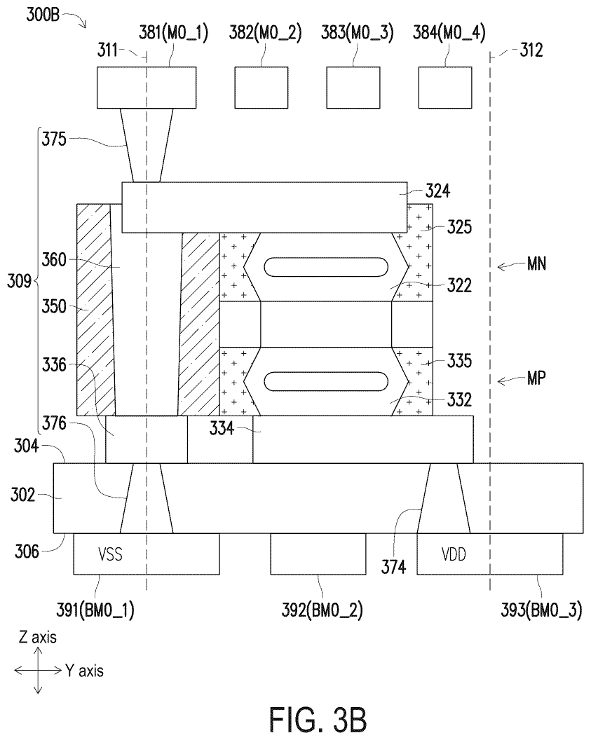

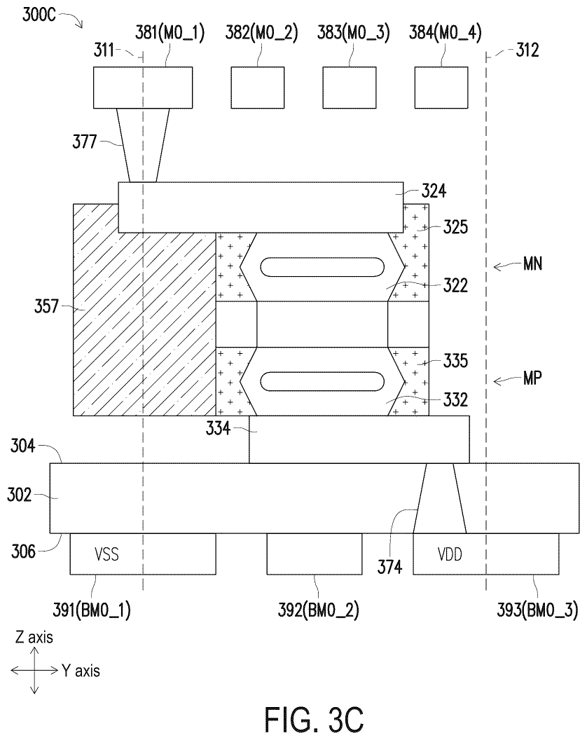

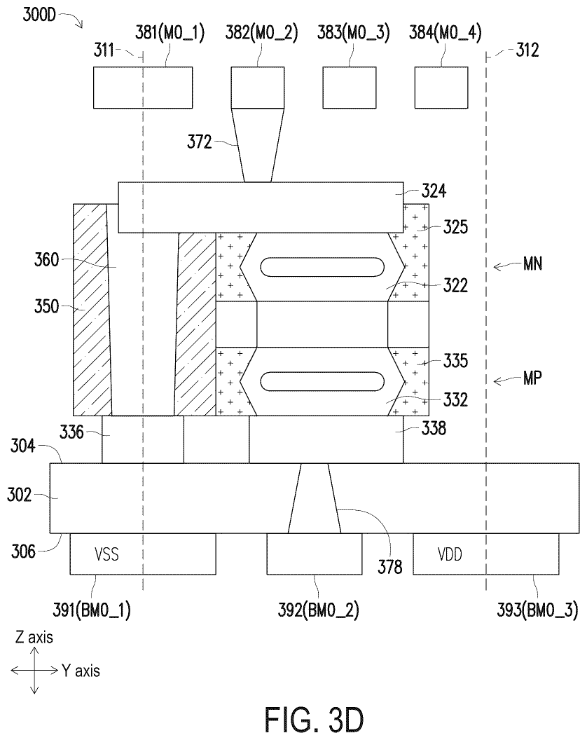

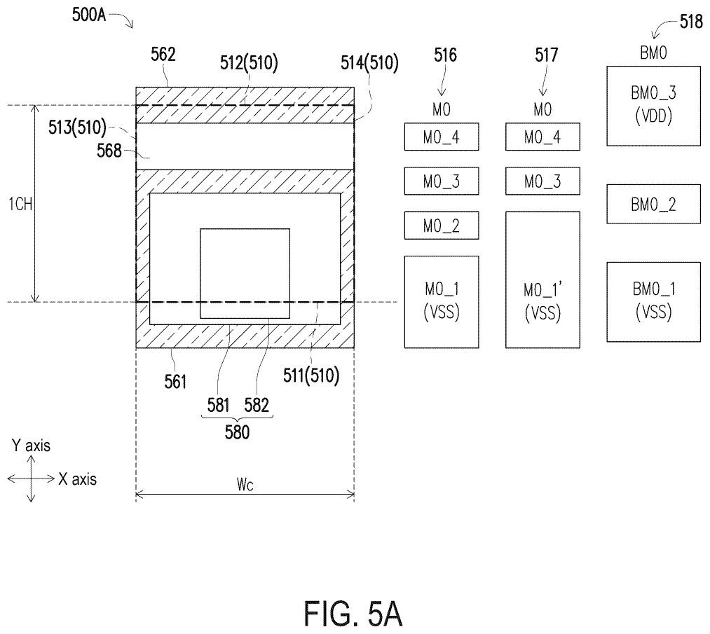

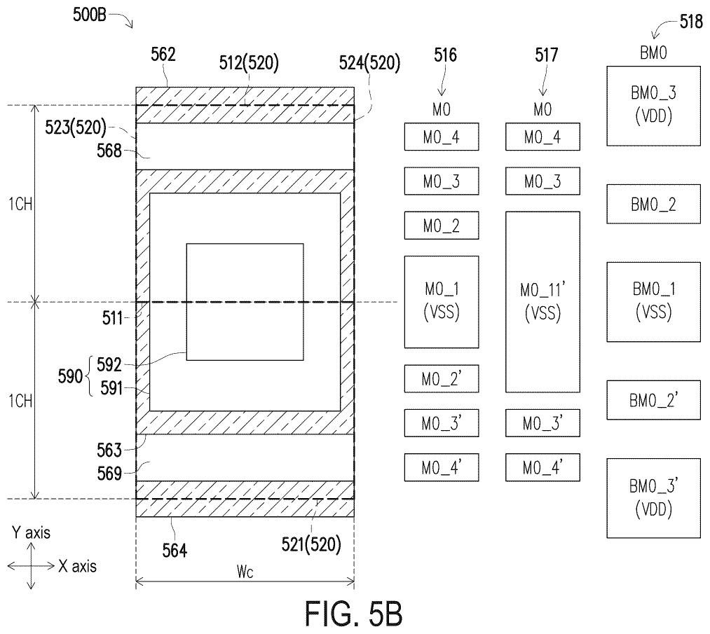

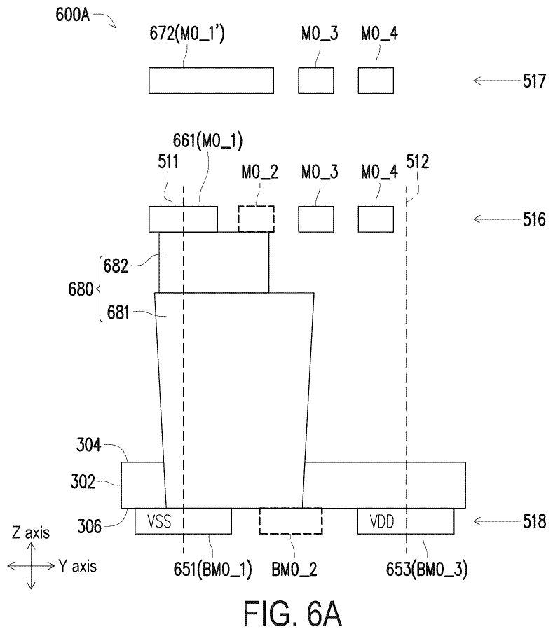

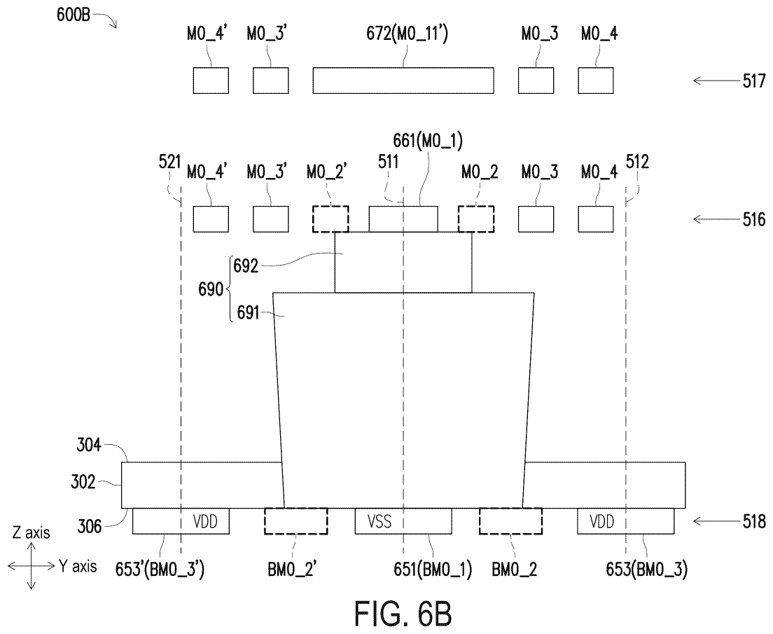

The macro 202 includes a region 204 which comprises both a stand-alone power tap structure and an in-cell power tap structure. Examples of in-cell power tap structures are described with respect to FIG. 3B. Examples of stand-alone power tap structures are described with respect to FIGS. 5A-5B, 6A-6B. In some embodiments, the region 204 comprises a substrate having circuitry formed thereon, in a front-end-of-line (FEOL) fabrication. Furthermore, above and/or below (e.g., on a front side and/or a back side of) the substrate, the region 204 comprises various metal layers that are stacked over and/or under insulating layers in a Back End of Line (BEOL) fabrication. The BEOL provides a power network and/or routing for circuitry of the IC device 200A, including the macro 202 and the region 204.

FIG. 2B is a schematic perspective view of a region of an IC device 200B, in accordance with some embodiments. In at least one embodiment, the IC device 200B corresponds to the IC device 200A and/or includes a circuit region corresponding to the region 204 in FIG. 2A. For simplicity, some components of the IC device 200B are omitted or schematically illustrated in FIG. 2B.

The IC device 200B comprises a power delivery structure 210, and one or more functional circuits 215 (schematically represented by an arrow in FIG. 2B) coupled to and powered by power delivered through the power delivery structure 210. The power delivery structure 210 comprises a back side power delivery network 212 schematically represented by back side power rails 220, 222, 224, 226, 228, a front side power delivery network 213 schematically represented by front side power rails 230, 234, 238, and a plurality of power tap structures schematically represented by a stand-alone power tap structure 240, and in-cell power tap structures 244, 248.

The back side power delivery network 212 and the front side power delivery network 213 are correspondingly arranged on a back side and a front side of the IC device 200B. The front side is opposite to the back side in a thickness direction (e.g., a Z axis) of the IC device 200B. In some embodiments, the front side and back side of the IC device 200B correspond to a front side and a back side of the functional circuits 215, and/or to a front side and a back side of a substrate (not shown) on which the functional circuits 215 are arranged. In at least one embodiment, the front side is one of a first side and a second side, and the back side is the other of the first side and the second side.

The back side power delivery network 212 comprises a plurality of back side metal layers and back side via layers as described herein, and is configured to receive power from a power supply, and deliver the received power to the functional circuits 215. The power supply provides a first power supply voltage, and a second power supply voltage different from the first power supply voltage. A first power rail (not shown) of the back side power delivery network 212 is configured to receive the first power supply voltage from the power supply, and deliver the first power supply voltage through one or more back side metal layers and back side via layers to the back side power rails 220, 224, 228. A second power rail (not shown) of the back side power delivery network 212 is configured to receive the second power supply voltage from the power supply, and deliver the second power supply voltage through one or more back side metal layers and back side via layers to the back side power rails 222, 226. In the example configuration in FIG. 2B, the first power supply voltage is VSS and the second power supply voltage is VDD. Other configurations where the first power supply voltage is VDD and the second power supply voltage is VSS within the scopes of various embodiments. Power rails configured to receive and deliver VSS are sometimes referred to herein as VSS power rails, and power rails configured to receive and deliver VDD are sometimes referred to herein as VDD power rails. For example, the back side power rails 220, 224, 228 are referred to herein as back side VSS power rails 220, 224, 228 or VSS power rails 220, 224, 228, and the back side power rails 222, 226 are referred to herein as back side VDD power rails 222, 226 or VDD power rails 222, 226. In each metal layer, multiple VSS power rails and multiple VDD power rails are alternatingly arranged in a direction transverse to a lengthwise direction of the VSS power rails and VDD power rails. For example, the VSS power rails 220, 224, 228 and the VDD power rails 222, 226 are in the BM0 layer, and are alternatingly arranged in a direction (e.g., a Y axis) transverse to a lengthwise direction (e.g., an X axis) of the VSS power rails 220, 224, 228 and VDD power rails 222, 226. Among the alternatingly arranged VSS power rails 220, 224, 228 and VDD power rails 222, 226, two immediately adjacent power rails are arranged, along the Y axis, at a center-to-center interval of 1 CH (cell height) described with respect to FIG. 2C. Two power rails are considered immediately adjacent (or directly adjacent) where there are no other power rails therebetween. For example, the VSS power rail 220 is immediately adjacent to VDD power rail 222, and is arranged at a center-to-center interval of 1 CH from the VDD power rail 222. In at least one embodiment, the Y axis is perpendicular to the X axis.

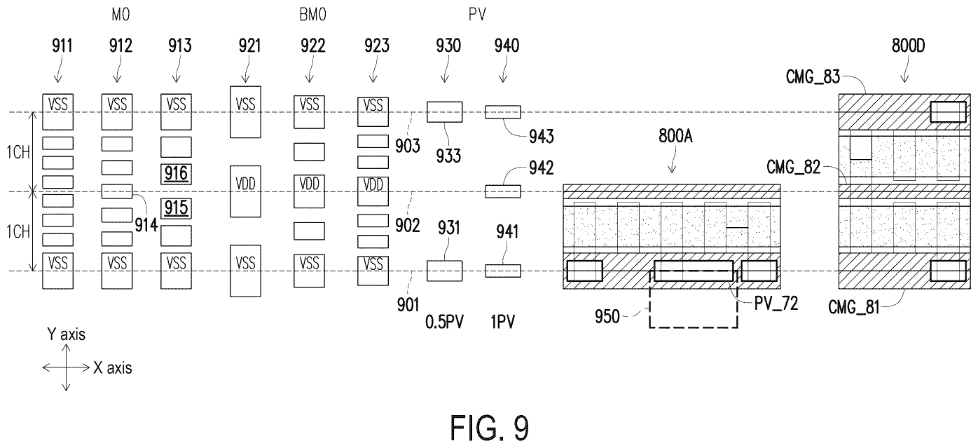

In the example configuration in FIG. 2B, the BM0 layer further comprises a signal track between two immediately adjacent power rails. For example, a signal track 221 is between the immediately adjacent VSS power rail 220 and VDD power rail 222. The BM0 layer further includes signal tracks 223, 225, 227 each arranged between a corresponding pair of immediately adjacent power rails. One or more disconnected metal patterns (not shown) are arranged along each of the signal tracks 221, 223, 225, 227 for signal transmission. The described number of one signal track between a pair of immediately adjacent power rails in the BM0 layer is an example. In some embodiments, zero or more than one signal tracks are arranged between a pair of immediately adjacent power rails, for example, as described with respect to FIG. 9.

The front side power delivery network 213 comprises at least front side power rails 230, 234, 238 in the M0 layer. The front side power rails 230, 234, 238 are configured to carry the first power supply voltage. In the example configuration in FIG. 2B, the first power supply voltage is VSS, and the front side power rails 230, 234, 238 are VSS power rails 230, 234, 238. In some embodiments, the front side power delivery network 213 further comprises other front side metal layers, such as, M1, M2, or the like, and front side via layers, such as V0, V1, or the like. Each VSS power rail in the in the M0 layer is electrically coupled, by one or more power tap structures, to a corresponding VSS power rail in the BM0 layer. For example, the VSS power rail 230 is electrically coupled to by the power tap structure 240 to the VSS power rail 220, the VSS power rail 234 is electrically coupled to by the power tap structure 244 to the VSS power rail 224, the VSS power rail 238 is electrically coupled to by the power tap structure 248 to the VSS power rail 228. As a result, VSS is delivered from the VSS power rails 220, 224, 228 on the back side to the VSS power rails 230, 234, 238 on the front side. In some embodiments, center lines of the VSS power rails 220, 224, 228 on the back side correspondingly coincides, along the Z axis, with center lines of the VSS power rails 230, 234, 238 on the front side. The VSS power rails 230, 234, 238 are arranged, along the Y axis, at a center-to-center interval of 2 CH.

In the example configuration in FIG. 2B, the M0 layer further comprises six signal tracks between two immediately adjacent power rails. For example, six signal tracks 232 (commonly designated with the same reference numeral) are arranged between the immediately adjacent VSS power rails 230, 234, and six further signal tracks 236 (commonly designated with the same reference numeral) are arranged between the immediately adjacent VSS power rails 234, 238. One or more disconnected metal patterns (not shown) are arranged along each of the signal tracks 232, 236 for signal transmission. The described number of six signal tracks between a pair of immediately adjacent power rails in the M0 layer is an example. Other numbers of signal tracks are within the scopes of various embodiments, for example, as described with respect to FIG. 9.

The functional circuits 215 configured to perform one or more functions of the IC device 200B are arranged between the back side power delivery network 212 and front side power delivery network 213 in the thickness direction (e.g., along the Z axis) of the IC device 200B. In some embodiments, the functional circuits 215 comprise one or more active devices, passive devices, logic circuits, or the like. Examples of logic circuits include, but are not limited to, AND, OR, NAND, NOR, XOR, INV, AND-OR-Invert (AOI), OR-AND-Invert (OAI), MUX, Flip-flop, BUFF, Latch, delay, clock, memory, or the like. Example memory cells include, but are not limited to, a static random access memory (SRAM), a dynamic RAM (DRAM), a resistive RAM (RRAIVI), a magnetoresistive RAM (MRAM), a read only memory (ROM), or the like. Examples of active devices or active elements include, but are not limited to, transistors, diodes, or the like. Examples of passive elements include, but are not limited to, capacitors, inductors, fuses, resistors, or the like. In some embodiments, a functional circuit of an IC device corresponds to a functional cell, or a set of functional cells, placed in a layout of the IC device, as described herein.

The functional circuits 215 are electrically coupled to and powered by VDD and VSS supplied from the back side power delivery network 212 and front side power delivery network 213. In some embodiments, the functional circuits 215 comprise CFET devices having an N-on-P structure, i.e., with N-type top semiconductor device stacked over corresponding P-type bottom semiconductor devices. The P-type bottom semiconductor devices are powered by VDD supplied from below, i.e., from the VDD power rails 222, 226. The N-type top semiconductor devices are powered by VSS supplied from below, i.e., from the VSS power rails 220, 224, 228, and/or from above, i.e., from the VSS power rails 230, 234, 238. In the example configuration in FIG. 2B, some N-type top semiconductor devices are powered by VSS supplied from above through via-to-rail (VR) vias 243, 247, 251 correspondingly under and electrically coupled to the VSS power rails 230, 234, 238. In some embodiments, an N-type top semiconductor device is powered by VSS supplied from below through a via interconnect, e.g., as described with respect to FIGS. 3A, 3B. In some embodiments where the functional circuits 215 comprise CFET devices having a P-on-N structure, N-type bottom semiconductor devices are powered by VDD supplied from below, whereas P-type top semiconductor devices are powered by VSS supplied from below and/or from above.

The power tap structures 240, 244, 248 comprise a combination of one or more in-cell power tap structures and one or more stand-alone power tap structures. For example, the power tap structures 244, 248 are in-cell power tap structures each incorporated in a standard cell, e.g., a functional cell corresponding to a functional circuit among the functional circuits 215. The power tap structure 240 is a stand-alone power tap structure not embedded in a functional cell. Instead, the power tap structure 240 corresponds to a power tap cell which is a standard cell specifically configured for power delivery. In at least one embodiment, a power tap cell is not configured for any function other than power delivery.

The power tap structure 240 comprises a via interconnect 241 and a VR via 242. The via interconnect 241 is over and electrically coupled, either directly or through one or more additional conductive features, to the VSS power rail 220. The VR via 242 is between and electrically couple the via interconnect 241 and the VSS power rail 230. The power tap structure 244 comprises a via interconnect 245 and a VR via 246. The via interconnect 245 is over and electrically coupled through one or more additional conductive features to the VSS power rail 224. The VR via 246 is between and electrically couple the via interconnect 245 and the VSS power rail 234. The power tap structure 248 comprises a via interconnect 249 and a VR via 250. The via interconnect 249 is over and electrically coupled through one or more additional conductive features to the VSS power rail 228. The VR via 250 is between and electrically couple the via interconnect 249 and the VSS power rail 238. In some embodiments, some or all of the via interconnects 241, 245, 249 comprise the same material and/or are simultaneously manufactured in the same manufacturing process(s). In at least one embodiment, some or all of the via interconnects 241, 245, 249 are manufactured using the same mask. In some embodiments, some or all of the VR vias 242, 243, 244, 247, 250, 251 comprise the same material and/or are simultaneously manufactured in the same manufacturing process(s). In at least one embodiment, some or all of the VR vias 242, 243, 244, 247, 250, 251 are manufactured using the same mask.

In some embodiments, a stand-alone power tap structure has a larger size than an in-cell power tap structure. In at least one embodiment, a size of a power tap structure is a size of the footprint of the power tap structure in a plane transverse to the thickness direction, i.e., in the X-Y plane. For example, in the X-Y plane or along the Z axis, the via interconnect 241 overlaps an entirety of the VR via 242, and the footprint of the power tap structure 240 is defined by the via interconnect 241. In the X-Y plane, a size of the power tap structure 240 is a size of the via interconnect 241. Similarly, in the X-Y plane, sizes of the power tap structures 244, 248 are sizes of the via interconnects 245, 249. In some embodiments, a size of the power tap structure 240, which is a stand-alone power tap structure, is larger than a size of the power tap structure 244 or 248, which is an in-cell power tap structure, when an area of the via interconnect 241 in the X-Y plane is larger than that of the via interconnect 245 or 249. For example, dimensions of the via interconnect 241 along the X axis and Y axis are correspondingly larger than dimensions of the via interconnect 245 or 249 along the X axis and Y axis.

In some other approaches, in-cell power tap structures are not used and stand-alone power tap structures are distributed uniformly, or substantially uniformly, across a chip area of an IC device. As a result, a power tap area occupied by the uniformly distributed stand-alone power tap structures becomes a potential design concern. In some embodiments, by including one or more smaller in-cell power tap structures, such as the power tap structures 244, 248, in the IC device 200B, it is possible to reduce a number of larger stand-alone power tap structures, such as the power tap structure 240, thereby advantageously reducing the power tap area. In at least one embodiment, due to the presence of in-cell power tap structures, stand-alone power tap structures in the IC device 200B are not distributed uniformly along the X axis and/or the Y axis.

FIG. 2C is a schematic view of a layout 200C of a circuit region of an IC device, in accordance with some embodiments. In some embodiments, the layout 200C corresponds to one or more of the IC devices 200A, 200B. In at least one embodiment, the layout 200C is stored on a non-transitory computer-readable recording medium.

The layout 200C comprises a plurality of active regions elongated along the X axis, and a plurality of gate regions elongated along the Y axis across one or more of the active regions. The active regions and the gate regions configure corresponding CFET devices. Each active region schematically presents both a top active region for top semiconductor devices of CFET devices, and a bottom active region for bottom semiconductor devices of the CFET devices. Each gate region schematically presents both a gate region of the top semiconductor device, and a gate region of the bottom semiconductor device of a CFET device. In some embodiments, each CFET device corresponds to the device stack 100A.

The layout 200C comprises an active region 255 which comprises, along the X axis, a first active region portion 270 and a second active region portion 271 continuous to the active region portion 270. The active region portion 270 has, along the Y axis, a width W1 smaller than a width W2 of the active region portion 271. Further active regions in the layout 200C comprise an active region which comprises an active region portion 272, an active region which comprises active region portions 273, 274, 275 sequentially arranged along the X axis and continuous to each other, an active region which comprises active region portions 273′, 274′, 275′ sequentially arranged along the X axis and continuous to each other, an active region which comprises active region portions 276, 277 continuous to each other along the X axis, and an active region which comprises active region portions 276′, 277′ continuous to each other along the X axis. Along the Y axis, the active region portion 274 has a width smaller than a width of each of the active region portions 273, 275 continuous thereto, the active region portion 274′ has a width smaller than a width of each of the active region portions 273′, 275′ continuous thereto, the active region portion 276 has a width smaller than a width of the active region portion 277 continuous thereto, and the active region portion 276′ has a width smaller than a width of the active region portion 277′ continuous thereto. In some embodiments, some or all of the active region portions 270, 274, 274′, 276, 276′ have the smaller width W1 and/or some or all of the active region portions 271, 272, 273, 273′, 275, 275′, 277, 277′ have the larger width W2. In at least one embodiment, all active region portions 270, 271, 272, 273, 273′, 274, 274′, 275, 275′, 276, 276′, 277, 277′ have the same width along the Y axis.

Representative gate regions 256, 257, 258 are illustrated in FIG. 2C, whereas other gate regions are not shown for simplicity. The gate region 256 is over the active region portion 270 and configures with the active region portion 270 a CFET device. Each of the gate regions 257, 258 is over the active region portion 271 and configures with the active region portion 271 a corresponding CFET device. The gate regions are arranged along the X axis at a regular pitch designated at CPP (contacted poly pitch). CPP is a center-to-center distance along the X axis between two directly adjacent gate regions. Two gate regions are considered directly adjacent (or immediately adjacent) where there are no other gate regions therebetween. CFET devices corresponding to immediately adjacent gate regions are considered as immediately adjacent CFET devices. For example, the gate regions 257, 258 are immediately adjacent and are arranged along the X axis at the interval of 1 CPP. The CFET devices configured by the gate regions 257, 258 and the underlying active region portion 271 are immediately adjacent along the X axis.

Some gate regions in the layout 200C are functional gate regions which, together with the underlying active region, configure semiconductor devices or transistors coupled into circuitry configured to perform a predetermined operation or function. In at least one embodiment, some other gate regions of the layout 200C are non-functional, or dummy, gate regions. Dummy gate regions are not configured to form transistors together with the underlying active region, and/or one or more transistors formed by dummy gate regions together with the underlying active region are not electrically coupled to other circuitry. In at least one embodiment, non-functional or dummy gates corresponding to dummy gate regions include dielectric material in a manufactured IC device corresponding to the layout 200C. Other configurations are within the scopes of various embodiments.

The layout 200C further comprises cut-gate regions 260-266 elongated along the X axis and arranged, along the Y axis, alternatingly with the active regions described herein. In at least one embodiment, the cut-gate regions 260-266 belong to a cut-gate mask. Examples of a cut-gate mask include, but are not limited to, a cut-metal-gate (CMG) mask, a cut-poly (silicon) (CPO) mask, or a similar mask configured to define or configure the length of one or more gates. For simplicity, CMG, CPO and cut-gate are used interchangeably herein to designate a gate length defining mask or region. The cut-gate regions 260-266 are referred to herein as CMG regions 260-266.

Along the Y axis, a length of each of the gate regions in the layout 200C is defined or configured between a pair of CMG regions. For example, the length of each of the gate regions 257, 258 is defined by and between the CMG regions 260, 261. The length of the gate region 256 is also defined by and between the CMG regions 260, 261; however, because a CMG jog portion 292 arranged on the CMG region 261 where the gate region 256 is located projects toward the CMG region 260, the length of the gate region 256 is shorter than the length of the gate regions 257, 258. The CMG jog portion 292 surrounds a power tap structure 280. A CMG jog portion 293 is arranged on the CMG region 263 and surrounds a power tap structure 284, and a CMG jog portion 295 is arranged on the CMG region 265 and surrounds a power tap structure 288. In some embodiments, except for the CMG jog portions 292, 293, 295 and any other CMG jog portions (not shown) arranged on one or more of the CMG regions 261, 263, 265, each of the CMG regions 261, 263, 265 has a constant width in the Y axis over a length thereof along the X axis. Unless otherwise specified, further descriptions of each of the CMG regions 261, 263, 265 are applicable to the portions where a CMG jog portion is not arranged, i.e., the portions where each of the CMG regions 261, 263, 265 has a constant width in the Y axis. For example, a center line of the CMG region 261 refers to the center line of the portion (corresponding to the gate regions 257, 258) where the CMG region 261 has a constant width in the Y axis. In some embodiments, the CMG regions 260, 262, 264, 266 are free of CMG jog portions and each have a constant width in the Y axis over an entire length thereof along the X axis.

The CMG regions 260-266 have corresponding center lines arranged along the Y axis at the interval 1 CH. In some embodiments, along the Z axis (perpendicular to the X-Y plane of FIG. 2C), the CMG regions 260, 262, 264, 266 overlap corresponding back side VDD power rails, similar to the back side VDD power rails 222, 226. In some embodiments, the center line of at least one of the CMG regions 260, 262, 264, 266 coincides with the center line of the corresponding back side VDD power rail. The back side VDD power rails overlapping the CMG regions 260, 262, 264, 266 are schematically indicated with the label “(VDD)” in FIG. 2C.

In some embodiments, along the Z axis (perpendicular to the X-Y plane of FIG. 2C), the CMG regions 261, 263, 265 overlap corresponding back side and front side VSS power rails, similar to the back side VSS power rails 220, 224, 228 and the front side VSS power rails 230, 234, 238. In some embodiments, the center line of at least one of the CMG regions 261, 263, 265 coincides with the center line of at least one of the corresponding back side VSS power rail or the corresponding front side VSS power rail. The front side and back side VSS power rails overlapping the CMG regions 261, 263, 265 are schematically indicated with the label “(VSS)” in FIG. 2C.

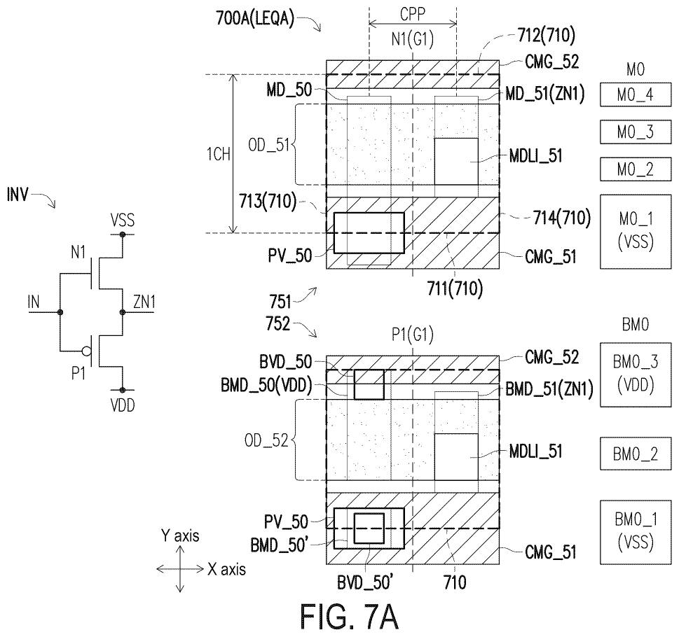

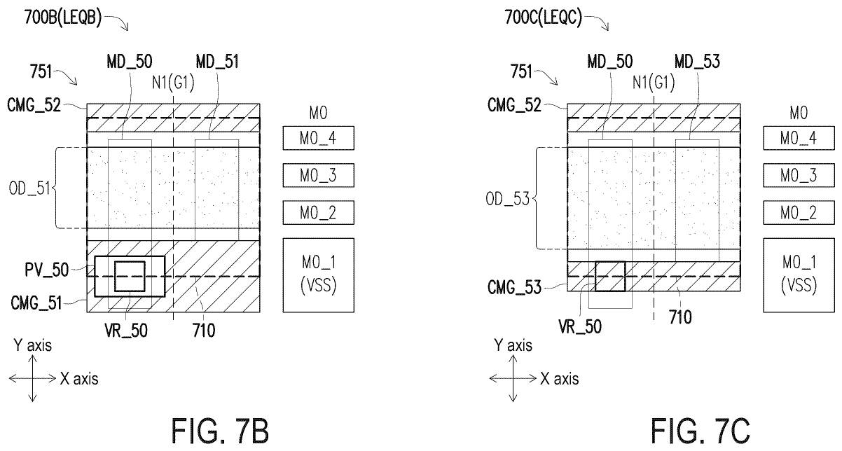

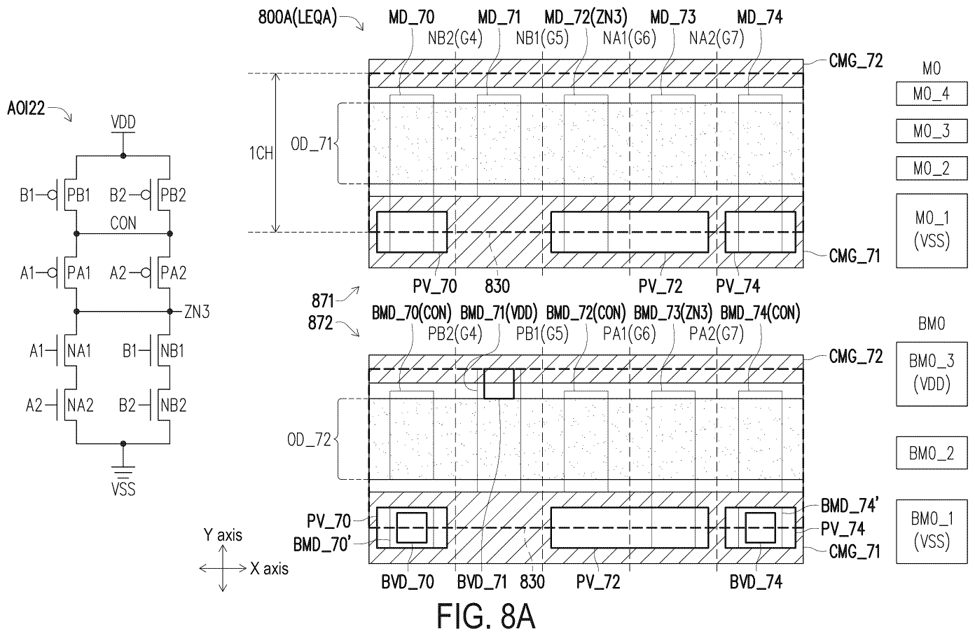

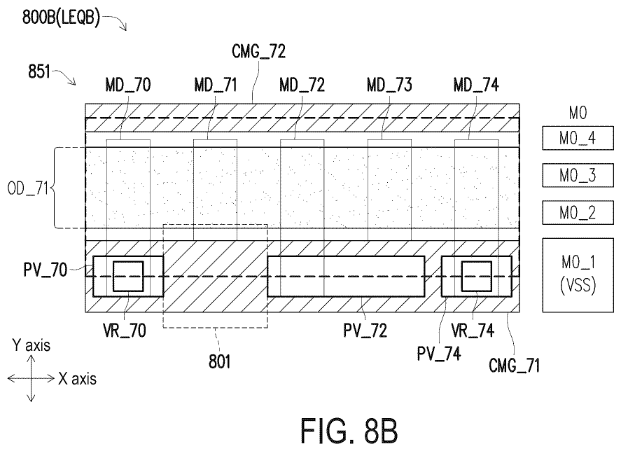

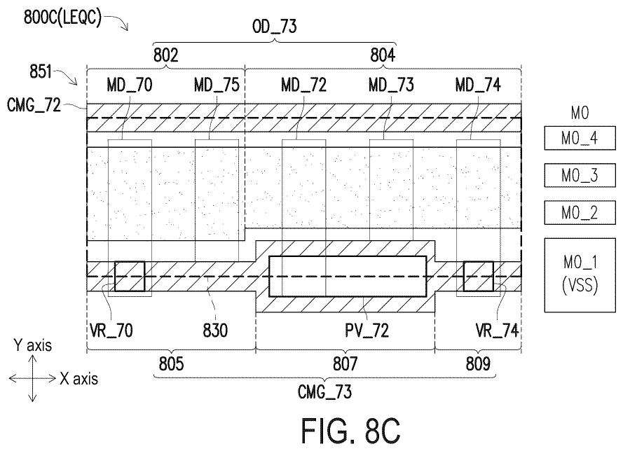

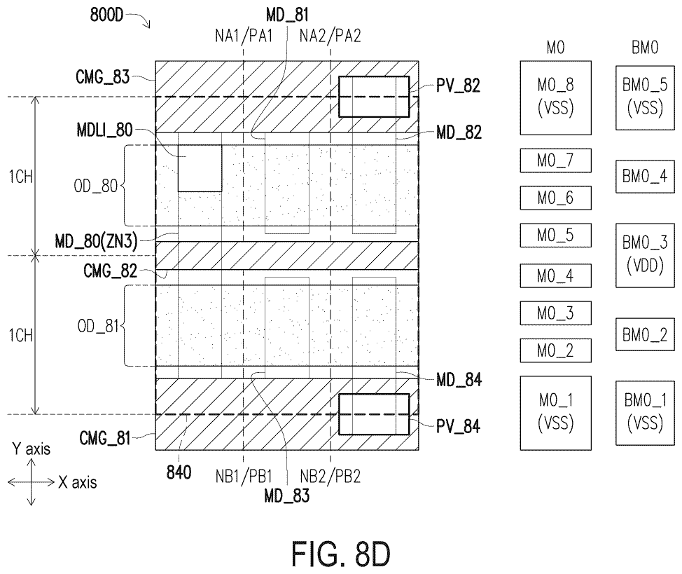

The layout 200C further comprises a plurality of cells placed therein. Representative cell shown in FIG. 2C comprise functional cells C1, C2, C3 and a power tap cell C4. The functional cells C1, C2, C3 correspond to one or more functional circuits as described herein. The functional circuits are electrically coupled to and powered by the VDD and VSS power rails (not shown) overlapping the CMG regions 260-266. In some embodiments, to generate the layout 200C, various cells, such as the cells C1-C4, are placed, in a placement operation performed by an EDA tool or an automated placement and routing (APR) system. Non-limiting example functional cells are described with respect to FIGS. 7A-7C, 8A-8D. Non-limiting example power tap cells are described with respect to FIGS. 5A-5B.

The cells C1-C4 are schematically represented in FIG. 2C by their corresponding boundaries. One or more cells are placed in the placement operation with their boundaries in abutment with the boundaries of one or more further cells. For example, in the X axis, the cell C1 is placed in abutment with the cell C2 along a common edge. In the Y axis, the cell C1 is placed in abutment with the cell C3 along a common edge. Cells are not always placed (or placeable) in abutment. Cells are placed over and/or under one or more of the VDD and VSS power rails (not shown) overlapping the CMG regions 260-266. In some embodiments, a cell is placed with the corresponding boundary over and coinciding with center lines of two power rails or center lines of two corresponding CMG regions. A cell height of the cell along the Y axis corresponds to a center-to-center distance between the two power rails or the two corresponding CMG regions. For example, in FIG. 2C, the boundary of the cell C1 has upper and lower edges over and coinciding correspondingly with the center lines of the CMG regions 264, 265. As a result, the cell C1 has a cell height of 1 CH (single cell height) being the center-to-center distance between the CMG regions 264, 265. The functional circuit in the cell C1 is configured to receive VSS from the VSS power rail overlapping the CMG region 265, and VDD from the VDD power rail overlapping the CMG region 264. In at least one embodiment, one or more cells (not shown) having a cell height of 2 CH (double cell height) are placed in the layout 200C. A non-limiting example cell having the double cell height is described with respect to FIG. 8D. The described cells with the single cell height or double cell height are examples. Other cells with greater cell heights, e.g., 3 CH, 4 CH, or the like, are within the scopes of various embodiments. The described placement operation is an example. Other placement operations are within the scopes of various embodiments.

In the example configuration in FIG. 2C, the boundary of the power tap cell C4 has upper and lower edges over and coinciding correspondingly with the center lines of the CMG regions 261, 262. As a result, the power tap cell C4 has the single cell height, as also described with respect to a non-limiting example in FIG. 5A. A non-limiting example power tap cell having the double cell height is described with respect to FIG. 5B. The power tap cell C4 comprises a stand-alone power tap structure 280 which comprises a via interconnect 281 and a VR via 282.

The layout 200C further comprises in-cell power tap structures 284, 288 which comprise corresponding via interconnects 285, 289 and VR vias 286, 290. Unlike the power tap structure 280 included in the power tap cell C4, each of the power tap structures 284, 288 is included in a functional cell, similar to the cells C1-C3. The layout 200C further comprises VR vias 283, 287, 291 configured to provide VSS to corresponding functional cells. For example, the VR via 291 is arranged on the boundary of the cell C2 and is configured to provide VSS to the functional circuit in the cell C2. In some embodiments, the power tap structures 280, 284, 288, the via interconnects 281, 285, 289, and the VR vias 282, 286, 290, 283, 287, 291 correspond to the power tap structures 240, 244, 248, the via interconnects 241, 245, 249, and the VR vias 242, 246, 250, 243, 247, 251.

The CMG jog portion 292 extends around the via interconnect 281 and corresponds to a dielectric structure that surrounds the via interconnect 281. A space 268 between the CMG jog portion 292 and the adjacent CMG region 262 corresponds to a further dielectric structure. In some embodiments, the dielectric structures corresponding to the CMG jog portion 292 and the space 268 comprise the same dielectric material. There is no active region, or active region portion, present in the Y axis between the power tap structure 280 and the CMG region 262. In some embodiments, a spacing between the power tap structure 280 and the CMG region 262 (or the VDD power rail overlapping the CMG region 262) is free of any active region or any active region portion. In some embodiments, an active region portion (not shown) is arranged on the left side of the power tap cell C4 in FIG. 2C, and is disconnected from the active region portion 272 by the power tap cell C4. The CMG jog portion 292, the via interconnect 281 and the VR via 282 are asymmetrical across the center line of the CMG region 261.

The CMG jog portion 293 extends around the via interconnect 285 and corresponds to a dielectric structure that surrounds the via interconnect 285. Due to the presence of the CMG jog portion 293, the active region portions 274 and 274′ on opposite sides of the CMG jog portion 293 along the Y axis have smaller widths than the corresponding adjacent active region portions 273, 275 and 273′, 275′. Along the Y axis, the power tap structure 284 overlaps the active region portions 274, 274′ of the smaller width(s), without overlapping the active region portions 273, 275, 273′, 275′ of the larger width(s). In some embodiments, at least one of the CMG jog portion 293, the via interconnect 285 or the VR via 286 is symmetrical across the center line of the CMG region 263. In at least one embodiment, each of the CMG jog portion 293 and the via interconnect 285 is symmetrical across the center line of the CMG region 263.

Similarly, the CMG jog portion 295 extends around the via interconnect 289 and corresponds to a dielectric structure that surrounds the via interconnect 289. Due to the presence of the CMG jog portion 295, the active region portions 276 and 276′ on opposite sides of the CMG jog portion 295 along the Y axis have smaller widths than the corresponding adjacent active region portions 277 and 277′. Along the Y axis, the power tap structure 288 overlaps the active region portions 276, 276′ of the smaller width(s), without overlapping the active region portions 277, 277′ of the larger width(s). In some embodiments, at least one of the CMG jog portion 295, the via interconnect 289 or the VR via 290 is symmetrical across the center line of the CMG region 265. In at least one embodiment, each of the CMG jog portion 295 and the via interconnect 289 is symmetrical across the center line of the CMG region 265.

In FIG. 2C, the stand-alone power tap structure 280 occupies a larger area than each of the in-cell power tap structures 284, 288. In some embodiments, by replacing one or more stand-alone power tap structures with one or more in-cell power tap structures, it is possible to reduce the power tap area and achieve area improvements.

Although the in-cell power tap structures 284 and 288 occupy smaller areas than the stand-alone power tap structure 280, they still limit a width (sometimes referred to as “active region width”) of the adjacent active region portions 274, 274′ and 276, 276′. In some embodiments, by forming active regions with non-uniform widths, i.e., with a larger or increased active region width in active region portions, e.g., one or more of the active region portions 273, 275, 277, 273′, 275′, 277′, which do not face an in-cell power tap structure, it is possible in one or more embodiments to improve performance (or speed). In some embodiments, further performance improvements are obtainable by limiting the size (e.g., the length along the X axis) and/or the number of in-cell power tap structures, thereby increasing the size and/or area of active region portions with increased active region widths. In at least one embodiment, although there is an increase in power consumption associated with an increase in active region width, the impact is far less than in other approaches which attempt to obtain speed improvement by increasing the number of gate (or PO) fingers. In at least one embodiment, overall improvements in power, performance and area (PPA) are obtainable.

Various example configurations related to via interconnects in accordance with some embodiments are described with respect to FIGS. 3A-3D. In the example configuration in FIG. 3A, a via interconnect is configured to provide a power supply voltage from a back side power rail to a top semiconductor device in a device stack, in accordance with some embodiments. In the example configuration in FIG. 3B, a via interconnect is configured as part of a power tap structure to provide a power supply voltage from a back side power rail to a front side power rail, in accordance with some embodiments. In the example configuration in FIG. 3C, a via interconnect is absent, and a top semiconductor device in a device stack is configured to be powered by a front side power rail, in accordance with some embodiments. In the example configuration in FIG. 3D, a via interconnect is configured for signal transmission, rather than power delivery, in accordance with some embodiments. Corresponding components in FIGS. 3A-3D are designated by the same reference numerals.

FIG. 3A is a schematic cross-sectional view of a circuit region of an IC device 300A, in accordance with some embodiments. In some embodiments, the IC device 300A corresponds to one or more of the IC devices 200A, 200B, and the layout 200C.

As illustrated in FIG. 3A, the IC device 300A comprises a substrate 302 having a front side 304, and a back side 306 opposite to the front side 304 in a thickness direction, i.e., Z axis, of the substrate 302. In some embodiments, the substrate 302 comprises a semiconductor material, such as silicon, silicon germanium (SiGe), gallium arsenic, or other suitable semiconductor materials. In some embodiments, the substrate 302 comprises a dielectric material, such as silicon nitride, silicon oxide, ceramic, glass, or other suitable materials. In some embodiments, the substrate 302 comprises a multi-layer structure. In some embodiments, the substrate 302 is omitted, or comprises an insulation layer that replaces an initial semiconductor bulk used during manufacture. In at least one embodiment, the substrate 302 corresponds to one or more substrates described with respect to FIGS. 1A-1F.

The IC device 300A further comprises a device stack 308 comprising a bottom semiconductor device MP, and a top semiconductor device MN stacked over the bottom semiconductor device MP along the thickness direction, i.e., the Z axis. In some embodiments, the device stack 308 corresponds to the device stack 100A, and/or is manufactured by one or more processes or operations described with respect to FIGS. 1B-IF. The device stack 308 is configured over the front side 304 of the substrate 302.

In the example configuration in FIG. 3A, the top semiconductor device MN is an N-type semiconductor device and the bottom semiconductor device MP is a P-type semiconductor device, which together configure the device stack 308 as a CFET device. Each of the top semiconductor device and bottom semiconductor device comprises a channel which is arranged in a corresponding active region. For example, a channel 321 of the top semiconductor device MN comprises a semiconductor material, such as Si, in a corresponding top active region (not numbered), and is configured as an N-type nanosheet. In some embodiments, the channel 321 comprises multiple N-type nanosheets stacked over, while being spaced from, each other in the thickness direction. Similarly, a channel 331 of the bottom semiconductor device MP comprises a semiconductor material, such as Si, in a corresponding bottom active region (not numbered) below the top active region, and is configured as a P-type nanosheet. In some embodiments, the channel 331 comprises multiple P-type nanosheets stacked over, while being spaced from, each other in the thickness direction. The described channel material and nanosheets are examples. Other channel materials and/or channel types, such as nanowire, FinFET, planar, or the like, are within the scopes of various embodiments.

Each of the top semiconductor device and bottom semiconductor device further comprises a gate. For example, the top semiconductor device MN comprises a gate 325 which is an all-around gate extending around the channel 321, and the bottom semiconductor device MP comprises a gate 335 which is an all-around gate extending around the channel 331. In the example configuration in FIG. 3A, the gates 325, 335 are electrically isolated from each other by a dielectric layer 345 in an isolated gate configuration as described herein. In at least one embodiment, the gates 325, 335 are electrically coupled to each other by a conductor, e.g., a gate local interconnect (MGLI) (not shown). In some embodiments, the gates 325, 335 are metal gates. Other gate materials, such as polysilicon, are within the scopes of various embodiments. In some embodiments, the gate material of the gate 325 and/or the gate 335 replaces a sacrificial material, such as SiGe, in the corresponding active region during a manufacturing process.

Each top semiconductor device or bottom semiconductor device further comprises a gate dielectric (not shown) between the corresponding gate and channel. For example, a gate dielectric is between each of the gate 325 and the corresponding channel 321, and extends around the channel 321. Example materials of the gate dielectric include high-k dielectric materials, or the like.

Each top semiconductor device further comprises source/drains (sometimes referred to as top source/drains) in the corresponding top active region, and each bottom semiconductor device further comprises source/drains (sometimes referred to as bottom source/drains) in the corresponding bottom active region. For example, the top semiconductor device MN includes a source/drain 322, and the bottom semiconductor device MP includes a source/drain 332. The other source/drain of the top semiconductor device MN and the other source/drain of the bottom semiconductor device MP are not visible/shown in FIG. 3A. In some embodiments, source/drains of a semiconductor device are coupled to the corresponding channel, and are arranged in the same active region as a the channel. For example, the source/drain 322 and the other source/drain (not shown) of the top semiconductor device MN are coupled by the channel 321, and are all in the top active region containing the channel 321. For another example, the source/drain 332 and the other source/drain (not shown) of the bottom semiconductor device MP are coupled by the channel 331, and are all in the bottom active region containing the channel 331.

In the example configuration in FIG. 3A, the IC device 300A further comprises a source/drain local interconnect (MDLI) 342 arranged between and electrically coupling the source/drains 322, 332. In some embodiments, the MDLI interconnect 342 is omitted, i.e., replaced by a dielectric material, to electrically isolate the source/drains 322, 332. In at least one embodiment, an MDLI interconnect other than the MDLI interconnect 342 is provided between and electrically couples the source/drains 322, 332. An example material of MDLI interconnects comprises a metal.

The IC device 300A further comprises MD contacts for the top semiconductor device MN, and BMD contacts for the bottom semiconductor device MP. For example, an MD contact 324, i.e., a top contact structure, is over and in electrical contact with the source/drain 322 of the top semiconductor device MN, whereas a BMD contact 334, i.e., a bottom contact structure, is under and in electrical contact with the source/drain 332 of the bottom semiconductor device MP. An MD contact (not shown) similar to the MD contact 324 is over and in electrical contact with the other source/drain of the top semiconductor device MN. A BMD contact (not shown) similar to the BMD contact 334 is under and in electrical contact with the other source/drain of the bottom semiconductor device MP.

The IC device 300A further comprises a conductor 336 co-elevational with the BMD contact 334 along the Z axis, and spaced from the BMD contact 334 along the Y axis. In some embodiments, a first element is co-elevational with a second element when at least one portion of the first element and at least one portion of the second element are in a plane perpendicular to the Z axis. In at least one embodiment, an entirety of the conductor 336 is co-elevational with an entirety of the BMD contact 334. In some embodiments, the conductor 336 comprises the same material as the BMD contact 334. In some embodiments, the conductor 336 is formed simultaneously with the BMD contact 334, from the same material, in the same manufacturing process, using the same mask. In other words, the conductor 336 is a bottom contact structure like the BMD contact 334, with the exception that the conductor 336 does not overlap and is not in contact with a source/drain or an active region. In at least one embodiment, a spacing do between the BMD contact 334 and the conductor 336 along the Y axis is equal to or greater than a predetermined spacing, i.e., a design rule, for ensuring that the IC device 300A is manufacturable.

The IC device 300A further comprises a dielectric structure 350 in contact with the gates 325, 335 along a surface 352. In some embodiments, the dielectric structure 350 corresponds to a CMG region or a CMG jog portion, described with respect to FIG. 2C. The IC device 300A further comprises a further dielectric structure (not shown for simplicity) similar to the dielectric structure 350, but on the other side of the gates 325, 335 along the Y axis, and in contact with the gates 325, 335 along a surface 351 opposite to the surface 352. The length of the gates 325, 335 is defined or configured by a distance along the Y axis between the dielectric structure 350 and the further dielectric structure. The dielectric structure 350 and the further dielectric structure are sometimes referred to as gate length defining dielectric structures. In the example configuration in FIG. 3A, the dielectric structure 350 and the further dielectric structure have corresponding center lines 311, 312. In some embodiments, the center lines 311, 312 correspond to center lines of corresponding power rails and/or center lines of corresponding CMG regions and/or edges of a boundary of a cell, as described with respect to FIG. 2C.

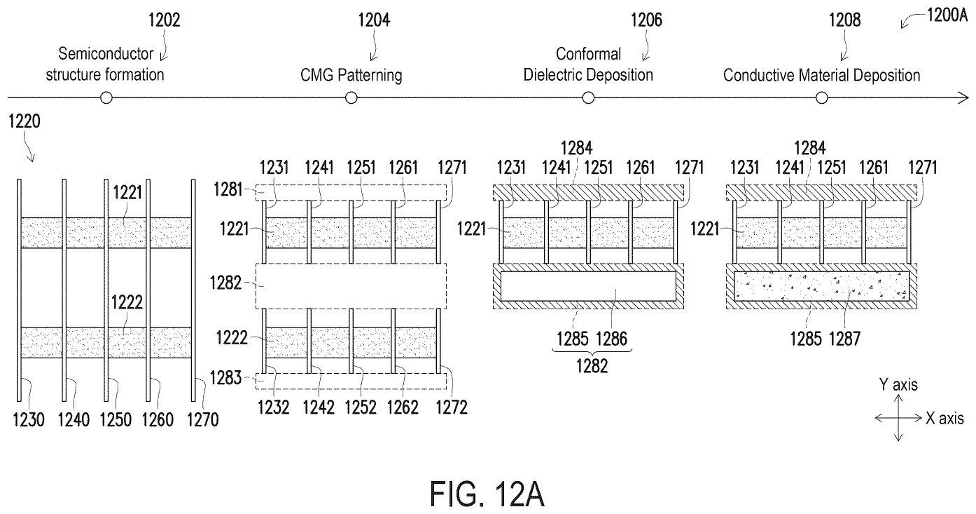

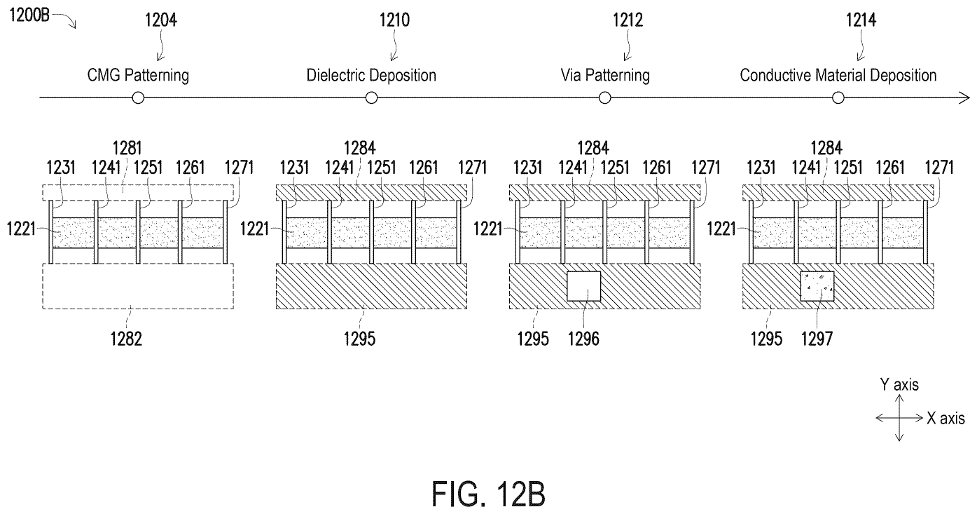

The IC device 300A further comprises a via interconnect 360 extending between and electrically coupling the MD contact 324 and the conductor 336. The via interconnect 360 is embedded in and surrounded by the dielectric structure 350. The dielectric structure 350 and the via interconnect 360 are co-elevational with the gates 325, 335. In at least one embodiment, an entirety of the gate 325 and/or an entirety of the gate 335 is/are co-elevational with the dielectric structure 350 and/or the via interconnect 360. The via interconnect 360 electrically isolates the via interconnect 360 from the gates 325, 335. In some embodiments, the via interconnect 360 is formed using the same CMG mask used to form the dielectric structure 350, and is therefore referred to as a self-aligned via interconnect 360. An example process in accordance with some embodiments is described with respect to FIG. 12A. In at least one embodiment, the via interconnect 360 is formed using a separate mask in addition to the CMG mask used to form the dielectric structure 350. An example process in accordance with some embodiments is described with respect to FIG. 12B.

A top portion of the via interconnect 360 is electrically coupled to the MD contact 324. In the example configuration in FIG. 3A, the MD contact 324 extends along the Y axis into the top portion of the via interconnect 360, such that a top surface 361 of the via interconnect 360 is, along the Z axis, between a top surface 326 and a bottom surface 327 of the MD contact 324. Other configurations are within the scopes of various embodiments. For example, in one or more embodiments, the top surface 326 of the MD contact 324 is flush with or below the top surface 361 of the via interconnect 360. A bottom portion of the via interconnect 360 is electrically coupled to the conductor 336. In the example configuration in FIG. 3A, a bottom surface 362 of the via interconnect 360 is over and in contact with a top surface of the conductor 336. Other configurations are within the scopes of various embodiments. In some embodiments, the via interconnect 360 has a center line coinciding, or aligned, with the center line 311.

In some embodiments, the IC device 300A further comprises at least one of a VG via (not shown) over and in electrical contact with the gate 325, or a BVG via (not shown) under and in electrical contact with the gate 335. In at least one embodiment, the IC device 300A further comprises at least one VD via (not shown) over and in electrical contact with the other source/drain of the top semiconductor device MN, or at least one BVD via under and in electrical contact with at least one of the BMD contacts of the bottom semiconductor device MP. In the example configuration in FIG. 3A, the IC device 300A comprises a BVD via 374 under and in electrical contact with the BMD contact 334. Specifically, the BVD via 374 extends from the back side 306, through the substrate 302, to the front side 304 where the BVD via 374 comes into contact with the BMD contact 334. In some embodiments, the BVD via 374 is omitted.

The IC device 300A further comprises a via 376 under and in electrical contact with the conductor 336. Specifically, the via 376 extends from the back side 306, through the substrate 302, to the front side 304 where the via 376 comes into contact with the conductor 336. In some embodiments, the via 376 comprises the same material as the BVD via 374. In some embodiments, the via 376 is formed simultaneously with the BVD via 374, from the same material, in the same manufacturing process, using the same mask. In other words, the via 376 is a BVD via like the BVD via 374, with the exception that the via 376 is in contact with the conductor 336 rather than with a BMD contact. The via 376 and similar vias electrically coupled to conductors like the conductor 336 are sometimes referred to herein as BVD vias.

The IC device 300A further comprises a front side redistribution structure 380, and a back side redistribution structure 390. The redistribution structure 380 is on the front side, over the VD, VG vias, and comprises a plurality of metal layers and via layers sequentially and alternatingly arranged over the VD, VG vias, as described herein with respect to FIG. 1F. The back side redistribution structure 390 is on the back side, and similarly comprises a plurality of metal layers and via layers sequentially and alternatingly arranged under the BVD, BVG vias. A metal layer, i.e., M0 layer, of the front side redistribution structure 380 and a metal layer, i.e., BM0 layer, of the back side redistribution structure 390 are illustrated in FIG. 3A, whereas other layers and/or features of the front side redistribution structure 380 and back side redistribution structure 390 are omitted for simplicity. Among the metal layers of the front side redistribution structure 380, the M0 layer is the metal layer closest to the device stack 308. Among the metal layers of the back side redistribution structure 390, the BM0 layer is the metal layer closest to the device stack 308.

In the example configuration in FIG. 3A, the M0 layer comprises, over the device stack 308, metal patterns 381-384 correspondingly on M0 tracks M0_1-M0_4. In some embodiments, one or more of the metal patterns 381-384 is/are omitted. The tracks M0_1-M0_4 are elongated along the X axis (FIGS. 2B-2C), and are arranged side by side along the Y axis. Specifically, the track M0_1 is immediately adjacent to the track M0_2, which is immediately adjacent to the track M0_3, which is immediately adjacent to the track M0_4. Two M0 tracks are considered directly adjacent (or immediately adjacent) where there are no other M0 tracks therebetween. M0 metal patterns on immediately adjacent M0 tracks are considered immediately adjacent. For example, along the Y axis, the metal pattern 381 is immediately adjacent to the metal pattern 382. Along the Y axis, the metal pattern 381 on the track M0_1 has a width greater than a width of each of the metal patterns 382-384 on the tracks M0_2-M0_4.

The metal pattern 381 extends across the center line 311 and is configured to be shared with another device stack (not shown) on the left side of the device stack 308 in FIG. 3A. In some embodiments, the metal pattern 381 has a center line coinciding, or aligned, with the center line 311. In some embodiments, the metal pattern 381 comprises a power rail similar to one or more front side power rails described with respect to FIGS. 2B, 2C. For example, the metal pattern 381 is configured in one or more embodiments as a VSS power rail to provide VSS to one or more N-type top semiconductor devices in one or more device stacks of the IC device 300A.

The metal patterns 382-384 on the tracks M0_2-M0_4 are arranged between the center lines 311, 312. In some embodiments, the metal patterns 382-384 are configured to transmit signals between the device stack 308 and other device stacks or CFET devices in the IC device 300A. The metal patterns 382-384 and the tracks M0_2-M0_4 are sometimes referred correspondingly to as M0 signal patterns and M0 signal tracks. For example, at least one of the metal patterns 382-384 is electrically coupled to the gate 325 or the other source/drain of the top semiconductor device MN through a corresponding VG via or VD via. In some embodiments, at least one of the metal patterns 382-384 is electrically coupled to the gate 335 or a source/drain of the bottom semiconductor device MP through a via or local interconnect (not shown) extending between the M0 layer and the gate 335 or the source/drain of the bottom semiconductor device MP. The described number of three M0 signal tracks between the center lines 311, 312 (i.e., over 1 CH) is an example. Other numbers of M0 signal tracks over 1 CH are within the scopes of various embodiments.

In the example configuration in FIG. 3A, the BM0 layer comprises, under the device stack 308 and on the back side 306 of the substrate 302, metal patterns 391-393 correspondingly on BM0 tracks BM0_1-BM0_3. The tracks BM0_1-BM0_3 are elongated along the X axis, and are arranged side by side along the Y axis. Specifically, the track BM0_1 is immediately adjacent to the track BM0_2, which is immediately adjacent to the track BM0_3. Two BM0 tracks are considered directly adjacent (or immediately adjacent) where there are no other BM0 tracks therebetween. BM0 metal patterns on immediately adjacent BM0 tracks are considered immediately adjacent. For example, along the Y axis, the metal pattern 391 is immediately adjacent to the metal pattern 392. Along the Y axis, the metal patterns 391, 393 on the tracks BM0_1, BM0_3 has a width greater than a width of the metal pattern 392 on the track BM0_2.

The metal pattern 391 extends across the center line 311 and is configured to be shared with another device stack (not shown) on the left side of the device stack 308 in FIG. 3A. In some embodiments, the metal pattern 391 has a center line coinciding, or aligned, with the center line 311. The metal pattern 393 extends across the center line 312 and is configured to be shared with another device stack (not shown) on the right side of the device stack 308 in FIG. 3A. In some embodiments, the metal pattern 393 has a center line coinciding, or aligned, with the center line 312. The metal patterns 391, 393 are configured as back side power rails of a back side power delivery network described with respect to FIG. 2B. In the example configuration in FIG. 3A, the metal pattern 391 is a VSS power rail configured to provide VSS to the top semiconductor device MN and corresponding to one or more of the VSS power rails described with respect to FIGS. 2B, 2C, whereas the metal pattern 393 is a VDD power rail configured to provide VDD to the bottom semiconductor device MP and corresponding to one or more of the VDD power rails described with respect to FIGS. 2B, 2C. The BM0 tracks BM0_1, BM0_3 are sometimes referred to as BM0 power tracks.

The metal pattern 392 on the track BM0_2 is arranged between the center lines 311, 312. In some embodiments, the metal pattern 392 is configured to transmit signals between the device stack 308 and other device stacks, or CFET devices, in the IC device 300A. The metal pattern 392 and the track BM0_2 is sometimes referred correspondingly to as a BM0 signal pattern and a BM0 signal track. For example, the metal pattern 392 is electrically coupled to the gate 335 or a source/drain of the bottom semiconductor device MP through a corresponding BVG via or BVD via. In some embodiments, the metal pattern 392 is electrically coupled to the gate 325 or a source/drain of the top semiconductor device MN through a via or local interconnect (not shown) extending between the BM0 layer and the gate 325 or the source/drain of the top semiconductor device MN. The described number of one BM0 signal track between the center lines 311, 312 (i.e., over 1 CH) is an example. Other numbers of BM0 signal tracks over 1 CH are within the scopes of various embodiments. In some embodiments, the metal pattern 392 and/or the track BM0_2 is/are omitted.

The metal pattern 393, referred to herein as power rail 393, is in electrical contact with the BVD via 374. As a result, VDD on the power rail 393 is provided to the source/drain 332 of the bottom semiconductor device MP through the BVD via 374 and BMD contact 334. In some embodiments, the BVD via 374 is omitted, e.g., when the bottom semiconductor device MP is not directly powered by VDD.

The metal pattern 391, referred to herein as power rail 391, is in electrical contact with the BVD via 376, and is electrically coupled to the via interconnect 360 through the BVD via 376. As a result, VSS on the power rail 391 is provided to the source/drain 322 of the top semiconductor device MN through an electrical connection comprising the BVD via 376, conductor 336, via interconnect 360, and MD contact 324. The top semiconductor device MN receives power (i.e., VSS) from the back side power delivery network, rather than from a front side power delivery network. An entirety of the electrical connection from the power rail 391 to the source/drain 322, i.e., the BVD via 376, conductor 336, via interconnect 360 and MD contact 324, is below the M0 layer, i.e., below the metal layers of the front side redistribution structure 380. In other words, the top semiconductor device MN is electrically coupled to the back side power rail 391 without intermediary of any of the front side power rails of the IC device 300A. In the example configuration in FIG. 3A, the power rail 391 overlaps, along the Z axis, an entirety of at least one of the BVD via 376, the conductor 336, the via interconnect 360, or the metal pattern 381.

The described configuration for power delivery to an N-type top semiconductor device in a device stack is an example. Other configurations are within the scopes of various embodiments. For example, in some embodiments where the device stack 308 comprises a P-type top semiconductor device over an N-type bottom semiconductor device, the power rails 391, 393 are configured correspondingly as a VDD power rail and a VSS power rail, and VDD is provided from the power rail 391 through the electrical connection including the via interconnect 360 to the P-type top semiconductor device.

FIG. 3B is a schematic cross-sectional view, similar to FIG. 3A, of a circuit region of an IC device 300B, in accordance with some embodiments. In some embodiments, the IC device 300B corresponds to one or more of the IC devices 200A, 200B and the layout 200C. In at least one embodiment, the IC device 300B corresponds to the IC device 300A or a portion of the IC device 300A.

Compared to the IC device 300A in which the via interconnect 360 is configured for power delivery from a back side power rail to a top semiconductor device, the via interconnect 360 in the IC device 300B is also configured as part of an in-cell power tap structure 309. The power tap structure 309 comprises the BVD via 376, conductor 336, via interconnect 360, and a VR via 375. The VR via 375 is between and in electrical contact with the MD contact 324 and the metal pattern 381 configured as a front side VSS power rail. VSS is delivered from the back side VSS power rail 391, through the power tap structure 309, to the front side VSS power rail 381 which is configured to further provide VSS to one or more N-type top semiconductor devices in one or more device stacks of the IC device 300B, for example, as described with respect to FIG. 3C. In some embodiments, the power tap structure 309, the via interconnect 360, the VR via 375 and the dielectric structure 350 correspond to the power tap structure 284 or 288, the via interconnect 285 or 289, the VR via 286 or 250, and the CMG jog portion 293 or 295. In at least one embodiment, the dielectric structure 350 corresponds to a portion of a CMG region where a CMG jog portion is not arranged. In at least one embodiment, the power tap structure 309 provides, together with other conductive features, an in-cell power tap structure which has a smaller size than a stand-alone power tap structure and, therefore, provides one or more advantages as described herein.

FIG. 3C is a schematic cross-sectional view, similar to FIG. 3A, of a circuit region of an IC device 300C, in accordance with some embodiments. In some embodiments, the IC device 300C corresponds to one or more of the IC devices 200A, 200B and the layout 200C. In at least one embodiment, the IC device 300C corresponds to one or more of the IC devices 300A, 300B or a portion of one or more of the IC devices 300A, 300B.

Compared to the IC devices 300A, 300B comprising the via interconnect 360, a via interconnect is absent in the circuit region of the IC device 300C shown in FIG. 3C. The conductor 336 and BVD via 376 are also absent from the circuit region of the IC device 300C shown in FIG. 3C. The IC device 300C comprises a VR via 377 between and in electrical contact with the MD contact 324 and the metal pattern 381 configured as a front side VSS power rail. VSS is delivered to the front side VSS power rail 381 from a back side VSS power rail through a stand-alone power tap structure or an in-cell power tap structure. VSS is further delivered from the front side VSS power rail 381 to the MD contact 324 of the top semiconductor device MN through the VR via 377. As a result, the top semiconductor device MN in FIG. 3C is powered from the front side, rather than from the back side as described with respect to FIG. 3A. The MD contact 324 and the VR via 377 are formed over a dielectric structure 357 corresponding to the dielectric structure 350. In at least one embodiment, the dielectric structure 357 corresponds to a portion of a CMG region where a CMG jog portion is not arranged. In some embodiments, the VR via 377 corresponds to one or more of the VR vias 243, 247, 251.

The IC devices 300A, 300C are examples demonstrating that it is possible to power top semiconductor devices of device stacks from the back side or from the front side, in accordance with some embodiments. In some embodiments, an IC device comprises at least one top semiconductor device being powered from the back side (as in the IC device 300A) and at least one further top semiconductor device being power from the front side (as in the IC device 300C), whereas all bottom semiconductor devices in the IC device are powered from the back side.

The IC devices 300A, 300B are examples of configuring a via interconnect embedded in a gate length defining dielectric structure for power delivery. In some embodiments, such a via interconnect is configured instead for signals, e.g., data, control, clock, or the like.

FIG. 3D is a schematic cross-sectional view, similar to FIG. 3A, of a circuit region of an IC device 300D, in accordance with some embodiments. In some embodiments, the IC device 300D corresponds to one or more of the IC devices 200A, 200B and the layout 200C. In at least one embodiment, the IC device 300D corresponds to one or more of the IC devices 300A-300C or a portion of one or more of the IC devices 300A-300C.

Compared to the IC device 300A in which the via interconnect 360 is configured for power delivery from a back side power rail to a top semiconductor device, the via interconnect 360 in the IC device 300D is configured for signal transmission to/from the top semiconductor device. Specifically, the BVD via 376 is omitted, and the conductor 336 is not electrically coupled to the power rail 391. Instead, the conductor 336 extends along the X axis to be electrically coupled to a BMD contact of a further bottom source/drain (not shown) other than the source/drain 322. As a result, the source/drain 322 of the top semiconductor device MN is electrically coupled to the further bottom source/drain through the MD contact 324, the via interconnect 360, the conductor 336 and the BMD contact of the further bottom source/drain. In some embodiments, the further bottom source/drain is the other source/drain of the bottom semiconductor device MP. In at least one embodiment, the further bottom source/drain is a source/drain of a bottom semiconductor device of another CFET device. The IC device 300D further comprises a VD via 372 electrically coupling the MD contact 324 to the metal pattern 382, for signal transmission. In some embodiments, the VD via 372 is omitted.

In the example configuration in FIG. 3D, the source/drain 332 is not directly powered by VDD, and the BVD via 374 is omitted. The IC device 300D comprises a BMD contact 338 shorter than, and instead of, the BMD contact 334. The BMD contact 338 is under and in electrical contact with the source/drain 332. The IC device 300D further comprises a BVD via 378 electrically coupling the BMD contact 338 to the metal pattern 392 for signal transmission to/from the source/drain 332. In some embodiments, the BVD via 378 is omitted. In at least one embodiment, the source/drain 322 is coupled to receive VDD by the BMD contact 334 and BVD via 374 which correspondingly replace the BMD contact 338 and BVD via 378. The BMD contact 334 is an example of a BMD contact for power delivery, and the BMD contact 338 is an example of a BMD contact for signal transmission.

As described herein, it is possible in one or more embodiments, to configure a via interconnect embedded in a gate length defining dielectric structure either for power delivery (e.g., as in the IC devices 300A, 300B) or for signal transmission (e.g., as in the IC device 300D). In at least one embodiment, a via interconnect for power delivery is configurable for powering a top semiconductor device from the back side (e.g., as in the IC devices 300A, 300B) and/or also as an in-cell power tap structure (e.g., as in the IC device 300B). In some embodiments, the described flexibility in configuring via interconnects for different purposes and/or configurations provides associated design flexibility/customizability and/or permits various adjustments and/or corrections to be made or tuned to achieve one or more PPA improvements.

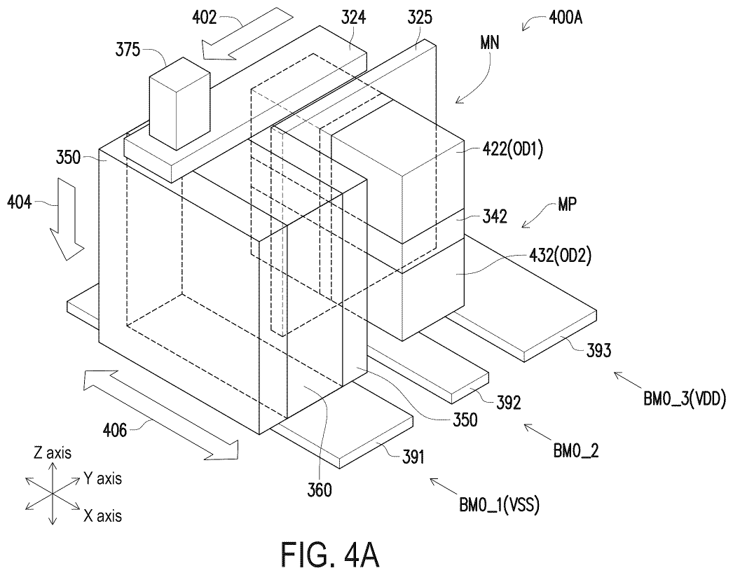

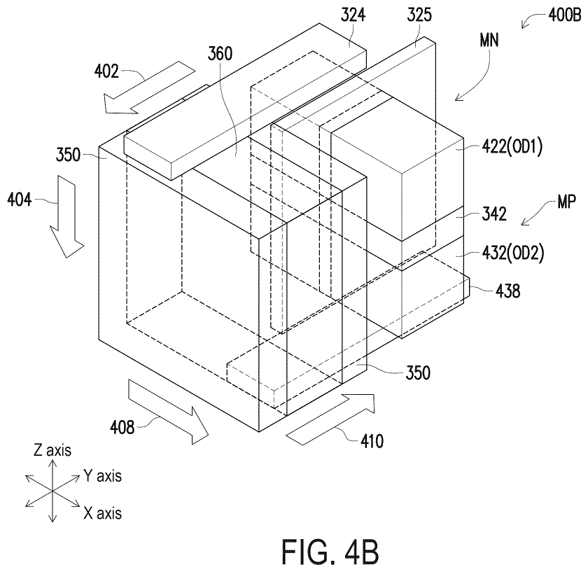

FIG. 4A is a schematic perspective view of a circuit region of an IC device 400A, in accordance with some embodiments. In some embodiments, the IC device 400A corresponds to the IC device 300B. Components in FIG. 4A having corresponding components in FIGS. 3A-3D are designated by the same reference numerals as in FIGS. 3A-3D.

In FIG. 4A, the other source/drains of the top semiconductor device MN and bottom semiconductor device MP, which are not visible in FIG. 3A, are shown. Specifically, the top semiconductor device MN comprises a source/drain 422 which, together with the source/drain 322 (below the MD contact 324 in FIG. 4A) and the channel 321 (not shown in FIG. 4A), belongs to a top active region OD1. The bottom semiconductor device MP comprises a source/drain 432 which, together with the source/drain 332 (not shown in FIG. 4A) and the channel 331 (not shown in FIG. 4A), belongs to a bottom active region OD2. For simplicity, various features, such as, the front side VSS power rail 381, the conductor 336, BVD via 376, an MD contact over the source/drain 422, a BMD contact under the source/drain 432, or the like, are not illustrated in FIG. 4A. FIG. 4A includes arrows 402, 404, 406 schematically showing a connection from the source/drain 322 (not shown in FIG. 4A) through the MD contact 324 and the via interconnect 360 to the power rail 391 along which VSS is delivered. The VR via 375 further electrically couples the MD contact 324 to the front side VSS power rail 381 (not shown in FIG. 4A) to provide, together with the other conductive features including the via interconnect 360, an in-cell power tap structure between the back side VSS power rail 391 and the front side VSS power rail 381.

In some embodiments, the VR via 375 is omitted from the IC device 400A, and a structure corresponding to the IC device 300A is obtained. In at least one embodiment, the via interconnect 360 is omitted from the IC device 400A, and a structure corresponding to the IC device 300C is obtained.

FIG. 4B is a schematic perspective view of a circuit region of an IC device 400B, in accordance with some embodiments. In some embodiments, the IC device 400B corresponds to the IC device 300D. Components in FIG. 4B having corresponding components in FIGS. 3A-3D, 4A are designated by the same reference numerals as in FIGS. 3A-3D, 4A.

In FIG. 4B, the IC device 400B comprises a BMD contact 438 for signal transmission under the source/drain 432. For simplicity, various features, such as, the conductor 336, an MD contact over the source/drain 422, the metal patterns 391-393, or the like, are not illustrated in FIG. 4B. FIG. 4B includes arrows 402, 404, 406, 410 schematically showing a connection from the source/drain 322 (not shown in FIG. 4B) through the MD contact 324, the via interconnect 360 and the BMD contact 438 to the source/drain 432 which is not directly under the source/drain 322. The configuration described with respect to FIG. 4B is an example of configuring the via interconnect 360 for signal transmission between non-overlapping source/drains of the top semiconductor device and the bottom semiconductor device in the same device stack, or CFET device. Other configurations, in which the via interconnect 360 or a similar via interconnect is configured for signal transmission between non-overlapping source/drains of a top semiconductor device and a bottom semiconductor device in different device stacks or CFET devices, are within the scopes of various embodiments.

FIG. 5A is a schematic view of a layout 500A of a power tap cell, in accordance with some embodiments. In some embodiments, the layout 500A corresponds to the power tap cell C4 and/or includes a stand-alone power tap structure corresponding to the stand-alone power tap structure 240. In at least one embodiment, the layout 500A is stored on a non-transitory computer-readable recording medium. Components in FIG. 5A having corresponding components in FIGS. 2B-2C, 3A-3D are designated by the same reference numerals as in 2B-2C, 3A-3D.

The layout 500A comprises a boundary 510 (i.e., cell boundary). In some embodiments, the boundary 510 corresponds to the boundary of the cell C4 described with respect to FIG. 2C. The boundary 510 comprises edges 511, 512, 513, 514. The edges 511, 512 are elongated along the X axis, and the edges 513, 514 are elongated along the Y axis. In some embodiments, the X axis is an example of one of a first direction and a second direction, and the Y axis is an example of the other of the first direction and the second direction. The edges 511, 512, 513, 514 are connected together to form the closed boundary 510. In a place-and-route operation (e.g., performed by an APR system), cells are placed in an IC layout in abutment with each other at their respective boundaries. The rectangular shape of the boundary 510 is an example. Other boundary shapes for various cells are within the scope of various embodiments. The power tap cell represented by the layout 500A has a cell height of 1 CH along the Y axis, and a cell width Wc along the X axis. In at least one embodiment, the cell width Wc is a minimum cell width (or minimum cell pitch) defined by a predetermined set of design rules configured to ensure manufacturability of an IC device corresponding to the layout 500A.

The layout 500A comprises CMG regions 561, 562 correspondingly overlapping the edges 511, 512 of the boundary 510. In some embodiments, the edge 512 coincides with the center line of the CMG region 562. The layout 500A further comprises a stand-alone power tap structure 580 which comprises a via interconnect 581 and a VR via 582. The CMG region 561 extends around the via interconnect 581 and corresponds to a dielectric structure that surrounds the via interconnect 581. A space 568 between the CMG region 561 and the adjacent CMG region 562 corresponds to a further dielectric structure. In some embodiments, the dielectric structures corresponding to the CMG region 561 and the space 568 comprise the same dielectric material. There is no active region, or active region portion, present in the Y axis between the power tap structure 580 and the CMG region 562. In some embodiments, a spacing between the power tap structure 580 and the CMG region 562 (or a power rail overlapping the CMG region 562) is free of any active region or any active region portion. The CMG region 561, the via interconnect 581 and the VR via 582 overlap, and are asymmetrical across, the edge 511 of the boundary 510. In some embodiments, the CMG regions 561, 562, the power tap structure 580, the via interconnect 581, the VR via 582 and the space 568 correspond to the CMG jog portion 292, the CMG region 262, the power tap structure 280, the via interconnect 281, the VR via 282, and the space 268. In some embodiments, the via interconnect 581 and VR via 582 of the stand-alone power tap structure 580 are correspondingly formed together with, and/or in the same manner as, via interconnects and VR vias of one or more in-cell power tap structures, as described with respect to FIGS. 12A-12B.

The layout 500A is applicable to various metal schemes. In the example configuration in FIG. 5A, an M0 metal scheme 516, an alternative M0 metal scheme 517, and a BM0 metal scheme 518 are illustrated. The M0 metal scheme 516 comprises a power track M0_1 for a front side VSS power rail, and three M0 signal tracks M0_2, M0_3, M0_4, as described with respect to FIG. 3A. The BM0 metal scheme 518 comprises a power track BM0_1 for a back side VSS power rail, a further power track BM0_3 for a back side VDD power rail, and a signal track BM0_2 in between, as described with respect to FIG. 3A. Along a Z axis (perpendicular to the X-Y plane of FIG. 5A), the track BM0_1, the via interconnect 581, the VR via 582, and the track M0_1 overlap each other. In some embodiments, the edge 511 of the boundary 510 coincides with the center line of the track M0_1 and/or the center line of the track BM0_1.

In some embodiments, instead of the M0 metal scheme 516, the M0 metal scheme 517 is used. The M0 metal scheme 517 comprises a power track M0_1′ for a front side VSS power rail, and two M0 signal tracks M0_3, M0_4. The track M0_1′ overlaps both the track M0_1 and track M0_2 and provides a wider front side VSS power rail which, in turn, provides an increased contact area with the VR via 582 and reduces resistance and voltage (IR) drop, in one or more embodiments. In some embodiments, an upper edge of the track M0_1′ coincides with an upper edge of the track M0_2, and/or a lower edge of the track M0_1′ coincides with a lower edge of the track M0_1.

FIG. 5B is a schematic view of a layout 500B of a power tap cell, in accordance with some embodiments. In at least one embodiment, the layout 500B is stored on a non-transitory computer-readable recording medium. Components in FIG. 5B having corresponding components in FIGS. 2B-2C, 3A-3D, 5A are designated by the same reference numerals as in 2B-2C, 3A-3D, 5A.

A difference between the layout 500A and the layout 500B is that the power tap cell in the layout 500A has a single cell height 1 CH, whereas the power tap cell in the layout 500B has a double cell height 2 CH. The layout 500B comprises a boundary 520 corresponding to the boundary 510. The boundary 520 comprises edges 521, 512, 523, 524. The edges 521, 512 are elongated along the X axis, and the edges 523, 524 are elongated along the Y axis. The layout 500B further comprises CMG regions 562, 563, 564, and a stand-alone power tap structure 590 which comprises a via interconnect 591 and a VR via 592. The CMG region 563 extends around the via interconnect 591 and corresponds to a dielectric structure that surrounds the via interconnect 591. Spaces 568, 569 correspondingly between the CMG region 563 and the adjacent CMG regions 562, 564 correspond to further dielectric structures. In some embodiments, the dielectric structures corresponding to the CMG region 563 and the spaces 568, 569 comprise the same dielectric material. There is no active region, or active region portion, present in the Y axis between the power tap structure 590 and the CMG regions 562, 564. In some embodiments, spacings between the power tap structure 590 and the CMG regions 562, 564 (or power rails overlapping the CMG regions 562, 564) are free of any active region or any active region portion.

In some embodiments, the boundary 520 is obtained by combining the boundary 510 with a version of the boundary 510 flipped across the edge 511, and/or the CMG region 563 is obtained by combining the CMG region 561 with a version of the CMG region 561 flipped across the edge 511, and/or the via interconnect 591 is obtained by combining the via interconnect 581 with a version of the via interconnect 581 flipped across the edge 511, and/or the CMG region 564 is symmetrical to the CMG region 562 across the edge 511. In at least one embodiment, the power tap cell in FIG. 5B is symmetrical across the edge 511. In some embodiments, the CMG regions 563 corresponds to a CMG jog portion. In some embodiments, the via interconnect 591 and VR via 592 of the stand-alone power tap structure 590 are correspondingly formed together with, and/or in the same manner as, via interconnects and VR vias of one or more in-cell power tap structures, as described with respect to FIGS. 12A-12B.

The layout 500B is applicable to various metal schemes. In the example configuration in FIG. 5B, the M0 metal scheme 516 further comprises three M0 signal tracks M0_2′, M0_3′, M0_4′ which are symmetrical to the M0 signal tracks M0_2, M0_3, M0_4 across the edge 511. The BM0 metal scheme 518 comprises a further power track BM0_3′ for a further back side VDD power rail, and a further signal track BM0_2′. The tracks BM0_2′, BM0_3′ are symmetrical to the tracks BM0_2, BM0_3 across the edge 511, in one or more embodiments.

In some embodiments, instead of the M0 metal scheme 516, the M0 metal scheme 517 is used. The M0 metal scheme 517 in FIG. 5B further comprises M0 signal tracks M0_3′, M0_4′ which are symmetrical to the M0 signal tracks M0_3, M0_4 across the edge 511. In the M0 metal scheme 517 in FIG. 5B, a power track M0_11′ for a front side VSS power rail is obtained by combining the track M0_1′ with a version of the track M0_1′ flipped across the edge 511. The track M0_11′ overlaps the tracks M0_1, M0_2, M0_2′ and provides a wider front side VSS power rail which, in turn, provides an increased contact area with the VR via 592 and reduces resistance and voltage (IR) drop, in one or more embodiments. In some embodiments, an upper edge of the track M0_11′ coincides with an upper edge of the track M0_2, and/or a lower edge of the track M0_11′ coincides with a lower edge of the track M0_2′.

FIG. 6A is a schematic cross-sectional view of a circuit region of an IC device 600A, in accordance with some embodiments. In some embodiments, the circuit region in FIG. 6A corresponds to the power tap cell described with respect to FIG. 5A. In at least one embodiment, the IC device 600A corresponds to one or more of the IC devices and/or layouts described with respect to FIGS. 2A-5B. Corresponding components in FIGS. 3A-6A are designated by the same reference numerals.

The IC device 600A comprises a power tap structure 680 comprising a via interconnect 681 and a VR via 682. In at least one embodiment, the power tap structure 680, the via interconnect 681 and the VR via 682 correspond to the power tap structure 580, the via interconnect 581 and the VR via 582. The IC device 600A further comprises a dielectric structure (not shown) corresponding to the CMG region 561 and surrounding the via interconnect 681. The M0 layer has the M0 metal scheme 516, and comprises the tracks M0_1-M0_4. A front side VSS power rail 661 is provided along the track M0_1. The BM0 layer has the BM0 metal scheme 518, and comprises the tracks BM0_1-BM0_3. A back side VSS power rail 651 and a back side VDD power rail 653 are correspondingly provided along the tracks BM0_1, BM0_3.

The via interconnect 681 extends through the substrate 302 to come into electrical contact with the VSS power rail 651. The via interconnect 681 overlaps the track BM0_2. In the example configuration in FIG. 6A, no metal pattern is provided along the track BM0_2 and directly under the via interconnect 681. The VR via 682 is between and electrically couples the via interconnect 681 and the VSS power rail 661. The VR via 682 overlaps the track M0_2. In the example configuration in FIG. 6A, no metal pattern is provided along the track M0_2 and directly over the VR via 682.

In some embodiments, the M0 layer has the M0 metal scheme 517 instead of the M0 metal scheme 516. In the M0 metal scheme 517, a front side VSS power rail 671 is provided along the track M0_1′. As illustrated in FIG. 6A, the VSS power rail 671 of the M0 metal scheme 517 provides a greater contact area with the VR via 682 than the VSS power rail 661 of the M0 metal scheme 516, thereby advantageously reducing resistance and voltage (IR) drop, in one or more embodiments.

FIG. 6B is a schematic cross-sectional view of a circuit region of an IC device 600B, in accordance with some embodiments. In some embodiments, the circuit region in FIG. 6B corresponds to the power tap cell described with respect to FIG. 5B. In at least one embodiment, the IC device 600B corresponds to one or more of the IC devices and/or layouts described with respect to FIGS. 2A-6A. Corresponding components in FIGS. 3A-6B are designated by the same reference numerals.

The IC device 600B comprises a power tap structure 690 comprising a via interconnect 691 and a VR via 692. In at least one embodiment, the power tap structure 690, the via interconnect 691 and the VR via 692 correspond to the power tap structure 590, the via interconnect 591 and the VR via 592. The IC device 600B further comprises a dielectric structure (not shown) corresponding to the CMG region 563 and surrounding the via interconnect 691. The M0 layer has the M0 metal scheme 516, and comprises the tracks M0_1-M0_4 and tracks M0_2′-M0_4′. The front side VSS power rail 661 is provided along the track M0_1. The BM0 layer has the BM0 metal scheme 518, and comprises the tracks BM0_1-BM0_3 and tracks BM0_2′, BM0_3′. The back side VSS power rail 651, the back side VDD power rail 653, and a further back side VDD power rail 653′ are correspondingly provided along the tracks BM0_1, BM0_3, BM0_3′.

The via interconnect 691 extends through the substrate 302 to come into electrical contact with the VSS power rail 651. The via interconnect 691 overlaps the tracks BM0_2, BM0_2′. In the example configuration in FIG. 6B, no metal pattern is provided along the tracks BM0_2, BM0_2′ and directly under the via interconnect 691. The VR via 692 is between and electrically couples the via interconnect 691 and the VSS power rail 661. The VR via 692 overlaps the tracks M0_2, M0_2′. In the example configuration in FIG. 6B, no metal pattern is provided along the tracks M0_2, M0_2′ and directly over the VR via 692.

In some embodiments, the M0 layer has the M0 metal scheme 517 instead of the M0 metal scheme 516. In the M0 metal scheme 517, a front side VSS power rail 672 is provided along the track M0_11′. As illustrated in FIG. 6B, the VSS power rail 672 of the M0 metal scheme 517 provides a greater contact area with the VR via 692 than the VSS power rail 661 of the M0 metal scheme 516, thereby advantageously reducing resistance and voltage (IR) drop, in one or more embodiments.

Various example layouts of a first circuit region in accordance with some embodiments are described with respect to FIGS. 7A-7C, and various example layouts of a second circuit region in accordance with some embodiments are described with respect to FIGS. 8A-8D. In the example layouts in FIGS. 7A, 8A, a top semiconductor device is powered from a back side power rail, in a configuration sometimes referred to herein as “LEQA” (layout equivalent circuit-LEQ). In the example layouts in FIGS. 7B, 8B, a top semiconductor device is powered from both a back side power rail and a front side power rail by an in-cell power tap structure, in a configuration sometimes referred to herein as “LEQB”. In the example layouts in FIGS. 7C, 8C, a top semiconductor device is powered from a front side power rail, in a configuration sometimes referred to herein as “LEQC”. In the example layout in FIG. 8D, the second circuit region has a configuration sometimes referred to herein as “EEQ” (electrical equivalent circuit). Corresponding components in FIGS. 2B-8D are designated by the same reference numerals.

FIG. 7A includes a schematic circuit diagram of a circuit region and schematic views at various layers of a corresponding layout of the circuit region, in accordance with some embodiments. In some embodiments, the circuit region in FIG. 7A corresponds to a circuit region of one or more of the IC devices and/or layouts described with respect to FIGS. 2A-6B.

In FIG. 7A, the circuit region is an inverter (INV). The inverter INV comprises an NMOS transistor N1 and a PMOS transistor P1 coupled in series between VSS and VDD. Gates of the transistors N1, P1 are coupled to an input IN. A common source/drain of the transistors N1, P1 is coupled to an output ZN1. In at least one embodiment, the inverter INV is implemented by one or more CFET devices having the top semiconductor devices corresponding to the transistor N1, and the bottom semiconductor devices corresponding to the transistor P1.

A layout 700A in FIG. 7A is a layout of a cell INVD1, in accordance with some embodiments. The cell INVD1 represented by the layout 700A corresponds to the inverter INV, and includes one CFET device with one top semiconductor device corresponding to the transistor N1, and one bottom semiconductor device corresponding to the transistor P1. The layout 700A comprises an upper layer 751 and a lower layer 752. The layout 700A further comprises a boundary 710 (i.e., cell boundary). In some embodiments, the boundary 710 corresponds to the boundary of one or more of the cells C1-C3 described with respect to FIG. 2C. The boundary 710 comprises edges 711, 712, 713, 714. The edges 711, 712 are elongated along the X axis, and the edges 713, 714 are elongated along the Y axis. In some embodiments, the X axis is an example of one of a first direction and a second direction, and the Y axis is an example of the other of the first direction and the second direction. The edges 711, 712, 713, 714 are connected together to form the closed boundary 710. In a place-and-route operation, cells are placed in an IC layout in abutment with each other at their respective boundaries. The rectangular shape of the boundary 710 is an example. Other boundary shapes for various cells are within the scope of various embodiments. The cell represented by the layout 700A has a cell height of 1 CH.

The upper layer 751 includes the top semiconductor device, e.g., transistor N1, of the corresponding CFET device. The upper layer 751 comprises an NMOS active region OD_51 as a top active region, a functional gate region G1 schematically represented by its center line, MD contacts MD_50, MD_51, an MDLI interconnect MDLI_51, CMG regions CMG_51, CMG_52, and a via interconnect PV_50. In some embodiments, the layout 700A further comprises one or more M0 metal patterns (not shown) along one or more of the tracks M0_1-M0_4. The edges 711, 712 of the boundary 710 correspondingly coincide with the center lines of the regions CMG_51, CMG_52. In some embodiments, the layout 700A further comprises dummy gate regions (not shown) correspondingly on the edges 713, 714 of the boundary 710.

The lower layer 752 includes the bottom semiconductor device, e.g., transistor P1, of the corresponding CFET device. The boundary 710, regions CMG_51, CMG_52, interconnect MDLI_51 and via interconnect PV_50 are common for both the upper layer 751 and the lower layer 752. The lower layer 752 further comprises a PMOS active region OD_52 as a bottom active region, BMD contacts BMD_50, BMD_50′, BMD_51, BVD vias BVD_50, BVD_50′, and VSS and VDD power rails (not shown) correspondingly on the tracks BM0_1, BM0_3. In some embodiments, the layout 700A further comprises one or more BM0 metal patterns (not shown) along the track BM0_2. The functional gate regions of the transistors N1, P1 are electrically coupled to each other (e.g., by an MGLI interconnect) and are designated by the same reference numeral, i.e., gate region G1. As can be seen in FIG. 7A, the contact BMD_50′ for the via interconnect PV_50 and VSS is spaced, along the Y axis, from the contact BMD_50 for VDD. A pitch, i.e., a center-to-center distance along the X axis, between directly adjacent MD contacts (or BMD contacts) is the same as the pitch CPP between directly adjacent gate regions. Like the gate regions, the MD contacts and BMD contact are elongated along the Y axis.

The gate region G1 corresponds to the input IN. The source of the transistor P1 is electrically coupled by the contact BMD_50 and via BVD_50 to the VDD power rail on the track BM0_3. The drains of the transistors N1, P1 are electrically coupled together by the interconnect MDLI_51, and the corresponding contacts MD_51, BMD_51 correspond to the output ZN1.

The source of the transistor N1 is electrically coupled by the contact MD_50, via interconnect PV_50, contact BMD_50′ and via BVD_50′ to the back side VSS power rail on the track BM0_1. Thus, power is provided from the back side VSS power rail on the track BM0_1 to the top semiconductor device N1, through the via interconnect PV_50, in an LEQA configuration as described herein. In some embodiments, a cross-sectional view along the center line of the contact MD_50 (or the contact BMD_50) corresponds to the cross-sectional view in FIG. 3A.

FIG. 7B is a schematic view of an alternative layout 700B of the inverter in FIG. 7A, in accordance with some embodiments.

The lower layer of the layout 700B is the same as the lower layer 752 of the layout 700A, and is omitted from FIG. 7B. Compared to the layout 700A, the upper layer 751 of the layout 700B additionally comprises a VR via VR_50 configured to electrically couple the contact MD_50 to a front side VSS power rail on the track M0_1. Thus, power is provided to the top semiconductor device N1 both from the back side VSS power rail on the track BM0_1 as described with respect to the layout 700A, and from the front side VSS power rail on the track M0_1 through the via VR_50, in an LEQB configuration as described herein. An in-cell power tap structure is configured by the via BVD_50′, contact BMD_50′, via interconnect PV_50, contact MD_50, via VR_50. In some embodiments, a cross-sectional view along the center line of the contact MD_50 corresponds to the cross-sectional view in FIG. 3B.

FIG. 7C is a schematic view of a further alternative layout 700C of the inverter in FIG. 7A, in accordance with some embodiments.

Compared to the layout 700B, the via interconnect PV_50 is omitted from both the upper layer 751 and the lower layer (not shown) of the layout 700C. The via BVD_50′ and contact BMD_50′ are also omitted from the lower layer of the layout 700C. Thus, power is provided to the top semiconductor device N1 from the front side VSS power rail on the track M0_1 through the via VR_50, in an LEQC configuration as described herein. In some embodiments, a cross-sectional view along the center line of the contact MD_50 corresponds to the cross-sectional view in FIG. 3C.

As illustrated in FIGS. 7A, 7B, the presence of the via interconnect PV_50 causes a width of the corresponding region CMG_51 along the Y axis to be sufficiently large, to ensure that a dielectric structure corresponding to the region CMG_51 provides sufficient isolation for the via interconnect PV_50 embedded therein. Because the via interconnect PV_50 is omitted from the layout 700C, a CMG region with a width as large as the region CMG_51 is not necessary. In the example configuration in FIG. 7C, a region CMG_53 with a reduced width (compared to the width of the region CMG_51) replaces the region CMG_51. Because the region CMG_53 has a reduced width, it is possible to increase the active region width of the active region between the regions CMG_52, CMG_53. In the example configuration in FIG. 7C, an active region OD_53 with an increased width larger than the width of the active region OD_51 replaces the active region OD_51, and a contact MD_53 longer than the contact MD_51 replaces the contact MD_51. In the lower layer of the layout 700C, a bottom active region having the increased width replaces the active region OD_52.

In some embodiments, the LEQB configuration in FIG. 7B with a via interconnect, a wider CMG region surrounding the via interconnect, and a narrower active region corresponds to the in-cell power tap structures 284, 288 and the active region portions 270, 274, 274′, 276, 276′. The LEQC configuration in FIG. 7C with no via interconnect, a narrower CMG region, and a wider active region corresponds to the active region portions 271, 272, 273, 275, 277, 273′, 275′, 277′.

FIG. 8A includes a schematic circuit diagram of a circuit region and schematic views at various layers of a corresponding layout of the circuit region, in accordance with some embodiments. In some embodiments, the circuit region in FIG. 8A corresponds to a circuit region of one or more of the IC devices and/or layouts described with respect to FIGS. 2A-6B.

In FIG. 8A, the circuit region is a two-input two-output AND-OR-Invert (AOI22) logic. The AOI22 logic comprises inputs A1, A2, B1, B2, an output ZN3, and transistors PA1, PA2, PB1, PB2, NA1, NA2, NB1, NB2. Gates of the transistors PA1, NA1 are electrically coupled to the input A1. Gates of the transistors PA2, NA2 are electrically coupled to the input A2. Gates of the transistors PB1, NB1 are electrically coupled to the input B1. Gates of the transistors PB2, NB2 are electrically coupled to the input B2. Sources of the transistors PB1, PB2 are electrically coupled to VDD. Drains of the transistors PB1, PB2 are electrically coupled to a node CON. Sources of the transistors PA1, PA2 are electrically coupled to the node CON. Drains of the transistors PA1, PA2 are electrically coupled to the output ZN3. The transistors NA1, NA2 are electrically coupled in series between VSS and the output ZN3. The transistors NB1, NB2 are electrically coupled in series between VSS and the output ZN3.

A layout 800A in FIG. 8A is a layout of a cell AOI22D1, in accordance with some embodiments. The cell AOI22D1 represented by the layout 800A corresponds to the AOI22 logic, and includes first through fourth CFET devices. The transistors NA1, PA1 are correspondingly top and bottom semiconductor devices of the first CFET device, the transistors NA2, PA2 are correspondingly top and bottom semiconductor devices of the second CFET device, the transistors NB1, PB1 are correspondingly top and bottom semiconductor devices of the third CFET device, and the transistors NB2, PB2 are correspondingly top and bottom semiconductor devices of the fourth CFET device. The layout 800A comprises an upper layer 871 and a lower layer 872. The layout 800A further comprises a boundary 830 corresponding to the boundary 810. The cell represented by the layout 800A has a cell height of 1 CH.

The upper layer 871 includes the top semiconductor devices, e.g., transistors NA1, NA2, NB1, NB2, of the corresponding CFET devices. The upper layer 871 comprises an NMOS active region OD_71, gate regions G4-G7 schematically represented by their center lines, MD contacts MD_70-MD_74, CMG regions CMG_71, CMG_72, and via interconnects PV_70, PV_72, PV_74. In some embodiments, the layout 800A further comprises one or more M0 metal patterns (not shown) along one or more of the tracks M0_1-M0_4, and/or dummy gate regions on corresponding edges of the boundary 830.

The lower layer 872 includes the bottom semiconductor devices, e.g., transistors PA1, PA2, PB1, PB2, of the corresponding CFET devices. The boundary 830, regions CMG_71, CMG_72, and via interconnects PV_70, PV_72, PV_74 are common for both the upper layer 871 and the lower layer 872. The lower layer 872 further comprises a PMOS active region OD_72, BMD contacts BMD_70-BMD_74, BMD_70′ and BMD_74′, BVD vias BVD_70, BVD_71, BVD_74, and VSS and VDD power rails (not shown) correspondingly on the tracks BM0_1, BM0_3. In some embodiments, the layout 800A further comprises one or more BM0 metal patterns (not shown) along the track BM0_2. The functional gate regions of each pair of corresponding transistors, i.e., NA1 and PA1, NA2 and PA2, NB1 and PB1, NB2 and PB2, are electrically coupled to each other (e.g., by an MGLI interconnect) and are designated by the same reference numeral, i.e., gate regions G6, G7, G5, G4. As can be seen in FIG. 8A, the contact BMD_70′ for the via interconnect PV_70 and VSS is spaced, along the Y axis, from the contact BMD_70, and the contact BMD_74′ for the via interconnect PV_74 and VSS is spaced, along the Y axis, from the contact BMD_74.

The gate regions G4-G7 correspond to the inputs B2, B1, A1, A2. The common source of the transistors PB1, PB2 is electrically coupled by the contact BMD_71 and via BVD_71 to the VDD power rail on the track BM0_3. The contacts BMD_70, BMD_72, BMD_74 correspond to the node CON. The contacts MD_72, BMD_73 correspond to the output ZN3.

The source of the transistor NB2 is electrically coupled by the contact MD_70, via interconnect PV_70, contact BMD_70′ and via BVD_70 to the VSS power rail on the track BM0_1. The source of the transistor NA2 is electrically coupled by the contact MD_74, via interconnect PV_74, contact BMD_74′ and via BVD_74 to the VSS power rail on the track BM0_1. Thus, power is provided from the back side VSS power rail along the track BM0_1 to the top semiconductor devices NB2, NA2, through the via interconnects PV_70, PV_74, in an LEQA configuration. In some embodiments, cross-sectional views along the center lines of the contacts MD_70, MD_74 correspond to the cross-sectional view in FIG. 3A.

The common drain of the transistors NA1, NB1 is electrically coupled by the contact MD_72, via interconnect PV_72, contact BMD_73 to the common drain of the transistors PA1, PA2. Thus, the via interconnect PV_72 is configured for signal transmission to electrically couple a top source/drain to a bottom source/drain, as described herein with respect to FIGS. 3D, 4B.

FIG. 8B is a schematic view of an alternative layout 800B of the AOI22 logic in FIG. 8A, in accordance with some embodiments.

The lower layer of the layout 800B is the same as the lower layer 852 of the layout 800A, and is omitted from FIG. 8B. Compared to the layout 800A, the upper layer 851 of the layout 800B additionally comprises VR vias VR_70, VR_74 configured to electrically couple the contacts MD_70, MD_74 to a front side VSS power rail on the track M0_1. Thus, power is provided to the corresponding top semiconductor devices both from the back side VSS power rail on the track BM0_1 as described with respect to the layout 800A, and from the front side VSS power rail on the track M0_1 through the vias VR_70, VR_74 in an LEQB configuration. Two in-cell power tap structures are configured in a manner similar to FIG. 7B. In some embodiments, cross-sectional views along the center lines of the contacts MD_70, MD_74 correspond to the cross-sectional view in FIG. 3B.

In the layout 800B, the via interconnects PV_70, PV_72 are cut or disconnected from each other by a cut-PV region 801 of a cut-PV mask. A further cut-PV region (not shown) of the cut-PV mask is between the via interconnects PV_72, PV_74. In a manufactured IC device corresponding to the layout 800B, the cut-PV regions correspond to dielectric structures that electrically isolate adjacent via interconnects from each other. Cut-PV regions configure lengths of via interconnects along the X axis. In some embodiments, the lengths of via interconnects are configured by corresponding cut-PV regions to be as small as minimally required by predetermined design rules, so as to maximize active region widths in regions where via interconnects are not formed.

FIG. 8C is a schematic view of a further alternative layout 800C of the AOI22 logic in FIG. 8A, in accordance with some embodiments.

Compared to the layout 800B, the via interconnects PV_70, PV_74 are omitted from both the upper layer 851 and the lower layer (not shown) of the layout 800C. The vias BVD_70, BVD_74 and contacts BMD_70′, BMD_74′ are also omitted from the lower layer of the layout 800C. Thus, power is provided to the corresponding top semiconductor devices from the front side VSS power rail on the track M0_1 through the vias VR_70, VR_74 in an LEQC configuration. In some embodiments, cross-sectional views along the center lines of the contacts MD_70, MD_74 correspond to the cross-sectional view in FIG. 3C.

Similarly to the layout 700C, widths of CMG regions are reduced and widths of active regions are increased where via interconnects are not arranged. In the example configuration in FIG. 8C, a CMG region CMG_73 replaces the region CMG_71. The region CMG_73 comprises a portion 807 surrounding the via interconnect PV_72 and having a same width along the Y axis as the region CMG_71. The region CMG_73 further comprises portions 805, 809 with a reduced width where no via interconnects are arranged. In some embodiments, the portion 807 corresponds to a CMG jog portion as described with respect to FIG. 2C.

The active region OD_73 and a corresponding bottom active region (not shown) replace the active regions OD_71, OD_72. The active region OD_73 comprises a portion 804 corresponding to the via interconnect PV_72 and having a same width as the active region OD_71 along the Y axis. The active region OD_73 further comprises a portion 802 with an increased width. In some embodiments, the portion 802 corresponds to one or more of the active region portions 271, 272, 273, 275, 277, 273′, 275′, 277′. A contact MD_75 longer than the contact MD_71 replaces the contact MD_71.

FIG. 8D is a schematic view of a further alternative layout 800D of the AOI22 logic in FIG. 8A, in accordance with some embodiments.

Compared to the layouts 800A-800C, the layout 800D has a double cell height 2 CH, and no via interconnect for signal transmission. The layout 800D comprises a boundary 840, an upper layer, and a lower layer. For simplicity, the upper layer of the layout 800D is illustrated in FIG. 8D, whereas the lower layer is omitted. The upper layer comprises an NMOS active regions OD_80, OD_81, gate regions schematically represented by their center lines and labelled with the reference numerals of the corresponding transistors, MD contacts MD_80-MD_84, an MDLI interconnect MDLI_80, CMG regions CMG_81-CMG_83, and via interconnects PV_82, PV_84. In some embodiments, the layout 800A further comprises one or more M0 metal patterns (not shown) along one or more of the tracks M0_1-M0_8, and/or dummy gate regions on corresponding edges (along the Y axis) of the boundary 840.

The boundary 840, regions CMG_81-CMG_83, and via interconnects PV_82, PV_84 are common for both the upper layer and the lower layer. The lower layer further comprises various features (not shown) such as PMOS active regions, BMD contacts, BVD vias, VSS power rails on the tracks BM0_1, BM0_5, a VDD power rail on the track BM0_3. In some embodiments, the layout 800D further comprises one or more BM0 metal patterns (not shown) along one or more of signal tracks BM0_2, BM0_4. The functional gate regions of each pair of corresponding transistors, i.e., NA1 and PA1, NA2 and PA2, NBI and PB1, NB2 and PB2, are electrically coupled to each other (e.g., by an MGLI interconnect). The contact MD_80 extends continuously along the Y axis across both the active regions OD_80, OD_81, and correspond to the output ZN3.

The source of the transistor NA2 is electrically coupled by the contact MD_82, via interconnect PV_82, a BMD contact and a BVD via to the VSS power rail on the track BM0_5. The source of the transistor NB2 is electrically coupled by the contact MD_84, via interconnect PV_84, a BMD contact and a BVD via to the VSS power rail on the track BM0_1. Thus, power is provided from the back side VSS power rails to the top semiconductor devices NA2, NB2 through the via interconnects PV_82, PV_84, in an LEQA configuration. In some embodiments, the layout 800D is modifiable to have an LEQB configuration or an LEQC configuration, in manners similar to FIGS. 7B, 7C.

In at least one embodiment, at least one of the layouts 700A-700C, 800A-800D is stored as a standard cell in at least one library on a non-transitory computer-readable recording medium, and is read out and placed into a layout of an IC device to be designed and/or manufactured. In at least one embodiment, one or more advantages described herein are achievable by one or more of the layouts 700A-700C, 800A-800D, and/or IC devices corresponding to one or more of the layouts 700A-700C, 800A-800D.

FIG. 9 includes schematic views of various metal and via interconnect schemes and applicable circuit regions in layouts of one or more IC devices, in accordance with some embodiments. In FIG. 9, example M0 metal schemes 911-913 for the M0 layer, example BM0 metal schemes 921-923 for the BM0 layer, and example PV schemes 930, 940 for via interconnects are arranged over a region of 2 CH as indicated by lines 901-903.

The M0 metal scheme 911 corresponds to the M0 metal scheme 516. The M0 metal scheme 911 includes two VSS power rails centered correspondingly on the lines 901, 903, and six M0 signal tracks between the two VSS power rails. Over a single cell height, the M0 metal scheme 911 comprises a VSS power rail and three M0 signal tracks.

The M0 metal scheme 912 includes two VSS power rails centered correspondingly on the lines 901, 903, and five M0 signal tracks between the two VSS power rails. Among the five M0 signal tracks, a shared track 914 is centered on the line 902. Over a single cell height, the M0 metal scheme 912 comprises a VSS power rail, two M0 signal tracks, and a shared track (i.e., the shared track 914).

The M0 metal scheme 913 includes two VSS power rails centered correspondingly on the lines 901, 903, and four M0 signal tracks between the two VSS power rails. Over a single cell height, the M0 metal scheme 912 comprises a VSS power rail, two M0 signal tracks, and a shared space (i.e., the space between signal tracks 915, 916).

The BM0 metal scheme 921 includes two VSS power rails centered correspondingly on the lines 901, 903, a VDD power rail centered on the line 902, and no BM0 signal tracks. Over a single cell height, the BM0 metal scheme 921 comprises a VDD power rail and a VSS power rail.

The BM0 metal scheme 922 corresponds to the BM0 metal scheme 518. The BM0 metal scheme 922 includes two VSS power rails centered correspondingly on the lines 901, 903, a VDD power rail centered on the line 902, and two BM0 signal tracks each between a pair of immediately adjacent power rails. Over a single cell height, the BM0 metal scheme 922 comprises a VDD power rail, a VSS power rail, and one BM0 signal track in between.

The BM0 metal scheme 923 includes two VSS power rails centered correspondingly on the lines 901, 903, a VDD power rail centered on the line 902, and four BM0 signal tracks two of which are between each pair of immediately adjacent power rails. Over a single cell height, the BM0 metal scheme 923 comprises a VDD power rail, a VSS power rail, and two BM0 signal tracks in between.

The PV scheme 930 includes two PV tracks 931, 933 for via interconnects. The PV tracks 931, 933 are centered correspondingly on the lines 901, 903. The PV scheme 930 includes no PV track on the line 902. Along the Y axis, the PV tracks 931, 933 have the same width. The PV scheme 930 is applied to the layouts 700A-700C, 800A-800D, for example, as can be seen from the layouts 800A, 800D illustrated in FIG. 9. In layouts adopting the PV scheme 930, wider CMG regions (e.g., regions CMG_81, CMG_83) are arranged along the lines 901, 903 with the PV tracks 931, 933, whereas a narrower CMG region (e.g., region CMG_82) is arranged along the line 902 with no via interconnect.

The PV scheme 940 includes three PV tracks 941-943 for via interconnects. The PV tracks 941-943 are centered correspondingly on the lines 901-903. Along the Y axis, the PV tracks 941-943 have the same width which is smaller than the width of each of the PV tracks 931, 933. In layouts adopting the PV scheme 940, CMG regions (not shown) having the same width in the Y axis are arranged along the lines 901-903. In some embodiments, the PV track 942 is configured for signal transmission but not for power delivery, whereas each of the PV tracks 931, 933, 941, 943 is configurable for both signal transmission and power delivery. The PV scheme 930 is an example of an arrangement with 0.5 PV track per cell height. For example, over one cell height between the lines 901, 902, there is 0.5 PV track including one half of the PV track 931. The PV scheme 940 is an example of an arrangement with 1 PV track per cell height. For example, over one cell height between the lines 901, 902, there is 1 PV track including one half of the PV track 941 and one half of the PV track 942.

In some embodiments, a layout is generated based on a combination of one of the M0 metal schemes 911-913, one of the BM0 metal schemes 921-923, and one of the PV schemes 930, 940. The described M0 metal schemes, BM0 metal schemes and PV schemes are examples. Other M0 metal schemes, BM0 metal schemes and/or PV schemes are within the scopes of various embodiments. For example, one or more of PV count, pitch, width, or the like, is/are customizable to provide different PV schemes.

In FIG. 9, the layout 800A is an example where a via interconnect for signal transmission, e.g., the via interconnect PV_72, is on the cell boundary, e.g., the line 901. To avoid short circuits, a constraint is enforced in a place-and-route operation such that a via interconnect or an MD contact of another cell are not permitted to be placed in a constraint zone 950 associated with the via interconnect PV_72. In at least one embodiment, it is possible to bypass such a constraint by replacing a cell having a via interconnect for signal transmission on the cell boundary (e.g., the layout 800A) with an equivalent cell for the same circuit and having no via interconnect for signal transmission (e.g., the layout 800D).

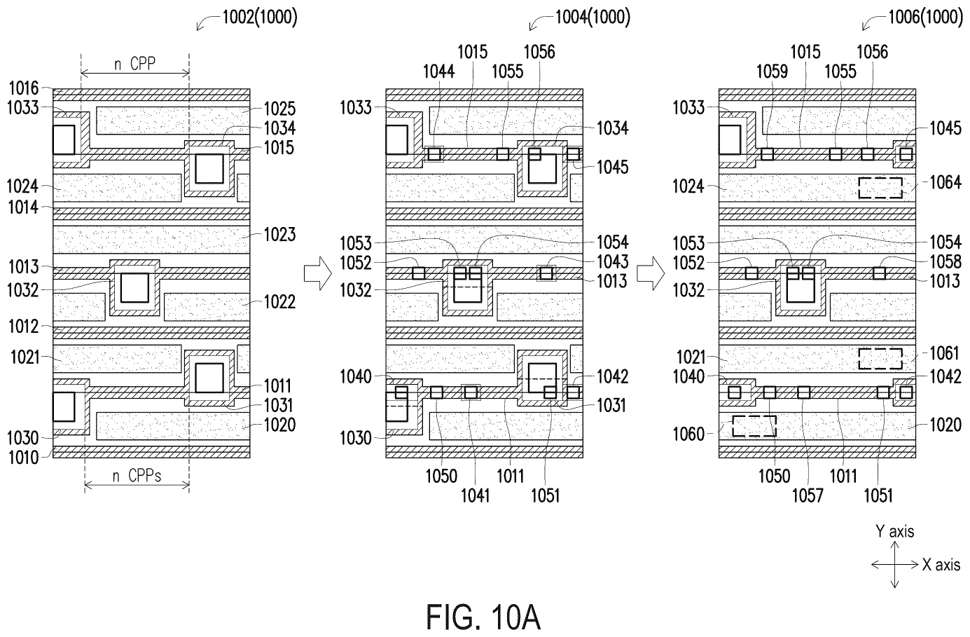

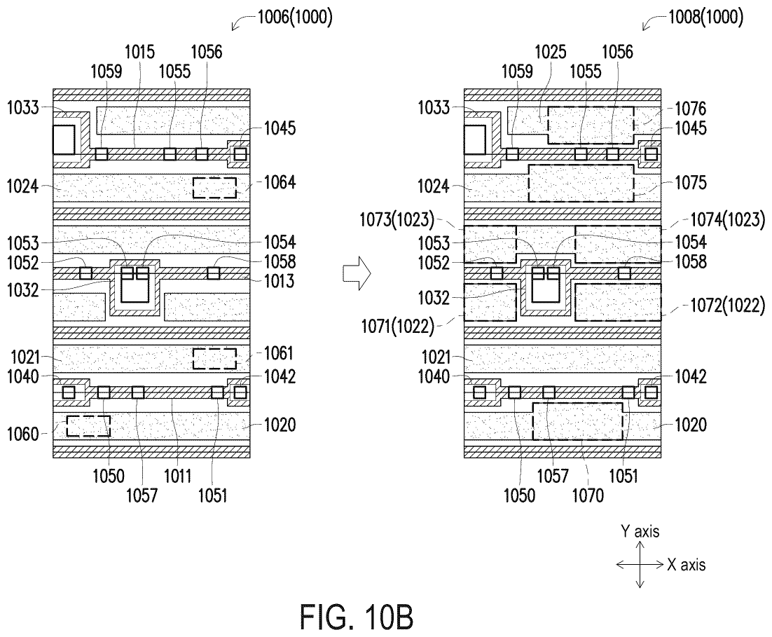

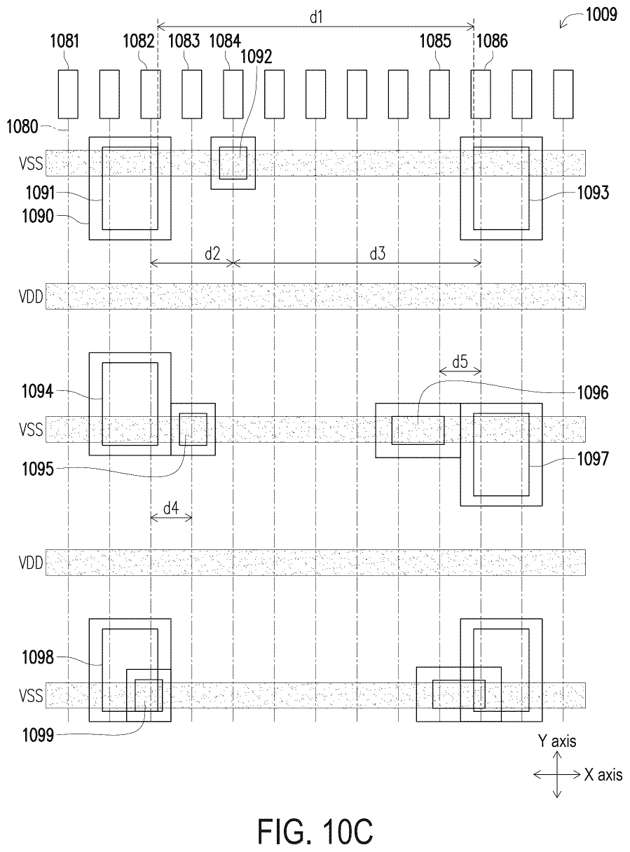

In some embodiments, an Automatic Placement and Routing (APR) operation is performed to generate a layout of an IC device based on an IC schematic, e.g., a netlist. For example, the layout is generated in the form of a Graphic Design System (GDS) file by an EDA tool, such as an APR tool. In at least one embodiment, the APR tool is configured to perform a power planning operation, a cell placement operation, a clock tree synthesis (CTS) operation and a routing operation. At the power planning operation, the APR tool performs power planning to generate a power delivery structure, e.g., as described with respect to FIG. 2B. At the cell placement operation, the APR tool performs cell placement, e.g., as described with respect to FIG. 2C. For example, cells configured to provide pre-defined functions and having pre-designed layouts are stored in one or more cell libraries. The APR tool accesses various cells from one or more cell libraries, and places the cells in an abutting manner to generate a layout corresponding to the IC schematic. At the CTS operation, the APR tool performs CTS to minimize skew and/or delays potentially present due to the placement of circuit elements in the layout. At the routing operation, the APR tool performs routing to route various nets interconnecting the placed circuit elements. The routing is performed to ensure that the routed interconnections or nets satisfy a set of constraints. The described APR tool/operation is an example. Other arrangements are within the scope of various embodiments. Examples of the power planning operation and the cell placement operation in accordance with some embodiments are described herein with respect to FIGS. 10A-10C.

FIGS. 10A, 10B include schematic views of various intermediate layouts 1002, 1004, 1006, 1008 which are versions of a layout 1000 of a circuit region of an IC device at various design stages, in accordance with some embodiments. In some embodiments, the layout 1000 corresponds to one or more of the IC devices and/or layouts described with respect to FIGS. 2A-9.

The intermediate layout 1002 in FIG. 10A comprises a plurality of CMG regions 1010-1016 and a plurality of active regions 1020-1025 arranged alternatingly along the Y axis. Initially, each of the CMG regions 1010-1016 has a constant width, and each of the active regions 1020-1025 has a constant width. The intermediate layout 1002 further comprises a back side power delivery network and a front side power delivery network each having one or more power rails (not shown) overlapping the CMG regions 1010-1016 along the Z axis, as described herein. As part of the power planning operation, power tap cells with stand-alone power tap structures 1030-1034 are arranged uniformly in the X axis and Y axis throughout the intermediate layout 1002, to couple the back side power delivery network with the front side power delivery network. In some embodiments, one or more of the stand-alone power tap structures 1030-1034 correspond to one or more of the stand-alone power tap structures 240, 280, 580, 590, 680, 690. The stand-alone power tap structures are distributed in accordance with a predetermined power delivery network (PDN) guideline. In some embodiments, the PDN guideline requires that, along a power rail, there is a power tap structure for every length unit, e.g., n CPPs. In the example configuration in FIG. 10A, the stand-alone power tap structures are arranged such that an edge-to-edge distance between two immediately adjacent stand-alone power tap structures, e.g., 1030, 1031, along a power rail (not shown, but overlapping the CMG region 1011) is n CPPs. In a non-limiting example, n=8.

The intermediate layout 1004 in FIG. 10A is obtained when standard cells are read from cell libraries and placed in the intermediate layout 1002. In some embodiments, the cell libraries include, for each circuit, multiple cells with different cell layouts. In an aspect, the multiple cells of the same circuit have different configurations LEQA, LEQB, LEQC for powering top semiconductor devices, for example, as described with respect to FIGS. 7A-7C where the circuit is an inverter, and/or with respect to FIGS. 8A-8C where the circuit is an AOI22 logic. In another aspect, the multiple cells of the same circuit have different configurations for signal transmission, e.g., using a via interconnect for signal transmission as in FIGS. 8A-8C, or without using a via interconnect for signal transmission as in FIG. 8D. As a result of the cell placement, various in-cell power tap structures 1040-1045 and VR vias 1050-1056 are arranged along the VSS power rails (not shown) which correspondingly overlap the CMG regions 1011, 1013, 1015. In some embodiments, one or more of the in-cell power tap structures 1040-1045 correspond to one or more of the in-cell power tap structures 244, 248, 284, 288, 309, or the like, and/or one or more of the VR vias 1050-1056 correspond to one or more of the VR vias 243, 247, 251, 377, or the like.

Based on the intermediate layout 1004, the APR tool is configured to identify, along a power rail, power tap structures which overlap each other, or adjacent to each other. Two power tap structures are considered adjacent when a distance along the X axis between the two power tap structures is a predetermined distance or less. In at least one embodiment, the predetermined distance is 1 CPP. For example, two power tap structures are considered adjacent when an edge-to-edge distance along the X axis between the two power tap structures is 1 CPP or less, as described with respect to FIG. 10C. Other predetermined distances for determining adjacent power tap structures are within the scopes of various embodiments. When power tap structures are identified as overlapping or adjacent, the APR tool is configured to merge the power tap structures or remove at least one of the power tap structures. As a result, it is possible in one or more embodiments to advantageously reduce the number of large stand-alone power tap structures. During the power tap structure merging and/or removal, the VR vias 1050-1056 are unaffected.

For example, along the VSS power rail overlapping the CMG region 1011, the stand-alone power tap structure 1030 overlaps the in-cell power tap structure 1040. In some embodiments, the overlapping stand-alone power tap structure 1030 and in-cell power tap structure 1040 are merged into one power tap structure with an effect/result similar to removing one of the stand-alone power tap structure 1030 and the in-cell power tap structure 1040. In at least one embodiment, because the in-cell power tap structure 1040 is smaller in size, it is preferred over the stand-alone power tap structure 1030, and the stand-alone power tap structure 1030 is removed as shown in the intermediate layout 1006. Similarly, the stand-alone power tap structure 1031 overlaps or is adjacent to the in-cell power tap structure 1044, and is removed as shown in the intermediate layout 1006. Because the in-cell power tap structures 1040, 1042 satisfy the PDN guideline, the in-cell power tap structure 1041 is not necessary, and is replaced with a VR via 1057 as show in the intermediate layout 1006. In some embodiments, the replacement of the in-cell power tap structure 1041 with the VR via 1057 comprises replacing a cell having the LEQB configuration (e.g., the layout 700B or 800B) with an equivalent cell of the same circuit and having the LEQC configuration (e.g., the layout 700C or 800C).

For another example, along the VSS power rail overlapping the CMG region 1013, the in-cell power tap structure 1043 is between the stand-alone power tap structure 1032 and a further stand-alone power tap structure (not shown) at n CPPs to the right from the stand-alone power tap structure 1032. Because the stand-alone power tap structure 1032 and the further stand-alone power tap structure satisfy the PDN guideline, the in-cell power tap structure 1043 is not necessary, and is replaced with a VR via 1058 as show in the intermediate layout 1006. In some embodiments, the replacement of the in-cell power tap structure 1043 with the VR via 1058 comprises replacing a cell having the LEQB configuration with an equivalent cell of the same circuit and having the LEQC configuration, as described herein.

For a further example, along the VSS power rail overlapping the CMG region 1015, the stand-alone power tap structure 1034 overlaps the in-cell power tap structure 1045, and is removed as show in the intermediate layout 1006. The in-cell power tap structure 1044 is between the stand-alone power tap structure 1033 and the in-cell power tap structure 1045 which satisfy the PDN guideline, and is replaced with a VR via 1059 as show in the intermediate layout 1006.

Compared to the intermediate layout 1004, three stand-alone power tap structures 1030, 1031, 1034 are removed from the intermediate layout 1006. As a result, active region portions 1060, 1061, 1064 at locations previously occupied correspondingly by the stand-alone power tap structures 1030, 1031, 1034 are generated and added to the corresponding active regions 1020, 1021, 1024, thereby providing area improvements in one or more embodiments. The same intermediate layout 1006 described with respect to FIG. 10A is illustrated again in FIG. 10B for case of description.

As shown in the intermediate layout 1008 in FIG. 10B, in regions where via interconnects are absent between adjacent power tap structures, it is possible to increase the active region width to obtain performance improvements in one or more embodiments. For example, compared to the intermediate layout 1006, the following active region portions in the intermediate layout 1008 are configured by the APR tool to have an increased active region width: an active region portion 1070 of the active region 1020, active region portions 1071, 1072 of the active region 1022, active region portions 1073, 1074 of the active region 1023, an active region portion 1075 of the active region 1024, and an active region portion 1076 of the active region 1025. In some embodiments, a region free of via interconnects is created or expanded by replacing a cell having the LEQA configuration (e.g., the layout 700A or 800A) with an equivalent cell of the same circuit and having the LEQC configuration (e.g., the layout 700C or 800C). Alternatively or additionally, in at least one embodiment, a region free of via interconnects is created or expanded by replacing a cell have one or more via interconnects for signal transmission (e.g., the layouts 800A-800C) with an equivalent cell of the same circuit and having no via interconnects for signal transmission (e.g., the layout 800D).

FIG. 10C is schematic view of an intermediate layout 1009 similar to the intermediate layout 1004 in FIG. 10A, and showing various examples for determining adjacent power tap structures, in accordance with some embodiments.

The intermediate layout 1009 includes a plurality of VDD power rails and a plurality of VSS power rails arranged alternatingly along the Y axis. The intermediate layout 1009 further includes a plurality of MD contacts arranged side by side along the X axis, at a regular pitch of CPP as described herein. For simplicity, some MD contacts are designated as 1081-1086, whereas other MD contacts are not numbered. Center lines of the MD contacts are also illustrated in FIG. 10C. For simplicity, the center line of the MD contact 1081 is designated as 1080, whereas the center lines of the other MD contacts are not numbered. The intermediate layout 1009 further comprises a plurality of power tap structures, including stand-alone power tap structures 1091, 1093, 1094, 1097, 1098, and in-cell power tap structures 1092, 1095, 1096, 1099. CMG regions each surrounding a corresponding power tap structure are also illustrated in FIG. 10C. For example, a CMG region 1090 surrounds the corresponding power tap structure 1091. For simplicity, the CMG regions surrounding the other power tap structures are not numbered.

In some embodiments, for determining adjacent power tap structures and/or for ensuring that at least one predetermined PDN guideline is satisfied, an edge-to-edge distance between power tap structures is considered. For example, in FIG. 10C, a distance d1 is an edge-to-edge distance between facing edges of the power tap structures 1091, 1093 which are immediately adjacent stand-alone power tap structures. In the example configuration in FIG. 10C, a predetermined PDN guideline is satisfied when d1 is 8 CPPs or less.

In at least one embodiment, an edge-to-edge distance between facing edges of two power tap structures is determined as a distance between the center lines of the two MD contacts closest to (or overlapping) the facing edges. For example, two MD contacts closest to (or overlapping) the facing edges of the power tap structures 1091, 1093 are the MD contacts 1082, 1086. The edge-to-edge distance, i.e., distance d1, between facing edges of the power tap structures 1091, 1093 is considered to be the distance (i.e., 8 CPPs) between the centerlines of the MD contacts 1082, 1086.

A distance d2 between facing edges of the power tap structures 1091, 1092 is considered to be the distance (i.e., 2 CPPs) between the centerlines of the closest (or overlapping) MD contacts 1082, 1084. Because the distance d2 is greater than a predetermined distance (1 CPP in this example), the power tap structures 1091, 1092 are not considered adjacent, and are not merged or removed as described with respect to the intermediate layout 1006.

A distance d3 between facing edges of the power tap structures 1092, 1093 is considered to be the distance (i.e., 6 CPPs) between the centerlines of the closest (or overlapping) MD contacts 1084, 1086. Because the distance d3 is greater than the predetermined distance of 1 CPP, the power tap structures 1092, 1093 are not considered adjacent, and are not merged or removed. In some embodiments, however, the in-cell power tap structure 1092 is replaced with a VR via, as described with respect to the intermediate layout 1006.

A distance d4 between facing edges of the power tap structures 1094, 1095 is considered to be the distance (i.e., 1 CPP) between the centerlines of the closest (or overlapping) MD contacts 1082, 1083. Because the distance d4 is not greater than the predetermined distance of 1 CPP, the power tap structures 1094, 1095 are considered adjacent, and are merged or removed as described with respect to the intermediate layout 1006.

A distance d5 between facing edges of the power tap structures 1096, 1097 is considered to be the distance (i.e., 1 CPP) between the centerlines of the closest (or overlapping) MD contacts 1085, 1086. Because the distance d5 is not greater than the predetermined distance of 1 CPP, the power tap structures 1096, 1097 are considered adjacent, and are merged or removed as described with respect to the intermediate layout 1006. In some embodiments, after the merging and/or removal of the power tap structures 1094, 1095, and the merging and/or removal of the power tap structures 1096, 1097, the resulting or remaining two power tap structures have an edge-to-edge distance not greater than 8 CPPs to satisfy the predetermined PDN guideline.

The power tap structures 1098, 1099 overlap each other and are subject to merging and/or removal, as described with respect to the intermediate layout 1006.

In some embodiments, some or all of the operations described with respect to FIGS. 10A-10C, e.g., power tap structure merging/removal, active region addition, active region width increase, are performed simultaneously by replacing a cell with an equivalent cell for the same circuit but having a different power delivering configuration for top semiconductor devices and/or a different signal transmission arrangement, as described herein.

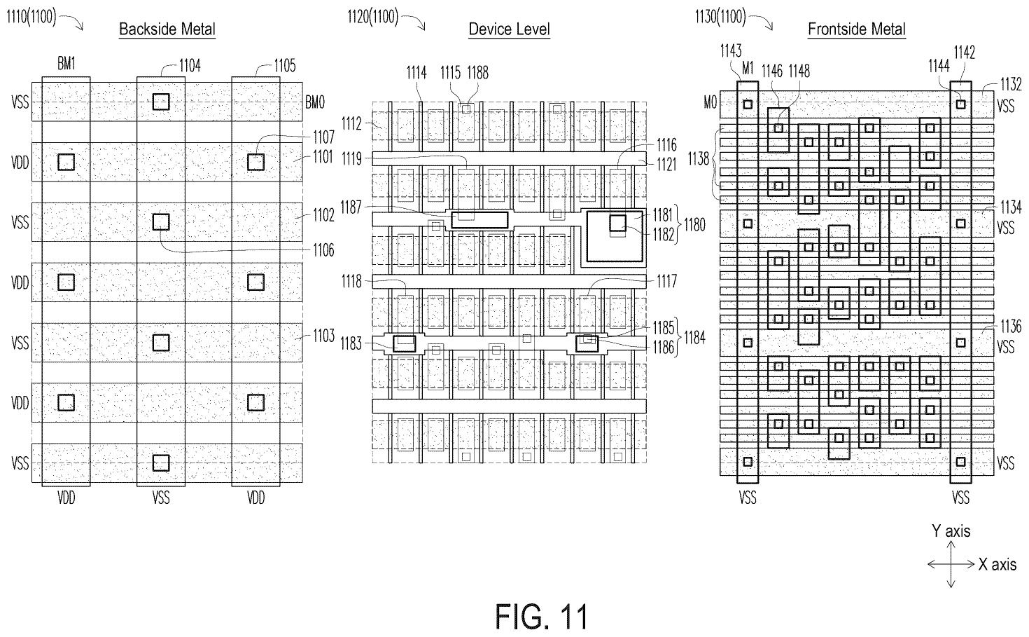

FIG. 11 includes schematic views at various layers of a layout 1100 of a circuit region of an IC device, in accordance with some embodiments. In some embodiments, the IC device corresponds to one or more of the IC devices and/or layouts described herein. The layout 1100 comprises a back side metal level 1110, a device level 1120, and a front side metal level 1130.

The back side metal level 1110 comprises a plurality of BM1 power rails, e.g., 1104, 1105, in the BM1 metal layer, a plurality of BM0 power rails, e.g., 1101-1103, in the BM0 metal layer, and a plurality of BV0 vias. The BM1 power rails are elongated along the Y axis, and configured to alternatingly carry VDD and VSS. The BM0 power rails are elongated along the X axis, and configured to alternatingly carry VDD and VSS. A BV0 via is between and electrically couples a BM1 power rail and a corresponding BM0 power rail. For example, a BV0 via 1106 is between and electrically couples a BM1 VSS power rail 1104 and a corresponding BM0 VSS power rail 1102. For a further example, a BV0 via 1107 is between and electrically couples a BM1 VDD power rail 1105 and a corresponding BM0 VDD power rail 1101. The described BM1 power rails, BM0 power rails and BV0 vias configure a back side power delivery network corresponding to the back side power delivery network 212. In some embodiments, one or more of the BM0 layer, BM1 layer further comprise corresponding BM0 and/or BM1 metal patterns (not shown) for signals.

The front side metal level 1130 comprises a plurality of M1 power rails, e.g., 1142, 1143, in the M1 metal layer, a plurality of M0 power rails, e.g., 1132, 1134, 1136, in the M0 metal layer, and a plurality of V0 vias. The M1 power rails are elongated along the Y axis, and configured to carry VSS. The M0 power rails are elongated along the X axis, and configured to carry VSS. A V0 via is between and electrically couples a M1 power rail and a corresponding M0 power rail. For example, a V0 via 1144 is between and electrically couples the M1 VSS power rail 1142 and the corresponding M0 VSS power rail 1132. The described M1 power rails, M0 power rails and corresponding V0 vias configure a front side power delivery network corresponding to the front side power delivery network 213. The M0 layer, M1 layer and V0 layer further comprise corresponding M0 metal patterns, M1 metal patterns and V0 vias for signals. For example, M0 metal patterns are elongated along the X axis and arranged along M0 signal tracks 1138 between the M0 VSS power rails 1132, 1134. M1 metal patterns are elongated along the Y axis, and arranged between the M1 VSS power rails 1142, 1143. A V0 via 1148 is between and electrically couples a M1 metal pattern 1146 and a corresponding M0 metal pattern along one of the M0 signal tracks 1138.

The device level 1120 comprises a plurality of device stacks configured by a plurality of active regions elongated along the X axis, and a plurality of gate regions elongated along the Y axis. An example active region 1112 and an example gate region 1114 are designated in FIG. 11. The device level 1120 shown in FIG. 11 corresponds to an upper layer of top semiconductor devices of the device stacks, similarly to the upper layers 751, 871 described herein. A lower layer of bottom semiconductor devices of the device stacks is omitted for simplicity. The device level 1120 further comprises MD contacts, e.g., 1115-1119, VD and VG vias (not shown), VR vias, e.g., 1182, 1186, 1188, via interconnects, e.g., 1181, 1183, 1185, 1187, and CMG regions arranged alternatingly with the active regions along the Y axis. An example CMG region 1121 is designated in FIG. 11.

The via interconnect 1183 is configured to provide VSS from the BM0 VSS power rail 1103 on the back side to a top semiconductor device having a source/drain under the MD contact 1118, in an LEQA configuration as described with respect to one or more of FIGS. 3A, 7A, 8A.

The via interconnect 1185 and the VR via 1186 configure an in-cell power tap structure 1184 configured to electrically couple the BM0 VSS power rail 1103 to the M0 VSS power rail 1136, while providing VSS to a top semiconductor device having a source/drain under the MD contact 1117, in an LEQB configuration as described with respect to one or more of FIGS. 2B, 2C, 3B, 4A, 7B, 8B.

The via interconnect 1181 and the VR via 1182 configure a stand-alone power tap structure 1180 configured to electrically couple the BM0 VSS power rail 1102 to the M0 VSS power rail 1134, as described with respect to one or more of FIGS. 2B, 2C, 5A, 6A. In the example configuration in FIG. 11, the stand-alone power tap structure 1180 is further configured to provide VSS to a top semiconductor device having a source/drain under the MD contact 1116. In some embodiments, the MD contact 1116 does not extend to overlap the via interconnect 1181 and/or the VR via 1182, and the stand-alone power tap structure 1180 is configured for the sole function of electrically coupling the corresponding BM0 VSS power rail 1102 and the M0 VSS power rail 1134.

The MD contact 1115 is coupled by the VR via 1188 to the M0 VSS power rail 1132 to receive VSS from the front side power delivery network, in an LEQC configuration as described with respect to one or more of FIGS. 2B, 2C, 3C, 7C, 8C. In the example configuration in FIG. 11, although there is no power tap structure electrically coupling the M0 VSS power rail 1132 to an underlying BM0 VSS power rail, VSS is still provided on the M0 VSS power rail 1132 through the M1 VSS power rails 1142, 1143, which, in turn, receive VSS from the M0 VSS power rails 1134, 1136 which are electrically coupled by the corresponding power tap structures 1180, 1184 to the corresponding BM0 VSS power rails 1102, 1103, as described herein.

The via interconnect 1187 is configured for signal transmission, and electrically couples a top source/drain under the MD contact 1119 to a bottom source/drain (not shown), as described with respect to one or more of FIGS. 3D, 4B, 8A-8C.

Although the active regions in FIG. 11 are illustrated as having constant widths, other configurations are within the scopes of various embodiments. For example, as described herein with respect to, e.g., FIGS. 10A-10C, active region portions not facing a via interconnect are configurable to have an increased active region width, compared to active region portions that face via interconnects.

FIG. 12A includes a schematic diagram of a portion of an IC manufacturing process 1200A, and schematic views of an IC device at various stages in the manufacturing process, in accordance with some embodiments. In some embodiments, the process 1200A is performed to manufacture one or more of the IC devices and/or in accordance with one or more of the layouts described herein. The process 1200A comprises operations 1202, 1204, 1206, 1208.

At operation 1202, a semiconductor structure 1220 is formed. In at least one embodiment, one or more operations described with respect to FIGS. 1B-IF are performed to obtain the semiconductor structure 1220. The semiconductor structure 1220 comprises a plurality of elongated, continuous gate structures 1230, 1240, 1250, 1260, 1270 extending across first and second active regions 1221, 1222. Each of the active regions 1221, 1222 comprises a bottom active region and a top active region stacked over the bottom active region, as described herein. Each of the gate structures 1230, 1240, 1250, 1260, 1270 comprises a first all-around gate extending around one or more channels in the top active region, and a second all-around gate extending around one or more channels in the bottom active region, as described herein.

At operation 1204, CMG openings 1281, 1282, 1283 are formed, e.g., by etching, in the semiconductor structure 1220 using a CMG mask. This operation is sometimes referred to as CMG patterning. Each of the CMG openings 1281, 1282, 1283 corresponds to a CMG region, as described herein. Each of the CMG openings 1281, 1282, 1283 extends through an entire thickness, or height, of the gate structures 1230, 1240, 1250, 1260, 1270, to cut or severe each of the gate structures 1230, 1240, 1250, 1260, 1270 into disconnected sections. For example, the gate structures 1230, 1240, 1250, 1260, 1270 are cut into corresponding gate structures 1231 and 1232, 1241 and 1242, 1251 and 1252, 1261 and 1262, 1271 and 1272. For simplicity, in the subsequent operations, the gate structures 1232, 1242, 1252, 1262, 1272, the active region 1222, and structures corresponding to the CMG opening 1283 are not illustrated.

At operation 1206, a conformal deposition of a dielectric material is performed, to deposit the dielectric material over side walls of a CMG opening where a via interconnect is to be later formed. In an example process, a conformal deposition process, such as ALD, is performed to deposit a conformal layer 1285 of the dielectric material over side walls of the CMG opening 1282, followed by an anisotropic etching to remove portions of the conformal layer other than the portions on the side walls of the CMG opening 1282. As a result, a middle region 1286 of the CMG opening 1282 remains unfilled. Other CMG openings where a via interconnect is not to be formed later are filled with a dielectric material to form corresponding dielectric structures. For example, the CMG opening 1281 is filled with a dielectric material to obtain a dielectric structure 1284.

At operation 1208, a conductive material is deposited in the unfilled middle region 1286 of the CMG opening 1282, to obtain a via interconnect 1287. In some embodiments, the via interconnect 1287 corresponds to one or more of the via interconnects described herein, and the layer 1285 of the dielectric material corresponds to one or more of the dielectric structures surrounding such via interconnects, as described herein.

In the described example process 1200A, an extra mask is not required for the formation of the via interconnect 1287. Specifically, the via interconnect 1287 is self-aligned, and formed by the CMG mask. In at least one embodiment, this is an advantage, because the manufacturing process is not significantly complicated by the formation of via interconnects. In at least one embodiment, one or more advantages described herein are achievable by one or more IC devices manufactured in accordance with the process 1200A.

FIG. 12B includes a schematic diagram of a portion of an IC manufacturing process 1200B, and schematic views of an IC device at various stages in the manufacturing process, in accordance with some embodiments. In some embodiments, the process 1200B is performed to manufacture one or more of the IC devices and/or in accordance with one or more of the layouts described herein. Components in FIG. 12B having corresponding components in FIG. 12A are designated by the same reference numerals as in FIG. 12A.

The process 1200B comprises operations 1202 and 1204 as described with respect to FIG. 12A, and operations 1210, 1212, 1214. For simplicity, operation 1202 and various features of operation 1204 are not illustrated in FIG. 12B, and the description of operation 1204 is not repeated.

At operation 1210, a dielectric material is deposited in all CMG openings to form corresponding dielectric structures. For example, the CMG openings 1281, 1282 are filled with a dielectric material to obtain corresponding dielectric structures 1284, 1295.

At operation 1212, a via patterning process is performed to form a via opening in a dielectric structure where a via interconnect is to be formed later. For example, an etching process is performed using an additional mask to form a via opening 1296 in the dielectric structure 1295.

At operation 1214, a conductive material is deposited in the via opening 1296, to obtain a via interconnect 1297. In some embodiments, the via interconnect 1297 corresponds to one or more of the via interconnects described herein, and the dielectric structure 1295 corresponds to one or more of the dielectric structures surrounding such via interconnects, as described herein. In at least one embodiment, the via interconnect 1297 corresponds to a power via as described herein. In at least one embodiment, one or more advantages described herein are achievable by one or more IC devices manufactured in accordance with the process 1200B. In some embodiments, at least one of the process 1200A or the process 1200B is applicable to manufacture via interconnects for various in-cell power tap structures and/or stand-alone power tap structures described herein, even where such power tap structures are to be formed in accordance with one or more CMG jog portions.

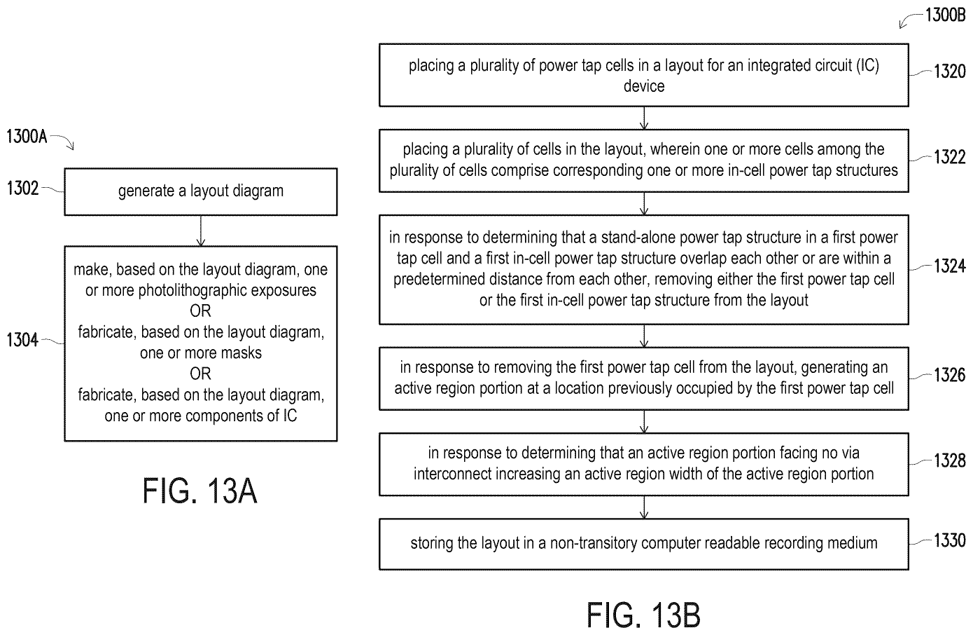

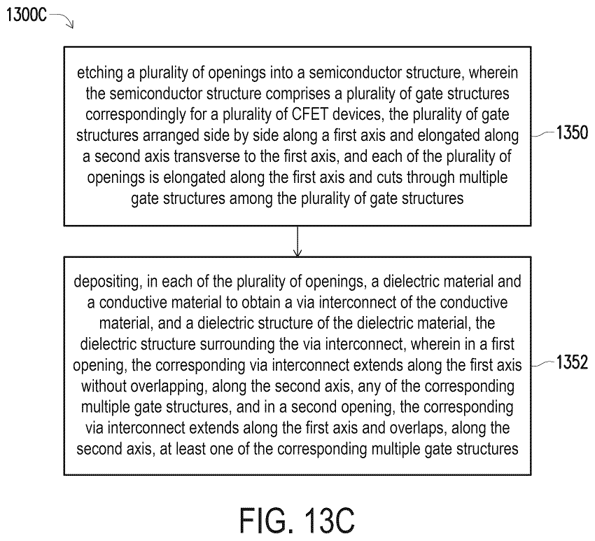

FIG. 13A is a flowchart of a method 1300A of generating a layout and using the layout to manufacture an IC device, in accordance with some embodiments. Method 1300A is implementable, for example, using an EDA system and/or an integrated circuit (IC) manufacturing system as described herein, in accordance with some embodiments. Regarding method 1300A, examples of the layout include the layouts disclosed herein, or the like. Examples of an IC device to be manufactured according to method 1300A include one or more of the IC devices disclosed herein.

At operation 1302, a layout is generated which, among other things, includes a combination of stand-alone power tap structures and in-cell power tap structures. An in-cell power tap structure comprises a via interconnect embedded in a dielectric structure corresponding to a cut-gate region of a cut-gate mask. Examples of operation 1302 are described with respect to FIGS. 10A-10C, 13B.

At operation 1304, based on the layout, at least one of (A) one or more photolithographic exposures are made or (B) one or more semiconductor masks are fabricated or (C) one or more components in a layer of an IC device are fabricated. Examples of operation 1304 are described with respect to FIGS. 12A-12B.

FIG. 13B is a flowchart of a method 1300B of generating a layout for an IC device, in accordance with some embodiments. The flowchart of FIG. 13B shows additional operations that demonstrate one or more examples of procedures implementable in operation 1302 of FIG. 13A, in accordance with one or more embodiments. In some embodiments, the layout generated by the method 1300B corresponds to one or more IC devices and layouts described herein. In at least one embodiment, the method 1300B is performed at least partially by a processor, e.g., in a computer system, an EDA system/tool, or an APR system/tool. The method 1300B comprises operations 1320, 1322, 1324, 1326, 1328, 1330. In at least one embodiment, one or more of the operations 1320, 1322, 1324, 1326, 1328, 1330 is/are omitted.

At operation 1320, a plurality of power tap cells is placed in a layout for an IC device. For example, as described with respect to FIG. 10A, power tap cells, e.g., as described with respect to FIGS. 2B, 2C, 5A, 5B, and corresponding stand-alone power tap structures 1030-1034 are placed in an intermediate layout 1002. In some embodiments, the power tap cells and the corresponding stand-alone power tap structures are distributed in a uniform manner along the X axis and/or the Y axis, in accordance with at least one predetermined PDN guideline. Other manners for initially distributing power tap cells and corresponding stand-alone power tap structures, not necessarily uniformly, are within the scopes of various embodiments.

At operation 1322, a plurality of cells, such as functional cells, are placed in the layout. One or more cells among the plurality of cells comprise corresponding one or more in-cell power tap structures. Examples of functional cells with in-cell power tap structures are described with respect to FIGS. 3B, 4A, 4B, 7B, 8B. In the example configuration in FIG. 10A, as a result of cell placement at operation 1322, various in-cell power tap structures 1040-1045 and various stand-alone power tap structures 1030-1034 are included in the intermediate layout 1004.

At operation 1324, it is determined whether a stand-alone power tap structure in a first power tap cell and a first in-cell power tap structure overlap each other or are within a predetermined distance from each other. In response to a positive determination, either the first power tap cell or the first in-cell power tap structure is removed from the layout. For example, as described with respect to the intermediate layouts 1004, 1006 in FIG. 10A, the determination of overlapping/adjacent power tap structures and power tap structure removal at operation 1324 result in various stand-alone power tap structures, e.g., 1030, 1031, 1034, and in-cell power tap structures, e.g., 1041, 1043, 1044, being removed. Accordingly, in one or more embodiments, it is possible to advantageously reduce the power tap area while satisfying at least one predetermined rule regarding power delivery, e.g., the predetermined PDN guideline.

At operation 1326, in response to the first power tap cell including a stand-alone power tap structure being removed from the layout at operation 1324, an active region portion is generated, or added, at a location previously occupied by the first power tap cell. For example, as described with respect to the intermediate layouts 1004, 1006 in FIG. 10A, active region portions 1060, 1061, 1064 are generated or added at locations previously occupied correspondingly by the stand-alone power tap structures 1030, 1031, 1034 which have been now removed as a result of operation 1324. Accordingly, in one or more embodiments, it is possible to advantageously provide area improvements.

At operation 1328, it is determined whether an active region portion faces no adjacent via interconnect. In response to a positive determination, an active region width of the active region portion is increased. For example, as described with respect to the intermediate layouts 1006, 1008 in FIG. 10B, various active region portions 1070-1076 are determined as facing no adjacent via interconnects, and therefore, the active region width of the active region portions 1070-1076 is increased, compared to the other active region portions that face one or more via interconnects. Accordingly, in one or more embodiments, it is possible to advantageously provide performance improvements due to the increased active region width.

In some embodiments, an increase in the active region width is made possible by removing a via interconnect configured to power a top semiconductor device from a back side power rail, and instead providing power to the top semiconductor device from a front side power rail, e.g., by replacing a cell having an LEQA configuration (e.g., layouts 300A, 700A, 800A) with an equivalent cell of the same circuit and having an LEQC configuration (e.g., layouts 300C, 700C, 800C). In such embodiments, in addition to determining whether the active region portion faces no adjacent via interconnect, it is further determined whether a predetermined rule for power delivery, e.g., the PDN guideline, is satisfied at the front side power rail from which power is to be provided to the top semiconductor device. In response to both determinations being positive, a cell having the LEQA configuration (e.g., layouts 300A, 700A, 800A) is replaced with an equivalent cell of the same circuit and having an LEQC configuration (e.g., layouts 300C, 700C, 800C), to obtain an increase in the active region width and associated performance improvements, in one or more embodiments.

At operation 1330, the layout is stored in a non-transitory computer readable recording medium, for later access and/or output for fabrication. In at least one embodiment, one or more advantages described herein are achievable by an IC device manufactured in accordance with the method 1300B.

FIG. 13C is a flowchart of a method 1300C of manufacturing an IC device, in accordance with some embodiments. The flowchart of FIG. 13C shows additional operations that demonstrate one or more examples of procedures implementable in operation 1304 of FIG. 13A, in accordance with one or more embodiments. In some embodiments, an IC device manufactured by the method 1300C corresponds to one or more IC devices described herein. The method 1300C comprises operations 1350, 1352.

At operation 1350, a plurality of openings into a semiconductor structure. The semiconductor structure comprises a plurality of gate structures correspondingly for a plurality of CFET devices. The plurality of gate structures is arranged side by side along a first axis and elongated along a second axis transverse to the first axis. Each of the plurality of openings is elongated along the first axis and cuts through multiple gate structures among the plurality of gate structures. For example, as described with respect to operations 1202 in FIG. 12A, a semiconductor structure 1220 comprises a plurality of gate structures 1230-1270 correspondingly for a plurality of CFET devices. The plurality of gate structures 1230-1270 is arranged side by side along a first axis, i.e., the X axis, and elongated along a second axis, i.e., the Y axis, transverse to the first axis. As described with respect to operation 1204 in FIG. 12A, an opening 1282 is etched in to the semiconductor structure 1220, such that the opening 1282 is elongated along the X axis and cuts through the plurality of gate structures 1230-1270, to severe the gate structures 1230-1270 into corresponding gate structures 1231-1271, 1232-1272.

At operation 1352, in each of the plurality of openings, a dielectric material and a conductive material are deposited to obtain a via interconnect of the conductive material, and a dielectric structure of the dielectric material surrounding the via interconnect. In a first opening among the plurality of openings, the corresponding via interconnect extends along the first axis without overlapping, along the second axis, any of the corresponding multiple gate structures. In a second opening among the plurality of openings, the corresponding via interconnect extends along the first axis and overlaps, along the second axis, at least one of the corresponding multiple gate structures.

For example, as described with respect to FIG. 12B, a dielectric material and a conductive material are deposited in an opening 1282 to obtain a via interconnect 1297 of the conductive material, and a dielectric structure 1295 of the dielectric material surrounding the via interconnect 1297. The via interconnect 1297 extends along the X axis without overlapping, along the Y axis, any of the corresponding multiple gate structures 1231-1271. In yet another example, as described with respect to FIG. 11, via interconnects 1183, 1185 of in-cell power tap structures extend along the X axis without overlapping, along the Y axis, any gate structure.

For a further example, as described with respect to FIG. 12A, a dielectric material and a conductive material are deposited in an opening 1282 to obtain a via interconnect 1287 of the conductive material, and a dielectric structure 1285 of the dielectric material surrounding the via interconnect 1287. The via interconnect 1287 extends along the X axis and overlaps, along the Y axis, at least one of the corresponding multiple gate structures, e.g., the gate structures 1231-1271. In yet another example, as described with respect to FIG. 11, a via interconnect 1187 of an in-cell power tap structure or a via interconnect 1181 of a stand-alone power tap structure extends along the X axis and overlaps, along the Y axis, at least one gate structure.

In some embodiments, one or more of the via interconnects formed in the operation 1352 are formed by at least one process described with respect to FIG. 12A. In at least one embodiment, one or more of the via interconnects formed in the operation 1352 are formed by at least one process described with respect to FIG. 12B. In at least one embodiment, one or more advantages described herein are achievable by an IC device manufactured in accordance with the method 1300C.

The described methods include example operations, but they are not necessarily required to be performed in the order shown. Operations may be added, replaced, changed order, and/or eliminated as appropriate, in accordance with the spirit and scope of embodiments of the disclosure. Embodiments that combine different features and/or different embodiments are within the scope of the disclosure and will be apparent to those of ordinary skill in the art after reviewing this disclosure.

In some embodiments, at least one method(s) discussed above is performed in whole or in part by at least one EDA system. In some embodiments, an EDA system is usable as part of a design house of an IC manufacturing system discussed below.

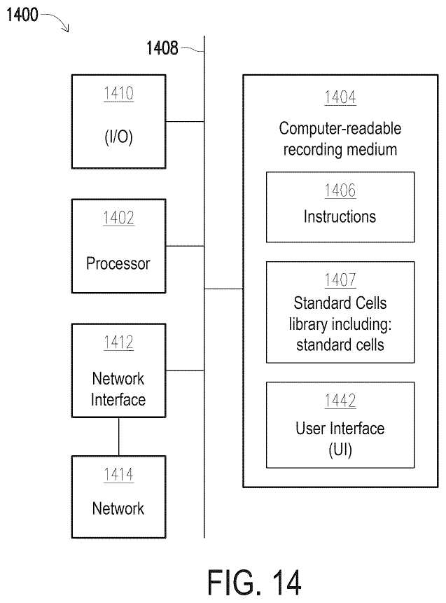

FIG. 14 is a block diagram of an electronic design automation (EDA) system 1400 in accordance with some embodiments.

In some embodiments, EDA system 1400 includes an APR system. Methods described herein of designing layouts represent wire routing arrangements, in accordance with one or more embodiments, are implementable, for example, using EDA system 1400, in accordance with some embodiments.

In some embodiments, EDA system 1400 is a general purpose computing device including a hardware processor 1402 and a non-transitory, computer-readable recording medium 1404. Recording medium 1404, amongst other things, is encoded with, i.e., stores, computer program code 1406, i.e., a set of executable instructions. Execution of instructions 1406 by hardware processor 1402 represents (at least in part) an EDA tool which implements a portion or all of the methods described herein in accordance with one or more embodiments (hereinafter, the noted processes and/or methods).

Processor 1402 is electrically coupled to computer-readable recording medium 1404 via a bus 1408. Processor 1402 is also electrically coupled to an I/O interface 1410 by bus 1408. A network interface 1412 is also electrically connected to processor 1402 via bus 1408. Network interface 1412 is connected to a network 1414, so that processor 1402 and computer-readable recording medium 1404 are capable of connecting to external elements via network 1414. Processor 1402 is configured to execute computer program code 1406 encoded in computer-readable recording medium 1404 in order to cause system 1400 to be usable for performing a portion or all of the noted processes and/or methods. In one or more embodiments, processor 1402 is a central processing unit (CPU), a multi-processor, a distributed processing system, an application specific integrated circuit (ASIC), and/or a suitable processing unit.

In one or more embodiments, computer-readable recording medium 1404 is an electronic, magnetic, optical, electromagnetic, infrared, and/or a semiconductor system (or apparatus or device). For example, computer-readable recording medium 1404 includes a semiconductor or solid-state memory, a magnetic tape, a removable computer diskette, a random access memory (RAM), a read-only memory (ROM), a rigid magnetic disk, and/or an optical disk. In one or more embodiments using optical disks, computer-readable recording medium 1404 includes a compact disk-read only memory (CD-ROM), a compact disk-read/write (CD-R/W), and/or a digital video disc (DVD).

In one or more embodiments, recording medium 1404 stores computer program code 1406 configured to cause system 1400 (where such execution represents (at least in part) the EDA tool) to be usable for performing a portion or all of the noted processes and/or methods. In one or more embodiments, recording medium 1404 also stores information which facilitates performing a portion or all of the noted processes and/or methods. In one or more embodiments, recording medium 1404 stores library 1407 of standard cells including such standard cells as disclosed herein.

EDA system 1400 includes I/O interface 1410. I/O interface 1410 is coupled to external circuitry. In one or more embodiments, I/O interface 1410 includes a keyboard, keypad, mouse, trackball, trackpad, touchscreen, and/or cursor direction keys for communicating information and commands to processor 1402.

EDA system 1400 also includes network interface 1412 coupled to processor 1402. Network interface 1412 allows system 1400 to communicate with network 1414, to which one or more other computer systems are connected. Network interface 1412 includes wireless network interfaces such as BLUETOOTH, WIFI, WIMAX, GPRS, or WCDMA; or wired network interfaces such as ETHERNET, USB, or IEEE-1364. In one or more embodiments, a portion or all of noted processes and/or methods, is implemented in two or more systems 1400.

System 1400 is configured to receive information through I/O interface 1410. The information received through I/O interface 1410 includes one or more of instructions, data, design rules, libraries of standard cells, and/or other parameters for processing by processor 1402. The information is transferred to processor 1402 via bus 1408. EDA system 1400 is configured to receive information related to a UI through I/O interface 1410. The information is stored in computer-readable recording medium 1404 as user interface (UI) 1442.

In some embodiments, a portion or all of the noted processes and/or methods is implemented as a standalone software application for execution by a processor. In some embodiments, a portion or all of the noted processes and/or methods is implemented as a software application that is a part of an additional software application. In some embodiments, a portion or all of the noted processes and/or methods is implemented as a plug-in to a software application. In some embodiments, at least one of the noted processes and/or methods is implemented as a software application that is a portion of an EDA tool. In some embodiments, a portion or all of the noted processes and/or methods is implemented as a software application that is used by EDA system 1400. In some embodiments, a layout which includes standard cells is generated using a tool such as VIRTUOSO® available from CADENCE DESIGN SYSTEMS, Inc., or another suitable layout generating tool.

In some embodiments, the processes are realized as functions of a program stored in a non-transitory computer readable recording medium. Examples of a non-transitory computer readable recording medium include, but are not limited to, external/removable and/or internal/built-in storage or memory unit, e.g., one or more of an optical disk, such as a DVD, a magnetic disk, such as a hard disk, a semiconductor memory, such as a ROM, a RAM, a memory card, and the like.

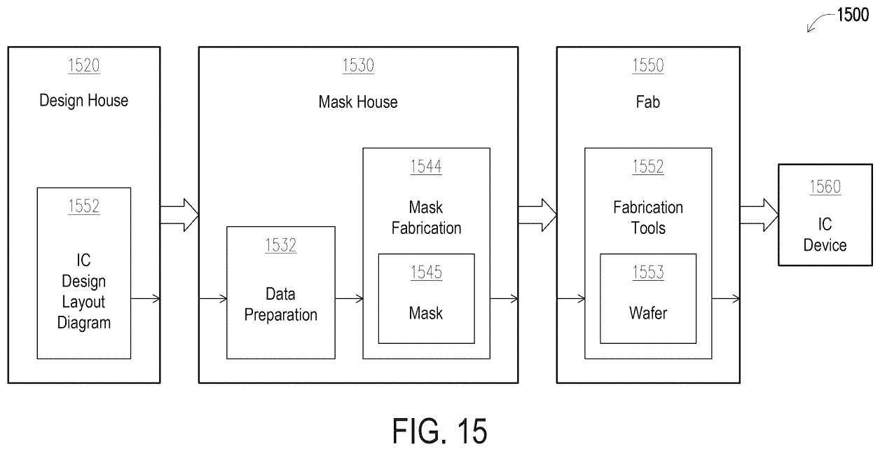

FIG. 15 is a block diagram of an integrated circuit (IC) manufacturing system 1500, and an IC manufacturing flow associated therewith, in accordance with some embodiments. In some embodiments, based on a layout, at least one of (A) one or more semiconductor masks or (B) at least one component in a layer of a semiconductor integrated circuit is fabricated using manufacturing system 1500.

In FIG. 15, IC manufacturing system 1500 includes entities, such as a design house 1520, a mask house 1530, and an IC manufacturer/fabricator (“fab”) 1550, that interact with one another in the design, development, and manufacturing cycles and/or services related to manufacturing an IC device 1560. The entities in system 1500 are connected by a communications network. In some embodiments, the communications network is a single network. In some embodiments, the communications network is a variety of different networks, such as an intranet and the Internet. The communications network includes wired and/or wireless communication channels. Each entity interacts with one or more of the other entities and provides services to and/or receives services from one or more of the other entities. In some embodiments, two or more of design house 1520, mask house 1530, and IC fab 1550 is owned by a single larger company. In some embodiments, two or more of design house 1520, mask house 1530, and IC fab 1550 coexist in a common facility and use common resources.

Design house (or design team) 1520 generates an IC design layout 1522. IC design layout 1522 includes various geometrical patterns designed for an IC device 1560. The geometrical patterns correspond to patterns of metal, oxide, or semiconductor layers that make up the various components of IC device 1560 to be fabricated. The various layers combine to form various IC features. For example, a portion of IC design layout 1522 includes various IC features, such as an active region, gate electrode, source and drain, metal lines or vias of an interlayer interconnection, and openings for bonding pads, to be formed in a semiconductor substrate (such as a silicon wafer) and various material layers disposed on the semiconductor substrate. Design house 1520 implements a proper design procedure to form IC design layout 1522. The design procedure includes one or more of logic design, physical design or place-and-route operation. IC design layout 1522 is presented in one or more data files having information of the geometrical patterns. For example, IC design layout 1522 can be expressed in a GDSII file format or DFII file format.

Mask house 1530 includes data preparation 1532 and mask fabrication 1544. Mask house 1530 uses IC design layout 1522 to manufacture one or more masks 1545 to be used for fabricating the various layers of IC device 1560 according to IC design layout 1522. Mask house 1530 performs mask data preparation 1532, where IC design layout 1522 is translated into a representative data file (“RDF”). Mask data preparation 1532 provides the RDF to mask fabrication 1544. Mask fabrication 1544 includes a mask writer. A mask writer converts the RDF to an image on a substrate, such as a mask (reticle) 1545 or a semiconductor wafer 1553. The design layout 1522 is manipulated by mask data preparation 1532 to comply with particular characteristics of the mask writer and/or requirements of IC fab 1550. In FIG. 15, mask data preparation 1532 and mask fabrication 1544 are illustrated as separate elements. In some embodiments, mask data preparation 1532 and mask fabrication 1544 can be collectively referred to as mask data preparation.

In some embodiments, mask data preparation 1532 includes optical proximity correction (OPC) which uses lithography enhancement techniques to compensate for image errors, such as those that can arise from diffraction, interference, other process effects and the like. OPC adjusts IC design layout 1522. In some embodiments, mask data preparation 1532 includes further resolution enhancement techniques (RET), such as off axis illumination, sub-resolution assist features, phase-shifting masks, other suitable techniques, and the like or combinations thereof. In some embodiments, inverse lithography technology (ILT) is also used, which treats OPC as an inverse imaging problem.

In some embodiments, mask data preparation 1532 includes a mask rule checker (MRC) that checks the IC design layout 1522 that has undergone processes in OPC with a set of mask creation rules which contain certain geometric and/or connectivity restrictions to ensure sufficient margins, to account for variability in semiconductor manufacturing processes, and the like. In some embodiments, the MRC modifies the IC design layout 1522 to compensate for limitations during mask fabrication 1544, which may undo part of the modifications performed by OPC in order to meet mask creation rules.

In some embodiments, mask data preparation 1532 includes lithography process checking (LPC) that simulates processing that will be implemented by IC fab 1550 to fabricate IC device 1560. LPC simulates this processing based on IC design layout 1522 to create a simulated manufactured device, such as IC device 1560. The processing parameters in LPC simulation can include parameters associated with various processes of the IC manufacturing cycle, parameters associated with tools used for manufacturing the IC, and/or other aspects of the manufacturing process. LPC takes into account various factors, such as aerial image contrast, depth of focus (“DOF”), mask error enhancement factor (“MEEF”), other suitable factors, and the like or combinations thereof. In some embodiments, after a simulated manufactured device has been created by LPC, if the simulated device is not close enough in shape to satisfy design rules, OPC and/or MRC are be repeated to further refine IC design layout 1522.

It should be understood that the above description of mask data preparation 1532 has been simplified for the purposes of clarity. In some embodiments, data preparation 1532 includes additional features such as a logic operation (LOP) to modify the IC design layout 1522 according to manufacturing rules. Additionally, the processes applied to IC design layout 1522 during data preparation 1532 may be executed in a variety of different orders.

After mask data preparation 1532 and during mask fabrication 1544, a mask 1545 or a group of masks 1545 are fabricated based on the modified IC design layout 1522. In some embodiments, mask fabrication 1544 includes performing one or more lithographic exposures based on IC design layout 1522. In some embodiments, an electron-beam (e-beam) or a mechanism of multiple e-beams is used to form a pattern on a mask (photomask or reticle) 1545 based on the modified IC design layout 1522. Mask 1545 can be formed in various technologies. In some embodiments, mask 1545 is formed using binary technology. In some embodiments, a mask pattern includes opaque regions and transparent regions. A radiation beam, such as an ultraviolet (UV) beam, used to expose the image sensitive material layer (e.g., photoresist) which has been coated on a wafer, is blocked by the opaque region and transmits through the transparent regions. In one example, a binary mask version of mask 1545 includes a transparent substrate (e.g., fused quartz) and an opaque material (e.g., chromium) coated in the opaque regions of the binary mask. In another example, mask 1545 is formed using a phase shift technology. In a phase shift mask (PSM) version of mask 1545, various features in the pattern formed on the phase shift mask are configured to have proper phase difference to enhance the resolution and imaging quality. In various examples, the phase shift mask can be attenuated PSM or alternating PSM. The mask(s) generated by mask fabrication 1544 is used in a variety of processes. For example, such a mask(s) is used in an ion implantation process to form various doped regions in semiconductor wafer 1553, in an etching process to form various etching regions in semiconductor wafer 1553, and/or in other suitable processes.

IC fab 1550 is an IC fabrication business that includes one or more manufacturing facilities for the fabrication of a variety of different IC products. In some embodiments, IC Fab 1550 is a semiconductor foundry. For example, there may be a manufacturing facility for the front end fabrication of a plurality of IC products (front-end-of-line (FEOL) fabrication), while a second manufacturing facility may provide the back end fabrication for the interconnection and packaging of the IC products (back-end-of-line (BEOL) fabrication), and a third manufacturing facility may provide other services for the foundry business.

IC fab 1550 includes fabrication tools 1552 configured to execute various manufacturing operations on semiconductor wafer 1553 such that IC device 1560 is fabricated in accordance with the mask(s), e.g., mask 1545. In various embodiments, fabrication tools 1552 include one or more of a wafer stepper, an ion implanter, a photoresist coater, a process chamber, e.g., a CVD chamber or LPCVD furnace, a CMP system, a plasma etch system, a wafer cleaning system, or other manufacturing equipment capable of performing one or more suitable manufacturing processes as discussed herein.

IC fab 1550 uses mask(s) 1545 fabricated by mask house 1530 to fabricate IC device 1560. Thus, IC fab 1550 at least indirectly uses IC design layout 1522 to fabricate IC device 1560. In some embodiments, semiconductor wafer 1553 is fabricated by IC fab 1550 using mask(s) 1545 to form IC device 1560. In some embodiments, the IC fabrication includes performing one or more lithographic exposures based at least indirectly on IC design layout 1522. Semiconductor wafer 1553 includes a silicon substrate or other proper substrate having material layers formed thereon. Semiconductor wafer 1553 further includes one or more of various doped regions, dielectric features, multilevel interconnects, and the like (formed at subsequent manufacturing steps).

In some embodiments, an integrated circuit (IC) device comprises an active region, a front side power rail, a back side power rail, and a first power tap structure extending between and electrically coupling the front side power rail to the back side power rail. The active region comprises, along a first axis, a first active region portion and a second active region portion continuous to the first active region portion. The first active region portion has, along a second axis transverse to the first axis, a width smaller than that of the second active region portion. The front side power rail and the back side power rail are on opposite sides of the active region, along a thickness direction transverse to both the first axis and the second axis. Along the second axis, the first power tap structure overlaps the first active region portion, without overlapping the second active region portion.

In some embodiments, an integrated circuit (IC) device comprises a plurality of complementary field-effect transistor (CFET) devices, a plurality of front side power rails and a plurality of back side power rails on opposite sides of the plurality of CFET devices along a thickness direction of the IC device, and a plurality of power tap structures each extending between and electrically coupling a front side power rail among the plurality of front side power rails to a corresponding back side power rail among the plurality of back side power rails. The plurality of power tap structures comprises a first power tap structure and second power tap structure. The first power tap structure has a smaller size, in a plane transverse to the thickness direction, than the second power tap structure.

In some embodiments, a method comprises etching a plurality of openings into a semiconductor structure. The semiconductor structure comprises a plurality of gate structures correspondingly for a plurality of complementary field-effect transistor (CFET) devices. The plurality of gate structures is arranged side by side along a first axis and elongated along a second axis transverse to the first axis. Each of the plurality of openings is elongated along the first axis and cuts through multiple gate structures among the plurality of gate structures. The method further comprises depositing, in each of the plurality of openings, a dielectric material and a conductive material to obtain a via interconnect of the conductive material, and a dielectric structure of the dielectric material surrounding the via interconnect. In a first opening among the plurality of openings, the corresponding via interconnect extends along the first axis without overlapping, along the second axis, any of the corresponding multiple gate structures. In a second opening among the plurality of openings, the corresponding via interconnect extends along the first axis and overlaps, along the second axis, at least one of the corresponding multiple gate structures.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An integrated circuit (IC) device, comprising:
an active region comprising, along a first axis, a first active region portion and a second active region portion continuous to the first active region portion, the first active region portion having, along a second axis transverse to the first axis, a width smaller than that of the second active region portion;
a front side power rail and a back side power rail on opposite sides of the active region, along a thickness direction transverse to both the first axis and the second axis; and
a first power tap structure extending between and electrically coupling the front side power rail to the back side power rail,
wherein, along the second axis, the first power tap structure overlaps the first active region portion, without overlapping the second active region portion.

2. The IC device of claim 1, further comprising:
a further active region comprising, along the first axis, a further first active region portion and a further second active region portion continuous to the further first active region portion, the further first active region portion having, along the second axis, a width smaller than that of the further second active region portion,
wherein, along the second axis,
the front side power rail, the back side power rail and the first power tap structure are between the active region and the further active region, and
the first power tap structure overlaps the further first active region portion, without overlapping the further second active region portion.

3. The IC device of claim 1, further comprising:
a second power tap structure extending between and electrically coupling the front side power rail to the back side power rail,
wherein
the active region further comprises a third active region portion continuous to the second active region portion and having a width smaller than that of the second active region portion, and
along the second axis, the second power tap structure overlaps the third active region portion, without overlapping the second active region portion.

4. The IC device of claim 1, further comprising:
a second power tap structure extending between and electrically coupling the front side power rail to the back side power rail,
wherein the second power tap structure has a larger size, in a plane transverse to the thickness direction, than the first power tap structure.

5. The IC device of claim 1, further comprising:
a second power tap structure extending between and electrically coupling the front side power rail to the back side power rail; and
a further back side power rail spaced from the back side power rail along the second axis,
wherein
the back side power rail and the further back side power rail are configured to correspondingly carry different power supply voltages, and
along the second axis,
the active region is between the back side power rail and the further back side power rail, and
a spacing between the second power tap structure and the further back side power rail is free of any active region.

6. The IC device of claim 1, further comprising:
a second power tap structure extending between and electrically coupling the front side power rail to the back side power rail,
wherein, along the first axis,
the first power tap structure overlaps neither of the first active region portion and the second active region portion, and
the second power tap structure overlaps both the first active region portion and the second active region portion.

7. The IC device of claim 1, further comprising:
a device stack in the active region, the device stack comprising:
a bottom semiconductor device, and
a top semiconductor device stacked over the bottom semiconductor device along the thickness direction;
a top contact structure over and in electrical contact with a source/drain of the top semiconductor device;
a bottom contact structure under and in electrical contact with a source/drain of the bottom semiconductor device;
a conductor co-elevational with, and spaced from, the bottom contact structure; and
a via interconnect extending between and electrically coupling the top contact structure and the conductor,
wherein the back side power rail is under and electrically coupled to the conductor.

8. The IC device of claim 1, further comprising:
a device stack in the first active region portion, the device stack comprising:
a bottom semiconductor device, and
a top semiconductor device stacked over the bottom semiconductor device along the thickness direction;
a top contact structure over and in electrical contact with a source/drain of the top semiconductor device;
a bottom contact structure under and in electrical contact with a source/drain of the bottom semiconductor device;
a conductor co-elevational with, and spaced from, the bottom contact structure; and
a via interconnect extending between and electrically coupling the top contact structure and the conductor,
wherein
the first power tap structure comprises the top contact structure, the via interconnect and the conductor,
the back side power rail is under and electrically coupled to the conductor, and
the front side power rail is over and electrically coupled to the top contact structure.

9. The IC device of claim 1, further comprising:
a device stack in the second active region portion, the device stack comprising:
a bottom semiconductor device, and
a top semiconductor device stacked over the bottom semiconductor device along the thickness direction;
a top contact structure over and in electrical contact with a source/drain of the top semiconductor device; and
a via between and electrically coupling the top contact structure to the front side power rail.

10. The IC device of claim 1, further comprising:
first and second device stacks, each comprising:
a bottom semiconductor device, and
a top semiconductor device stacked over the bottom semiconductor device along the thickness direction;
a top contact structure over and in electrical contact with a source/drain of the top semiconductor device of the first device stack;
a bottom contact structure under and in electrical contact with a source/drain of the bottom semiconductor device of the second device stack; and
a via interconnect extending between and electrically coupling the top contact structure and the bottom contact structure.

11. An integrated circuit (IC) device, comprising:
a plurality of complementary field-effect transistor (CFET) devices;
a plurality of front side power rails and a plurality of back side power rails on opposite sides of the plurality of CFET devices, along a thickness direction of the IC device; and
a plurality of power tap structures, each extending between and electrically coupling a front side power rail among the plurality of front side power rails to a corresponding back side power rail among the plurality of back side power rails,
wherein the plurality of power tap structures comprises a first power tap structure and second power tap structure, the first power tap structure having a smaller size, in a plane transverse to the thickness direction, than the second power tap structure.

12. The IC device of claim 11, further comprising:
a top contact structure over and in electrical contact with a source/drain of a top semiconductor device of a CFET device among the plurality of CFET devices; and
a via between and electrically coupling
the top contact structure, and
a front side power rail among the plurality of front side power rails.

13. The IC device of claim 12, wherein
the first power tap structure comprises the via.

14. The IC device of claim 11, further comprising:
a top contact structure over and in electrical contact with a source/drain of a top semiconductor device of a CFET device among the plurality of CFET devices;
a bottom contact structure under and in electrical contact with a source/drain of a bottom semiconductor device of the CFET device;
a conductor co-elevational with, and spaced from, the bottom contact structure; and
a via interconnect extending between and electrically coupling the top contact structure and the conductor,
wherein a back side power rail among the plurality of back side power rails is under and electrically coupled to the conductor.

15. The IC device of claim 11, wherein
the plurality of front side power rails and the plurality of back side power rails are configured to supply a first power supply voltage,
the plurality of CFET devices comprises:
a first CFET device having a first top contact structure over and in electrical contact with a source/drain of a top semiconductor device of the first CFET device, and
a second CFET device having a second top contact structure over and in electrical contact with a source/drain of a top semiconductor device of the second CFET device, and
the IC device further comprises:
a first via which overlaps, along the thickness direction, and electrically couples the first top contact structure and a front side power rail among the plurality of front side power rails, and
a second via which overlaps, along the thickness direction, and electrically couples the second top contact structure and a back side power rail among the plurality of back side power rails.

16. The IC device of claim 15, wherein
the first power tap structure comprises the first via or the second via.

17. The IC device of claim 11, wherein
the plurality of front side power rails and the plurality of back side power rails are configured to supply a first power supply voltage,
the IC device further comprises a plurality of further back side power rails configured to supply a second power supply voltage different from the first power supply voltage,
the plurality of CFET devices comprise bottom semiconductor devices which are configured to be powered by the second power supply voltage, and the bottom semiconductor devices are all electrically coupled to one or more of the further back side power rails, and
the plurality of CFET devices comprise top semiconductor devices which are configured to be powered by the first power supply voltage, and the top semiconductor devices comprise:
at least one top semiconductor device electrically coupled to one of the plurality of front side power rails, and
at least a further top semiconductor device electrically coupled to one of the plurality of back side power rails, without intermediary of any of the plurality of front side power rails.

18. A method, comprising:
etching a plurality of openings into a semiconductor structure, wherein
the semiconductor structure comprises a plurality of gate structures correspondingly for a plurality of complementary field-effect transistor (CFET) devices, the plurality of gate structures arranged side by side along a first axis and elongated along a second axis transverse to the first axis, and
each of the plurality of openings is elongated along the first axis and cuts through multiple gate structures among the plurality of gate structures; and
depositing, in each of the plurality of openings, a dielectric material and a conductive material to obtain
a via interconnect of the conductive material, and
a dielectric structure of the dielectric material, the dielectric structure surrounding the via interconnect,
wherein
in a first opening among the plurality of openings, the corresponding via interconnect extends along the first axis without overlapping, along the second axis, any of the corresponding multiple gate structures, and
in a second opening among the plurality of openings, the corresponding via interconnect extends along the first axis and overlaps, along the second axis, at least one of the corresponding multiple gate structures.

19. The method of claim 18, wherein
the depositing in each of the plurality of openings comprises:
depositing a conformal layer of the dielectric material over side walls of the opening to form the dielectric structure, while leaving a middle region of the opening unfilled; and
filing the middle region of the opening with the conductive material to obtain the corresponding via interconnect.

20. The method of claim 18, wherein
the depositing in each of the plurality of openings comprises:
depositing the dielectric material in the opening to obtain an intermediate dielectric structure;
etching a via opening in the intermediate dielectric structure, wherein a remainder of the intermediate dielectric structure outside the via opening configures the dielectric structure; and
filling the via opening with the conductive material to obtain the corresponding via interconnect.
